(19) United States
(12) Patent Application Publication
(10) Pub. No.: US 2016/0363859 A1
(43) Pub. Date: Dec. 15, 2016

(54) RADIATION-SENSITIVE RESIN COMPOSITION AND RESIST PATTERN-FORMING METHOD

(71) Applicant: JSR CORPORATION, Tokyo (JP)

(72) Inventor: Hayato NAMAI, Tokyo (JP)

(73) Assignee: JSR CORPORATION, Tokyo (JP)

(21) Appl. No.: 15/155,123

(22) Filed: May 16, 2016

(30) Foreign Application Priority Data
Jun. 15, 2015 (JP) 2015-120681

(51) Int. Cl. G03F 7/039; G03F 7/32; G03F 7/038; G03F 7/20

(52) U.S. Cl. CPC G03F 7/039; G03F 7/2053; G03F 7/322; G03F 7/038; G03F 7/325; G03F 7/2059

(57) ABSTRACT

A radiation-sensitive resin composition comprises: a polymer having a structural unit that comprises an acid-labile group; a radiation-sensitive acid generator; and a salt that comprises an onium cation, and HCO₃⁻, CO₃²⁻ or a combination thereof. The onium cation is preferably a sulfonium cation, an ammonium cation, an iodonium cation, a phosphonium cation, a diazonium cation or a combination thereof. The onium cation is preferably a cation represented by formula (b-1) or formula (b-2). The acid generated from the radiation-sensitive acid generator is preferably a sulfonic acid, an imide acid, an amide acid, a methide acid or a combination thereof.

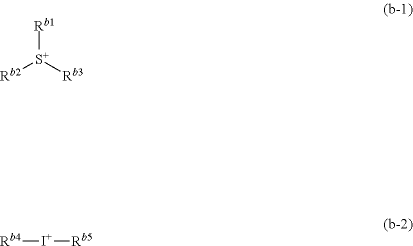

### CROSS-REFERENCE TO RELATED APPLICATIONS

The present application claims priority to Japanese Patent Application No. 2015-120681, filed Jun. 15, 2015, the contents of which are incorporated herein by reference in their entirety.

### BACKGROUND OF THE INVENTION

Field of the Invention

The present invention relates to a radiation-sensitive resin composition and a resist pattern-forming method.

Discussion of the Background

In radiation-sensitive resin compositions for use in microfabrication through lithography, an acid is generated in light-exposed regions upon irradiation with a far ultraviolet ray such as a KrF excimer laser beam (wavelength: 248 nm), an ArF excimer laser beam (wavelength: 193 nm) or an extreme-ultraviolet ray (EUV; wavelength: 13.5 nm), a charged particle ray such as an electron beam, or the like, and a chemical reaction catalyzed by the acid causes a difference in rate of dissolution in a developer solution between the light-exposed regions and light-unexposed regions, thereby forming a resist pattern on a substrate.

In these days, processing techniques for microfabrication of a resist pattern through the use of a laser beam or an electron beam having a shorter wavelength and by means of immersion scanners, and the like have been developed. Along with these circumstances, the radiation-sensitive resin compositions are demanded to form a resist pattern having not only superior resolution and rectangularity of cross-sectional shape, but also superior line width roughness (LWR) performances, critical dimension uniformity (CDU) performances, depth of focus and mask error enhancement factor (MEEF) performances, and to give a highly accurate pattern in a high process yield. To address these demands, the type, the molecular structure and the like of an acid generator, an acid diffusion controller and other component for use in radiation-sensitive resin compositions have been extensively studied. Onium salt compounds that contain an onium cation, and a carboxylic acid anion or a sulfonic acid anion have been known as the acid diffusion controller, and can reportedly improve the performances described above (see Japanese Unexamined Patent Application, Publication Nos. H11-125907, 2002-122994 and 2010-061043).

### SUMMARY OF THE INVENTION

According to one aspect of the present invention, a radiation-sensitive resin composition comprises: a polymer having a structural unit that comprises an acid-labile group; a radiation-sensitive acid generator; and a salt that comprises an onium cation, and HCO₃⁻, CO₃²⁻ or a combination thereof.

According to another aspect of the present invention, a resist pattern-forming method comprises applying the radiation-sensitive resin composition on a substrate to form a resist film on the substrate. The resist film is exposed. The resist film exposed is developed.

### DESCRIPTION OF THE EMBODIMENTS

According to an embodiment of the invention, a radiation-sensitive resin composition contains: a polymer (hereinafter, may be also referred to as “(A) polymer” or “polymer (A)”) having a structural unit that includes an acid-labile group (hereinafter, may be also referred to as “structural unit (I)”); a radiation-sensitive acid generator (hereinafter, may be also referred to as “(B) acid generator” or “acid generator (B)”); and a salt that contains an onium cation, and HCO₃⁻, CO₃²⁻ or a combination thereof (hereinafter, may be also referred to as “(C) salt” or “salt (C)”).

According to another embodiment of the invention, a resist pattern-forming method includes the steps of forming a resist film; exposing the resist film; and developing the resist film exposed, wherein the resist film is formed from the radiation-sensitive resin composition according to the embodiment of the present invention.

The “acid-labile group” as referred to herein means a group that substitutes for a hydrogen atom of a carboxy group, a hydroxy group or the like and is dissociated by an action of an acid. Further, the “number of ring atoms” as referred to means the number of atoms constituting a ring of an alicyclic structure, an aromatic ring structure, an aliphatic heterocyclic structure or an aromatic heterocyclic structure.

The radiation-sensitive resin composition and the resist pattern-forming method according to the embodiments of the present invention enable a resist pattern that is superior in LWR performances, CDU performances, resolution and rectangularity of cross-sectional shape to be formed while superior depth of focus and MEEF performances are exhibited. Therefore, these can be suitably used for pattern formation in production of semiconductor devices, and the like, in which further progress of miniaturization is expected. Hereinafter, the embodiments will be explained in detail.

### Radiation-Sensitive Resin Composition

The radiation-sensitive resin composition according to an embodiment of the present invention contains the polymer (A), the acid generator (B) and the salt (C). The radiation-sensitive resin composition may contain, as a favorable component, a polymer having a greater mass percentage content of fluorine atoms than that of the polymer (A) (hereinafter, may be also referred to as “(D) polymer” or “polymer (D)”), (E) a solvent, (F) a localization accelerator and/or other acid diffusion controller than the salt (C) (hereinafter, may be also referred to as “(G) other acid diffusion controller” or “other acid diffusion controller (G)). Furthermore, the radiation-sensitive resin composition may contain other optional component, within a range not leading to impairment of the effects of the present invention. Hereinafter, each component will be described.

### (A) Polymer

The polymer (A) has the structural unit (I). According to the radiation-sensitive resin composition, an acid-labile group of the polymer (A) in light-exposed regions is dissociated by an acid generated from the acid generator (B) or the like upon irradiation with a radioactive ray, causing a difference in solubility in a developer solution to be produced between the light-exposed regions and light-unexposed regions, and consequently a resist pattern can be formed. The polymer (A) generally serves as a base polymer in the radiation-sensitive resin composition. The “base polymer” as referred to means a polymer that is contained as a principal component among polymers constituting the resist film, and accounts for preferably no less than 50% by mass, and more preferably no less than 60% by mass with respect to the total polymers constituting the resist film.

The polymer (A) preferably has, in addition to the structural unit (I), a structural unit that includes a lactone structure, a cyclic carbonate structure, a sultone structure or a combination thereof (hereinafter, may be also referred to as “structural unit (II)”), a structural unit that includes a phenolic hydroxyl group (hereinafter, may be also referred to as “structural unit (III)”), and/or a structural unit that includes an alcoholic hydroxyl group (hereinafter, may be also referred to as “structural unit (IV)”), and may have other structural unit than the structural units (I) to (IV). The polymer (A) may have one type, or two or more types of these structural units. Hereinafter, each structural unit will be described.

### Structural Unit (I)

The structural unit (I) includes an acid-labile group. The structural unit (I) is exemplified by a structural unit represented by the following formula (a-1) (hereinafter, may be also referred to as “structural unit (I-1)”), a structural unit represented by the following formula (a-2) (hereinafter, may be also referred to as “structural unit (I-2)”), and the like.

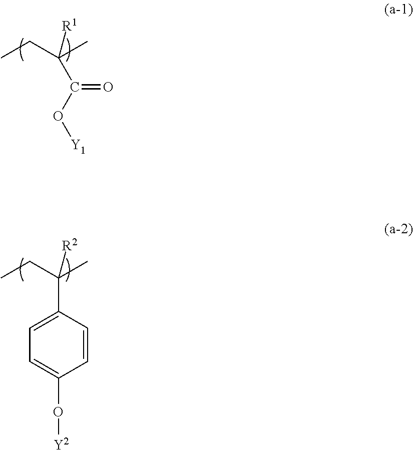

In the above formula (a-1), R¹ represents a hydrogen atom, a fluorine atom, a methyl group or a trifluoromethyl group; and Y¹ represents a monovalent acid-labile group represented by the following formula (Y-1).

In the above formula (a-2), R² represents a hydrogen atom or a methyl group; and Y² represents a monovalent acid-labile group represented by the following formula (Y-2).

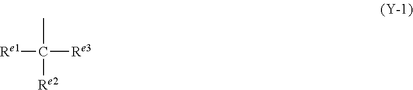

In the above formula (Y-1), R^{e1} represents a monovalent hydrocarbon group having 1 to 20 carbon atoms; R^{e2} and R^{e3} each independently represent a monovalent hydrocarbon group having 1 to 20 carbon atoms, or R^{e2} and R^{e3} taken together represent an alicyclic structure having 3 to 20 ring atoms together with the carbon atom to which R^{e2} and R^{e3} bond.

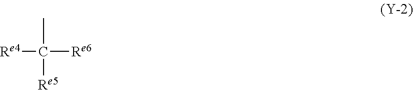

In the above formula (Y-2), R^{e4}, R^{e5} and R^{e6} each independently represent a hydrogen atom, a monovalent chain hydrocarbon group having 1 to 20 carbon atoms, a monovalent alicyclic hydrocarbon group having 3 to 20 carbon atoms, or an oxychain hydrocarbon group having 1 to 20 carbon atoms or an oxyalicyclic hydrocarbon group having 3 to 20 carbon atoms, wherein at least one of R^{e4}, R^{e5} and R^{e6} does not represent a hydrogen atom.

The “hydrocarbon group” as referred to includes chain hydrocarbon groups, alicyclic hydrocarbon groups and aromatic hydrocarbon groups. This “hydrocarbon group” may be a saturated hydrocarbon group or an unsaturated hydrocarbon group. The “chain hydrocarbon group” as referred to means a hydrocarbon group that is constituted with only a chain structure without having a cyclic structure, and the term “chain hydrocarbon group” includes both linear hydrocarbon groups and branched hydrocarbon groups. The “alicyclic hydrocarbon group” as referred to means a hydrocarbon group that has as a ring structure not an aromatic ring structure but only an alicyclic structure, and the term “alicyclic hydrocarbon group” includes both monocyclic alicyclic hydrocarbon groups and polycyclic alicyclic hydrocarbon groups. However, it is not necessary for the alicyclic hydrocarbon group to be constituted with only an alicyclic structure, and a part thereof may have a chain structure. The “aromatic hydrocarbon group” as referred to means a hydrocarbon group that has an aromatic ring structure as a ring structure. However, it is not necessary for the aromatic hydrocarbon group to be constituted with only an aromatic ring structure, and a part thereof may have a chain structure and/or an alicyclic structure.

In light of the copolymerizability of a monomer that gives the structural unit (I-1), R¹ represents preferably a hydrogen atom or a methyl group, and more preferably a methyl group.

The monovalent hydrocarbon group having 1 to 20 carbon atoms which may be represented by R^{e1}, R^{e2} or R^{e3} is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms which may be represented by R^{e1}, R^{e2} or R^{e3} include:

alkyl groups such as a methyl group, an ethyl group, a n-propyl group and an i-propyl group;

alkenyl groups such as an ethenyl group, a propenyl group and a butenyl group;

alkynyl groups such as an ethynyl group, a propynyl group and a butynyl group; and the like. Of these, the alkyl groups are preferred, an alkyl group having 1 to 4 carbon atoms is more preferred, a methyl group, an ethyl group and an i-propyl group are still more preferred, and the ethyl group is particularly preferred.

Examples of the monovalent alicyclic hydrocarbon group having 3 to 20 carbon atoms which may be represented by R^{e1}, R^{e2} or R^{e3} include:

monocyclic cycloalkyl groups such as a cyclopentyl group and a cyclohexyl group;

monocyclic cycloalkenyl groups such as a cyclopentenyl group and a cyclohexenyl group;

polycyclic cycloalkyl groups such as a norbornyl group, an adamantyl group and a tricyclodecyl group;

polycyclic cycloalkenyl groups such as a norbornenyl group and a tricyclodecenyl group; and the like. Of these, the monocyclic cycloalkyl groups and the polycyclic cycloalkyl groups are preferred, and the cyclopentyl group, the cyclohexyl group, the norbornyl group and the adamantyl group are more preferred.

Examples of the monovalent aromatic hydrocarbon group having 6 to 20 carbon atoms which may be represented by R^{e1}, R^{e2} or R^{e3} include:

aryl groups such as a phenyl group, a tolyl group, a xylyl group, a mesityl group, a naphthyl group, a methylnaphthyl group, an anthryl group and a methylanthryl group;

aralkyl groups such as a benzyl group, a phenethyl group, a naphthylmethyl group and an anthrylmethyl group; and the like.

Examples of the alicyclic structure having 3 to 20 carbon atoms which may be taken together represented by the groups of R^{e2} and R^{e3} together with the carbon atom to which R^{e2} and R^{e3} bond include:

monocyclic cycloalkane structures such as a cyclopropane structure, a cyclobutane structure, a cyclopentane structure, a cyclohexane structure, a cycloheptane structure and a cyclooctane structure;

polycyclic cycloalkane structures such as a norbornane structure, an adamantane structure, a tricyclodecane structure and a tetracyclododecane structure; and the like. Of these, a monocyclic cycloalkane structure having 5 to 8 carbon atoms and a polycyclic cycloalkane structure having 7 to 12 carbon atoms are preferred, a cyclopentane structure, a cyclohexane structure, a cyclooctane structure, a norbornane structure and an adamantane structure are more preferred, and the cyclopentane structure and the adamantane structure are still more preferred.

R^{e2} and R^{e3} represent preferably the monovalent chain hydrocarbon group having 1 to 20 carbon atoms and the monovalent alicyclic hydrocarbon group having 3 to 20 carbon atoms.

In light of the copolymerizability of a monomer that gives the structural unit (I-2), R² preferably represents the hydrogen atom.

Examples of the monovalent chain hydrocarbon group having 1 to 20 carbon atoms which may be represented by R^{e4}, R^{e5} or R^{e6} include groups similar to those exemplified in connection with R^{e1}, R^{e2} and R^{e3}, and the like. Of these, the alkyl groups are preferred, the alkyl group having 1 to 4 carbon atoms is more preferred, the methyl group, the ethyl group and the n-propyl group are still more preferred, and the methyl group is particularly preferred.

Examples of the monovalent alicyclic hydrocarbon group having 3 to 20 carbon atoms which may be represented by R^{e4}, R^{e5} or R^{e6} include groups similar to those exemplified in connection with R^{e1}, R^{e2} and R^{e3}, and the like. Of these, the monocyclic cycloalkyl group and the polycyclic cycloalkyl group are preferred, and the cyclopentyl group, the cyclohexyl group, the norbornyl group and the adamantyl group are more preferred.

Examples of the monovalent oxychain hydrocarbon group having 1 to 20 carbon atoms which may be represented by R^{e4}, R^{e5} or R^{e6} include:

alkoxy groups such as a methoxy group, an ethoxy group, a n-propoxy group, an i-propoxy group, a n-butoxy group, an i-butoxy group, a sec-butoxy group, a t-butoxy group and a n-pentyloxy group;

alkenyloxy groups such as an ethenyloxy group, a propenyloxy group, a butenyloxy group and a pentenyloxy group;

alkynyloxy groups such as an ethynyloxy group, a propynyloxy group, a butynyloxy group and a pentynyloxy group; and the like. Of these, the alkoxy groups are preferred, an alkoxy group having 1 to 4 carbon atoms is more preferred, and the methoxy group, the ethoxy group and the n-propoxy group are still more preferred.

Examples of the monovalent oxyalicyclic hydrocarbon group having 3 to 20 carbon atoms which may be represented by R^{e4}, R^{e5} or R^{e6} include:

monocyclic cycloalkyloxy groups such as a cyclopropyloxy group, a cyclobutyloxy group, a cyclopentyloxy group, a cyclohexyloxy group and a cyclooctyloxy group;

polycyclic cycloalkyloxy groups such as a norbomyloxy group, an adamantyloxy group, a tricyclodecyloxy group and a tetracyclododecyloxy group;

monocyclic cycloalkenyloxy groups such as a cyclopropenyloxy group, a cyclobutenyloxy group, a cyclopentenyloxy group and a cyclohexenyloxy group;

polycyclic cycloalkenyloxy groups such as a norbomenyloxy group and a tricyclodecenyloxy group; and the like. Of these, the monocyclic cycloalkyloxy groups and the polycyclic cycloalkyloxy groups are preferred, and the cyclopentyloxy group, the cyclohexyloxy group, the norbomyloxy group and the adamantyloxy group are more preferred.

The group represented by the above formula (Y-2) is preferably the group represented by the above formula (Y-2) in which R^{e4}, R^{e5} and R^{e6} represent the monovalent chain hydrocarbon group, the group represented by the above formula (Y-2) in which R^{e4} and R^{e5} represent the monovalent chain hydrocarbon group and R^{e6} represents the monovalent oxychain hydrocarbon group, or the group represented by the above formula (Y-2) in which R^{e4} represents the monovalent chain hydrocarbon group and R^{e5} and R^{e6} represent the monovalent oxychain hydrocarbon group, more preferably the group represented by the above formula (Y-2) in which R^{e4}, R^{e5} and R^{e6} represent the alkyl group, the group represented by the above formula (Y-2) in which R^{e4} and R^{e5} represent the alkyl group and R^{e6} represents the alkoxy group, or the group represented by the above formula (Y-2) in which R^{e4} represents the alkyl group and R^{e5} and R^{e6} represent the alkoxy group, still more preferably the group represented by the above formula (Y-2) in which R^{e4}, R^{e5} and R^{e6} represent the alkyl group, and particularly preferably a t-butyl group, a t-pentyl group, a t-hexyl group and a t-heptyl group.

Examples of the structural unit (I) include:

structural units represented by the following formulae (a-1-1) to (a-1-6) (hereinafter, may be also referred to as “structural units (I-1-1) to (I-1-6)”) and the like as the structural unit (I-1); and

structural units represented by the following formulae (a-2-1) to (a-2-3) (hereinafter, may be also referred to as “structural units (I-2-1) to (I-2-3)”) and the like as the structural unit (I-2).

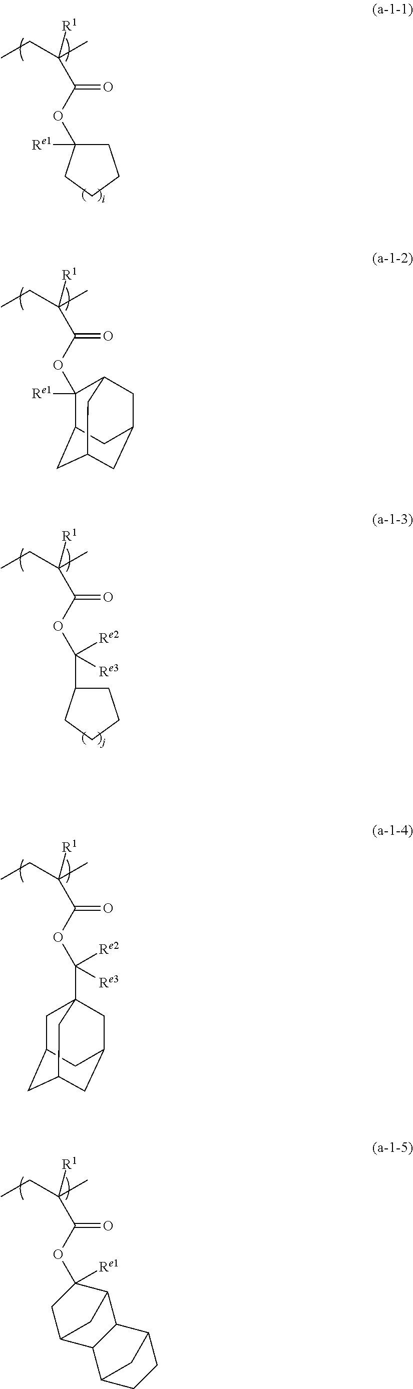

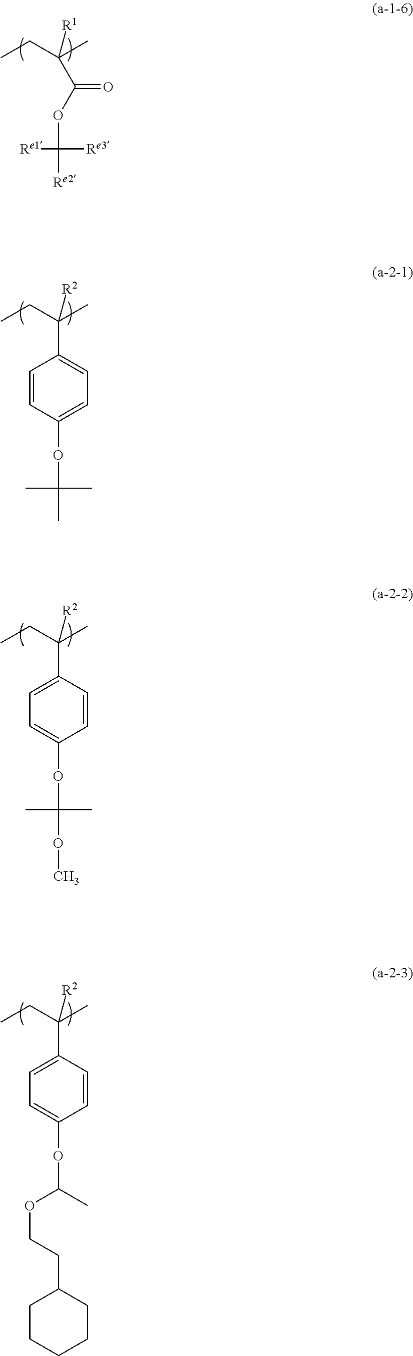

In the above formulae (a-1-1) to (a-1-6), R¹ is as defined in the above formula (a-1); R^{e1} to R^{e3} are as defined in the above formula (Y-1); R^{e1}′ to R^{e3}′ each independently represent a monovalent chain hydrocarbon group having 1 to 10 carbon atoms; and i and j are each independently an integer of 1 to 4.

In the above formulae (a-2-1) to (a-2-3), R² is as defined in the above formula (a-2).

As the structural unit (I), the structural units (I-1-1) to (I-1-5) and structural unit (I-2-3) are preferred.

Examples of the structural unit (I-1) include structural units represented by the following formulae, and the like.

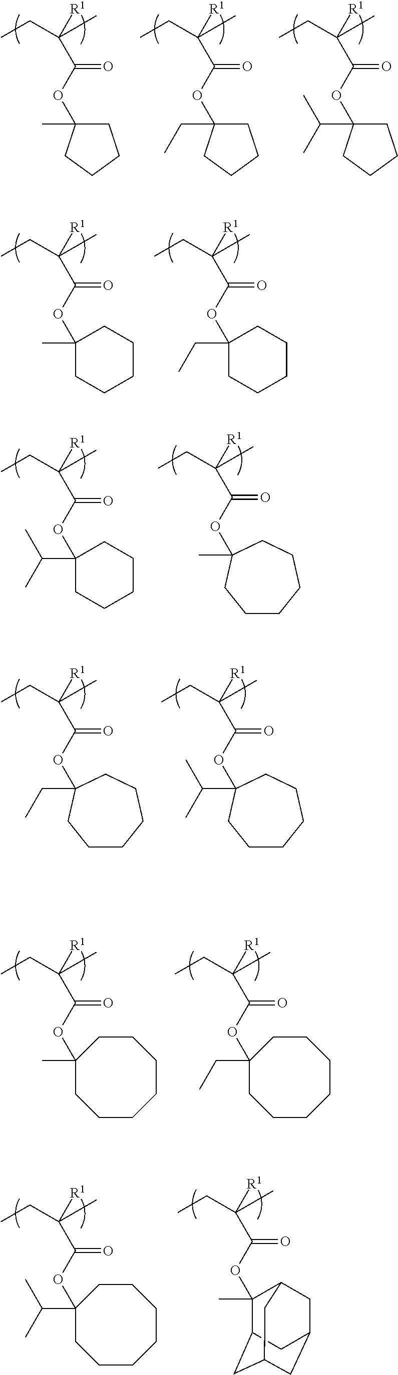

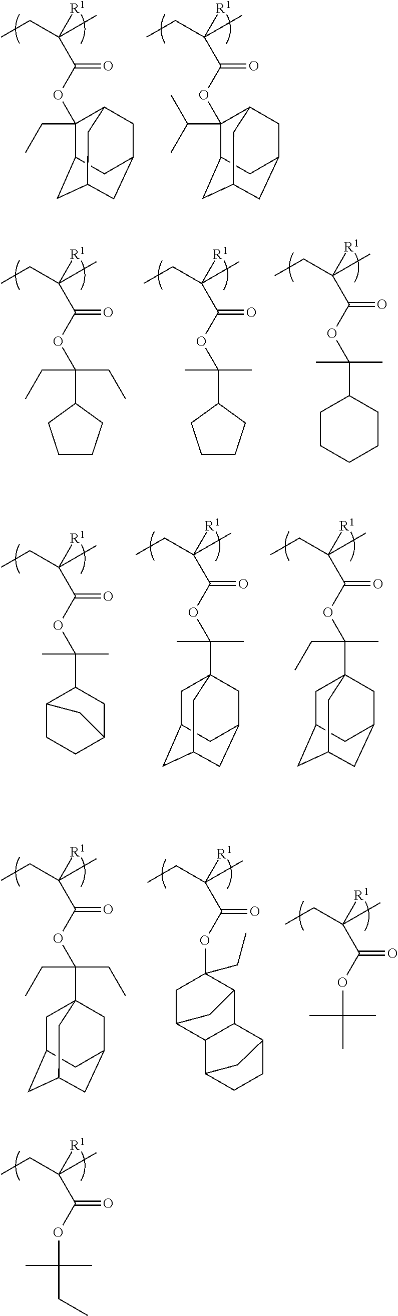

In the above formulae, R¹ is as defined in the above formula (a-1).

As the structural unit (I), a structural unit derived from 1-alkyl-monocyclic cycloalkan-1-yl (meth)acrylate, a structural unit derived from 2-alkyl-polycyclic cycloalkan-2-yl (meth)acrylate and a structural unit derived from 2-(cycloalkane-yl)propan-2-yl (meth)acrylate are preferred, and a structural unit derived from 1-ethyl-cyclopentyl-1-yl (meth)acrylate, a structural unit derived from 2-methyl-adamantyl-2-yl (meth)acrylate, a structural unit derived from 2-ethyl-adamantyl-2-yl (meth)acrylate, a structural unit derived from 2-(adamantane-yl)-propan-2-yl (meth)acrylate, a structural unit derived from 2-cyclohexyl-propan-2-yl (meth)acrylate and a structural unit derived from 2-ethyl-2-tetracyclododecan-2-yl (meth)acrylate are more preferred.

The lower limit of the proportion of the structural unit (I) with respect to the total structural units constituting the polymer (A) is preferably 10 mol %, more preferably 20 mol %, still more preferably 30 mol %, and particularly preferably 35 mol %. The upper limit of the aforementioned proportion is preferably 80 mol %, more preferably 75 mol %, still more preferably 70 mol %, and particularly preferably 60 mol %. When the proportion of the structural unit (I) falls within the above range, the LWR performances, etc. of the radiation-sensitive resin composition may be further improved.

### Structural Unit (II)

The structural unit (II) includes a lactone structure, a cyclic carbonate structure, a sultone structure or a combination thereof. When the polymer (A) further includes structural unit (II) in addition to the structural unit (I), the solubility of the polymer (A) in a developer solution may be further regulated, and consequently the LWR performances, etc. of the radiation-sensitive resin composition may be more improved. Moreover, the adhesiveness of a resist pattern formed from the radiation-sensitive resin composition to a substrate may be improved.

Examples of the structural unit (II) include structural units represented by the following formulae, and the like.

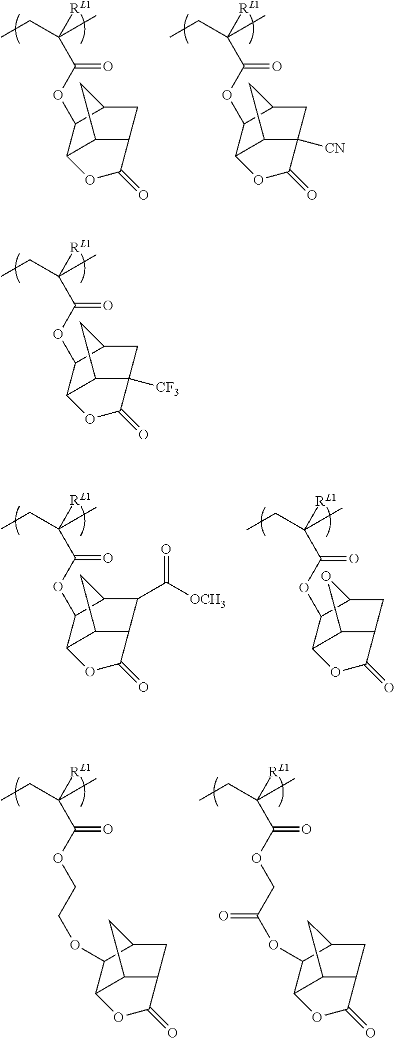

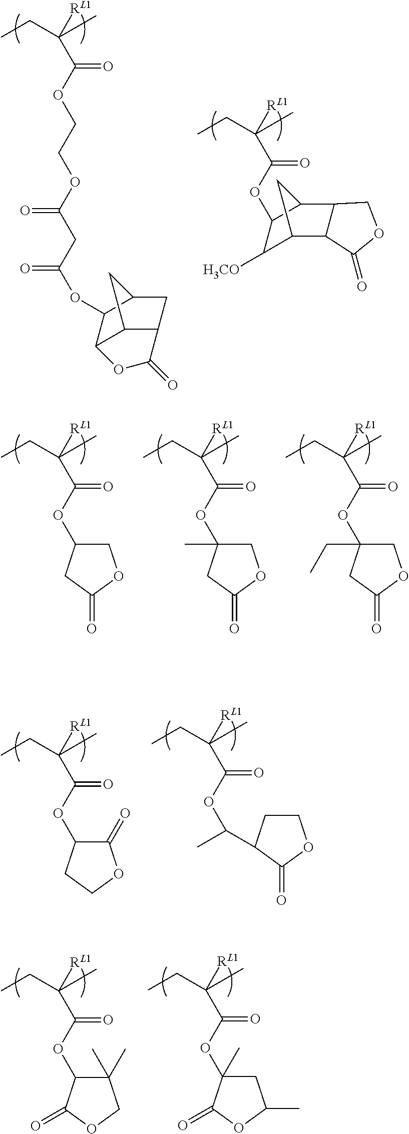

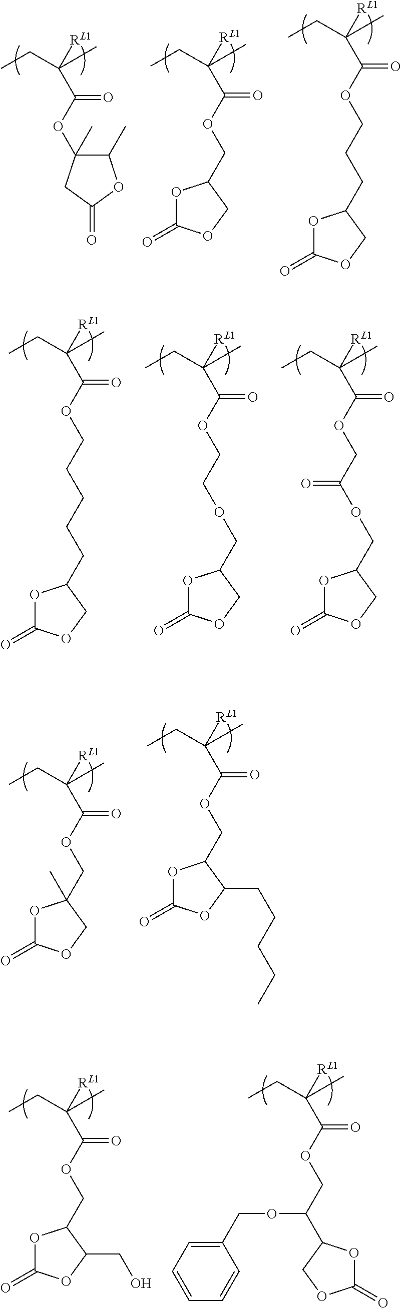

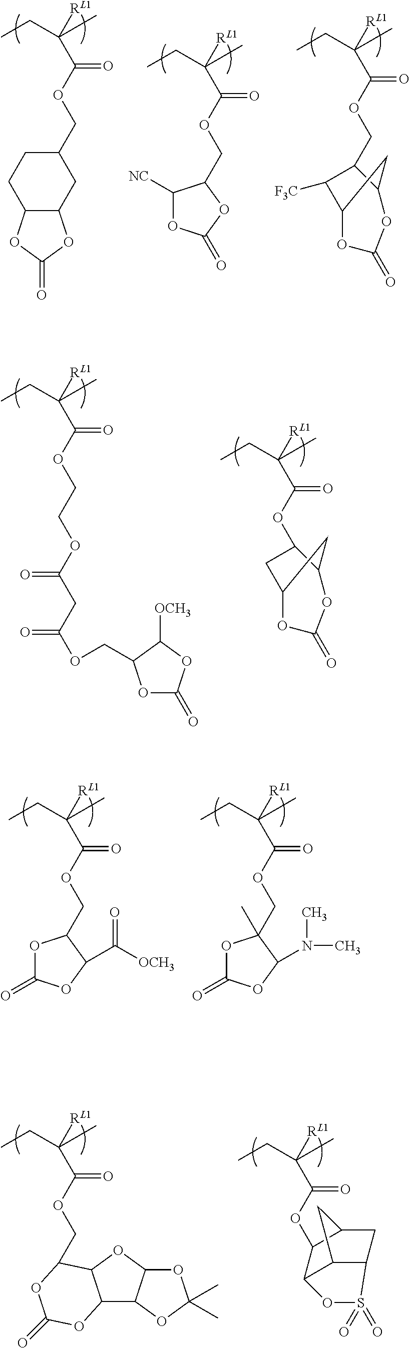

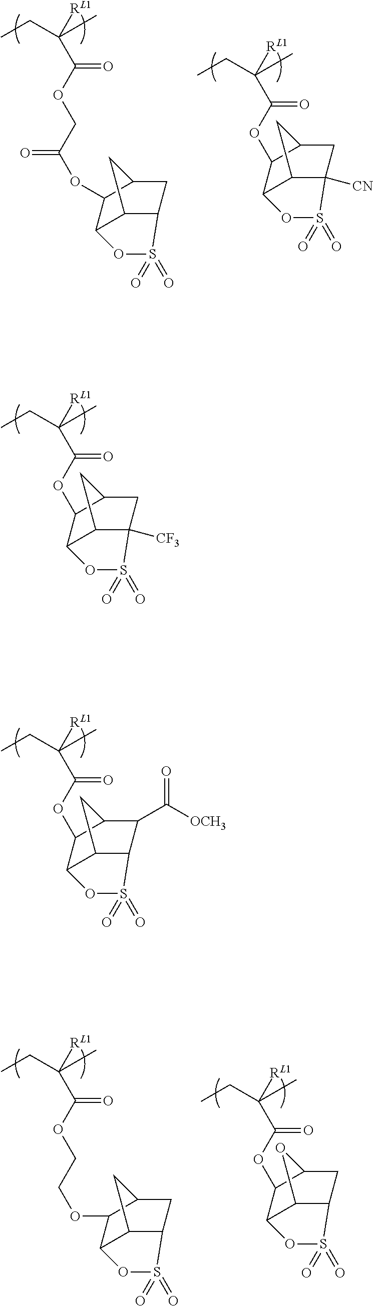

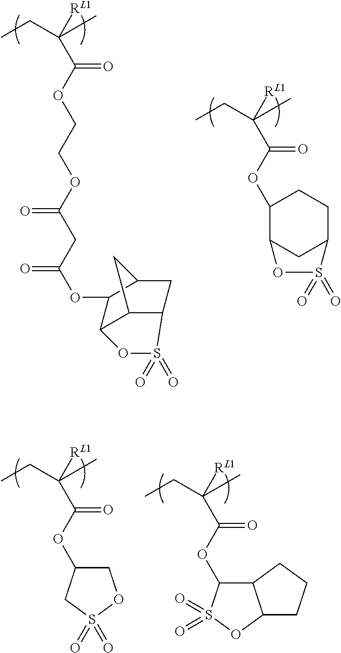

In the above formulae, R^{L1} represents a hydrogen atom, a fluorine atom, a methyl group or a trifluoromethyl group.

As the structural unit (II), a structural unit having a lactone structure is preferred, a structural unit derived from lactone-yl (meth)acrylate is more preferred, and a structural unit derived from norbornanelactone-yl (meth)acrylate, a structural unit derived from 5-cyano-norbornanelactone-yl (meth)acrylate, a structural unit derived from oxynorbornanelactone-yl (meth)acrylate and a structural unit derived from γ-butyrolactone-yl (meth)acrylate are still more preferred.

In a case where the polymer (A) has the structural unit (II), the lower limit of the proportion of the structural unit (II) with respect to the total structural units in the polymer (A) is preferably 10 mol %, more preferably 20 mol %, and still more preferably 30 mol %. The upper limit of the aforementioned proportion is preferably 80 mol %, more preferably 70 mol %, and still more preferably 60 mol %. When the proportion of the structural unit (II) falls within the above range, the LWR performances, etc. of the radiation-sensitive resin composition may be further improved. In addition, adhesiveness of the resulting resist pattern to a substrate may be further improved.

### Structural Unit (III)

The structural unit (III) includes a phenolic hydroxyl group. In a case where a KrF excimer laser beam, EUV, an electron beam or the like is used as a radioactive ray for irradiation in an exposure step of a resist pattern-forming method, when the polymer (A) has the structural unit (III), the sensitivity may be further enhanced.

Examples of the structural unit (III) include a structural unit represented by the following formula (a-3), and the like.

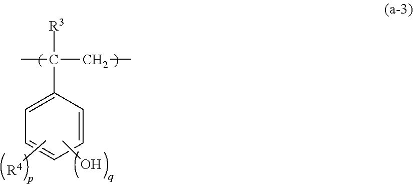

In the above formula (a-3), R³ represents a hydrogen atom or a methyl group; R⁴ represents a monovalent organic group having 1 to 20 carbon atoms; p is an integer of 0 to 3, wherein in a case where p is 2 or 3, a plurality of R⁴s may be identical or different; and q is an integer of 1 to 3, wherein the sum of p and q is no greater than 5.

The “organic group” as referred to means a group that includes at least one carbon atom.

R³ preferably represents the hydrogen atom in light of the copolymerizability of a monomer that gives the structural unit (III).

The monovalent organic group having 1 to 20 carbon atoms which is represented by R⁴ is exemplified by: a monovalent chain hydrocarbon group having 1 to 20 carbon atoms; a monovalent alicyclic hydrocarbon group having 3 to 20 carbon atoms; a monovalent aromatic hydrocarbon group having 6 to 20 carbon atoms; a group derived from the monovalent chain hydrocarbon group having 1 to 20 carbon atoms, the monovalent alicyclic hydrocarbon group having 3 to 20 carbon atoms, or the monovalent aromatic hydrocarbon group having 6 to 20 carbon atoms by substituting with a substituent, a part or all of hydrogen atoms included in these groups; a group derived from the monovalent chain hydrocarbon group having 1 to 20 carbon atoms, the monovalent alicyclic hydrocarbon group having 3 to 20 carbon atoms, or the monovalent aromatic hydrocarbon group having 6 to 20 carbon atoms by incorporating —CO—, —CS—, —O—, —S— or —NR″— or a combination of two or more thereof between two adjacent carbon atoms of these groups; and the like, wherein R″ represents a hydrogen atom or a monovalent organic group. Of these, the monovalent chain hydrocarbon group is preferred, an alkyl group is more preferred, and a methyl group is still more preferred.

In the above formula (a-3), p is preferably an integer of 0 to 2, more preferably 0 and 1, and still more preferably 0.

In the above formula (a-3), q is preferably 1 and 2, and more preferably 1.

Examples of the structural unit (III) include structural units represented by the following formulae (a-3-1) to (a-3-4) (hereinafter, may be also referred to as “structural units (III-1) to (III-4)”), and the like.

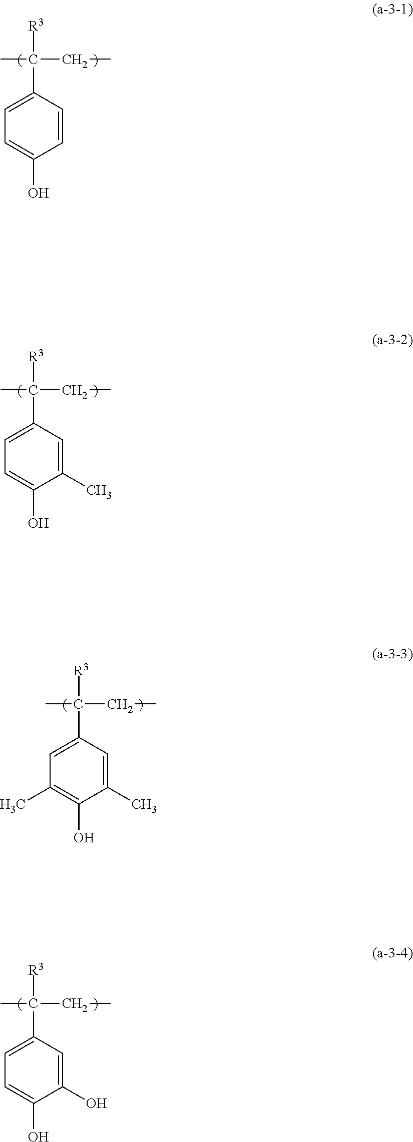

In the above formulae (a-3-1) to (a-3-4), R³ is as defined in the above formula (a-3).

As the structural unit (III), the structural unit (III-1) and the structural unit (III-2) are preferred, and the structural unit (III-1) is more preferred.

When the polymer (A) has the structural unit (III), the lower limit of the proportion of the structural unit (III) with respect to the total structural units constituting the polymer (A) is preferably 10 mol %, more preferably 30 mol %, and still more preferably 50 mol %. The upper limit of the aforementioned proportion is preferably 90 mol %, more preferably 80 mol %, and still more preferably 75 mol %. When the proportion of the structural unit (III) falls within the above range, the sensitivity of the radiation-sensitive resin composition may be further improved.

It is to be noted that the structural unit (III) can be formed, for example, by polymerizing a monomer derived from hydroxystyrene by substituting the hydrogen atom of the —OH group thereof with an acetyl group or the like and subsequently subjecting the resulting polymer to a hydrolysis reaction in the presence of a base such as an amine.

### Structural Unit (IV)

The structural unit (IV) includes an alcoholic hydroxyl group. When the polymer (A) includes the structural unit (IV), the solubility of the polymer (A) in a developer solution may be more appropriately regulated, and consequently the LWR performances, etc. of the radiation-sensitive resin composition may be more improved. Moreover, the adhesiveness of the resist pattern to the substrate may be further enhanced.

Examples of the structural unit (IV) include structural units represented by the following formulae, and the like.

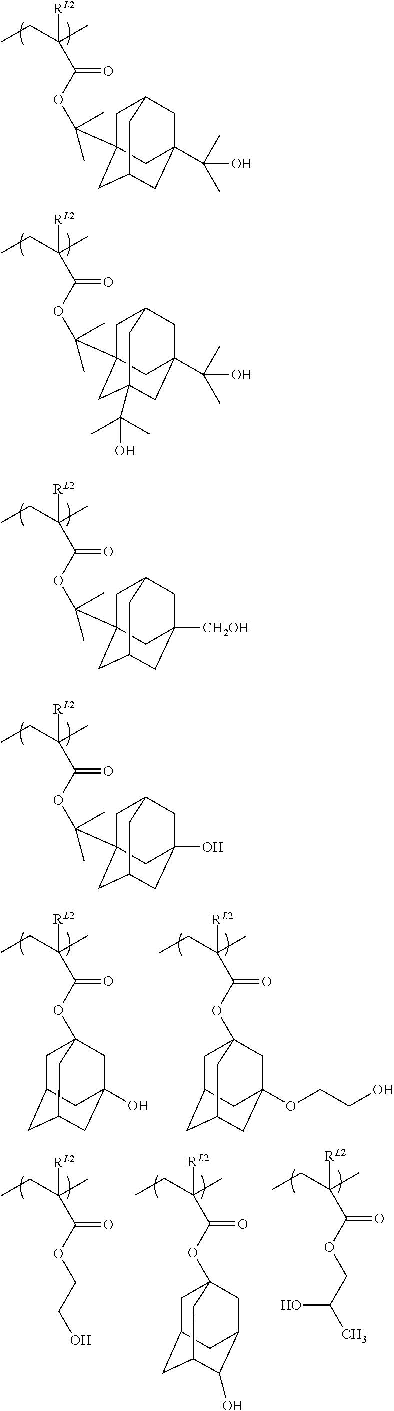

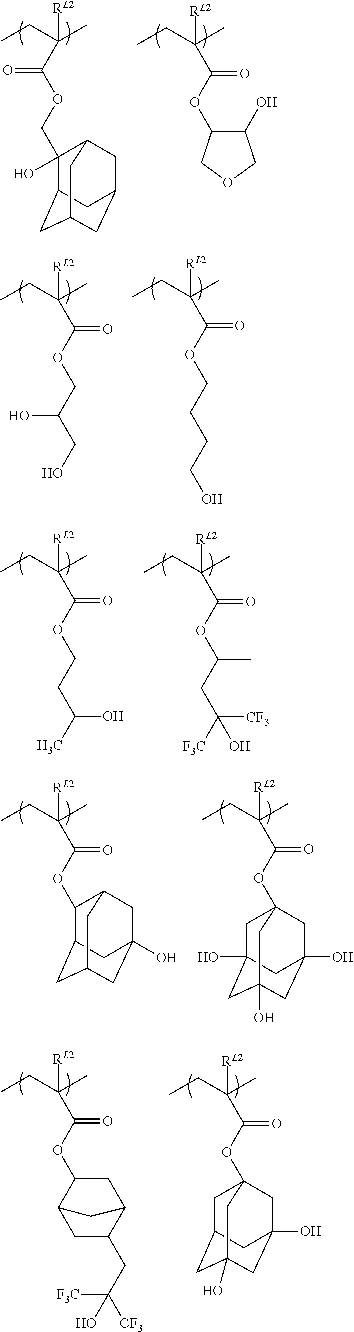

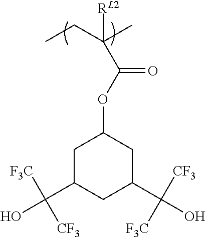

In the above formulae, R^{L2} represents a hydrogen atom, a fluorine atom, a methyl group or a trifluoromethyl group.

As the structural unit (IV), a structural unit that includes a hydroxyadamantyl group is preferred, and a structural unit derived from 3-hydroxyadamantyl (meth)acrylate is more preferred.

When the polymer (A) has the structural unit (IV), the lower limit of the proportion of the structural unit (IV) with respect to the total structural units constituting the polymer (A) is preferably 3 mol %, more preferably 5 mol %, and still more preferably 10 mol %. The upper limit of the aforementioned proportion is preferably 35 mol %, more preferably 30 mol %, and still more preferably 25 mol %. When the proportion of the structural unit (IV) falls within the above range, the LWR performances, etc. of the radiation-sensitive resin composition may be further improved. Moreover, the adhesiveness of the resist pattern to the substrate may be further enhanced.

### Other Structural Unit

The polymer (A) may have other structural unit than the structural units (I) to (IV). The other structural unit is exemplified by: a structural unit that includes a ketonic carbonyl group, a cyano group, a carboxy group, a nitro group, an amino group or a combination thereof; a structural unit derived from a (meth)acrylic acid ester that includes a nonlabile monovalent alicyclic hydrocarbon group; and the like. The upper limit of the proportion of the other structural unit with respect to the total structural units constituting the polymer (A) is preferably 20 mol %, and more preferably 10 mol %.

The lower limit of the content of the polymer (A) with respect to the total solid content of the radiation-sensitive resin composition is preferably 70% by mass, more preferably 80% by mass, and still more preferably 85% by mass. The “total solid content” as referred to means the sum of the components other than the solvent (E) in the radiation-sensitive resin composition.

### Synthesis Method of Polymer (A)

The polymer (A) may be synthesized, for example, by polymerizing each monomer that gives each structural unit in an appropriate solvent using a radical polymerization initiator or the like.

Examples of the radical polymerization initiator include:

azo radical initiators such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile) and dimethyl 2,2′-azobisisobutyrate;

peroxide radical initiators such as benzoyl peroxide, t-butyl hydroperoxide and cumene hydroperoxide; and the like. Of these, AIBN and dimethyl 2,2′-azobisisobutyrate are preferred, and AIBN is more preferred. These radical polymerization initiators may be used either alone, or as a mixture of two or more types thereof.

Examples of the solvent for use in the polymerization include:

alkanes such as n-pentane, n-hexane, n-heptane, n-octane, n-nonane and n-decane;

cycloalkanes such as cyclohexane, cycloheptane, cyclooctane, decalin and norbornane;

aromatic hydrocarbons such as benzene, toluene, xylene, ethylbenzene and cumene;

halogenated hydrocarbons such as chlorobutane, bromohexane, dichloroethane, hexamethylene dibromide and chlorobenzene;

saturated carboxylic acid esters such as ethyl acetate, n-butyl acetate, i-butyl acetate and methyl propionate;

ketones such as acetone, methyl ethyl ketone, 4-methyl-2-pentanone and 2-heptanone;

ethers such as tetrahydrofuran, dimethoxyethanes and diethoxyethanes;

alcohols such as methanol, ethanol, 1-propanol, 2-propanol and 4-methyl-2-pentanol; and the like. These solvents for use in the polymerization may be used either alone of one type, or two or more types thereof may be used in combination.

The lower limit of the reaction temperature in the polymerization is preferably 40° C., and more preferably 50° C. The upper limit of the reaction temperature is preferably 150° C., and more preferably 120° C. The lower limit of the reaction time period in the polymerization is preferably 1 hour, and more preferably 2 hrs. The upper limit of the reaction time period is preferably 48 hrs, and more preferably 24 hrs.

The lower limit of the polystyrene equivalent weight average molecular weight (Mw) as determined by gel permeation chromatography (GPC) of the polymer (A) is preferably 1,000, more preferably 2,000, still more preferably 2,500, and particularly preferably 3,000. The upper limit of the Mw is preferably 50,000, more preferably 30,000, still more preferably 20,000, and particularly preferably 15,000. When the Mw of the polymer (A) falls within the above range, the application property and the development defects-inhibiting effect of the radiation-sensitive resin composition may be improved.

The lower limit of the ratio (Mw/Mn) of the Mw to the polystyrene equivalent number average molecular weight (Mn) as determined by GPC of the polymer (A) is typically 1, and preferably 1.1. The upper limit of the aforementioned ratio is preferably 5, more preferably 3, and still more preferably 2.

The Mw and the Mn of the polymer as referred to herein mean a value determined by GPC under the following conditions:

GPC columns: “G2000 HXL”×2, “G3000 HXL”×1 and “G4000 HXL”×1 available from Tosoh Corporation, for example;

column temperature: 40° C.;

elution solvent: tetrahydrofuran;

flow rate: 1.0 mL/min;

sample concentration: 1.0% by mass;

amount of injected sample: 100 μL;

detector: differential refractometer; and

standard substance: mono-dispersed polystyrene.

### (B) Acid Generator

The acid generator (B) is a substance that generates an acid upon an exposure. The acid thus generated allows an acid-labile group included in the polymer (A) or the like to be dissociated, thereby generating a carboxy group, a hydroxy group or the like. As a result, the solubility of the polymer (A) in a developer solution is altered, and thus a resist pattern can be formed from the radiation-sensitive resin composition. The acid generator (B) may be contained in the radiation-sensitive resin composition either in the form of a low-molecular-weight compound (hereinafter, may be also referred to as “(B) acid generating agent” or “acid generating agent (B)”, as appropriate), or in the form of an acid generator incorporated as a part of the polymer, or may be in both of these forms.

The acid generating agent (B) is exemplified by an onium salt compound, a N-sulfonyloxyimide compound, a sulfonimide compound, a halogen-containing compound, a diazo ketone compound, and the like.

The onium salt compound is exemplified by a sulfonium salt, a tetrahydrothiophenium salt, an iodonium salt, a phosphonium salt, a diazonium salt, a pyridinium salt, and the like.

Specific examples of the acid generating agent (B) include compounds disclosed in paragraphs [0080] to [0113] of Japanese Unexamined Patent Application, Publication No. 2009-134088, and the like.

The acid generated from the acid generator (B) is exemplified by a sulfonic acid, an imide acid, an amide acid, a methide acid, a phosphinic acid, a carboxylic acid, and the like. Of these, the sulfonic acid, the imide acid, the amide acid and the methide acid are preferred.

The acid generating agent (B) is exemplified by a compound represented by the following formula (3) (hereinafter, may be also referred to as “(B1) acid generating agent” or “acid generating agent (B1)”), and the like.

A⁻X⁺ (3)

In the above formula (3), A⁻ represents a monovalent sulfonic acid anion, a monovalent imide acid anion, a monovalent amide acid anion or a monovalent methide acid anion; and X⁺ represents a monovalent onium cation.

In a case where A⁻ in the above formula (3) represents the sulfonic acid anion, the sulfonic acid is generated from the acid generating agent (B1). In a case where A⁻ represents the imide acid anion, the imide acid is generated from the acid generating agent (B1). In a case where A⁻ represents the amide acid anion, the amide acid is generated from the acid generating agent (B1). In a case where A⁻ represents the methide acid anion, the methide acid is generated from the acid generating agent (B1).

The acid generating agent (B1) in which A⁻ represents the sulfonic acid anion is exemplified by a compound represented by the following formula (4) (hereinafter, may be also referred to as “compound (4)”), and the like. When the acid generating agent (B1) has the following structure, it is expected that a diffusion length of the acid generated upon the exposure in the resist film will be more properly decreased through e.g., an interaction with the structural unit (I) of the polymer (A) or the like, and consequently the LWR performances, etc. of the radiation-sensitive resin composition may be more improved.

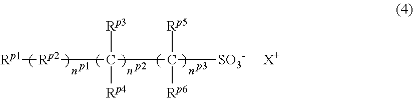

In the above formula (4), R^{p1} represents a monovalent group that includes a ring structure having 6 or more ring atoms; R^{p2} represents a divalent linking group; R^{p3} and R^{p4} each independently represent a hydrogen atom, a fluorine atom, a monovalent hydrocarbon group having 1 to 20 carbon atoms or a monovalent fluorinated hydrocarbon group having 1 to 20 carbon atoms; R^{p5} and R^{p6} each independently represent a fluorine atom or a monovalent fluorinated hydrocarbon group having 1 to 20 carbon atoms; n^{p1} is an integer of 0 to 10; n^{p2} is an integer of 0 to 10; n^{p3} is an integer of 0 to 10, wherein the sum of n^{p1}, n^{p2} and n^{p3} is no less than 1 and no greater than 30, and wherein in a case where n^{p1} is no less than 2, a plurality of R^{p2}s may be identical or different, in a case where n^{p2} is no less than 2, a plurality of R^{p3}s may be identical or different and a plurality of R^{p4}s may be identical or different, and in a case where n^{p3} is no less than 2, a plurality of R^{p5}s may be identical or different and a plurality of R^{p6}s may be identical or different; and X⁺ is as defined in the above formula (3).

The monovalent group that includes a ring structure having 6 or more ring atoms which is represented by R^{p1} is exemplified by: a monovalent group that includes an alicyclic structure having 6 or more ring atoms; a monovalent group that includes an aliphatic heterocyclic structure having 6 or more ring atoms; a monovalent group that includes an aromatic ring structure having 6 or more ring atoms; a monovalent group that includes an aromatic heterocyclic structure having 6 or more ring atoms; and the like.

Examples of the alicyclic structure having 6 or more ring atoms include: monocyclic cycloalkane structures such as a cyclohexane structure, a cycloheptane structure, a cyclooctane structure, a cyclononane structure, a cyclodecane structure and a cyclododecane structure;

monocyclic cycloalkene structures such as a cyclohexene structure, a cycloheptene structure, a cyclooctene structure and a cyclodecene structure;

polycyclic cycloalkane structures such as a norbornane structure, an adamantane structure, a tricyclodecane structure and a tetracyclododecane structure;

polycyclic cycloalkene structures such as a norbornene structure and a tricyclodecene structure; and the like.

Examples of the aliphatic heterocyclic structure having 6 or more ring atoms include:

lactone structures such as a hexanolactone structure and a norbornanelactone structure;

sultone structures such as a hexanosultone structure and a norbornanesultone structure;

oxygen atom-containing heterocyclic structures such as an oxacycloheptane structure and an oxanorbornane structure;

nitrogen atom-containing heterocyclic structures such as an azacyclohexane structure and a diazabicyclooctane structure;

sulfur atom-containing heterocyclic structures such as a thiacyclohexane structure and a thianorbornane structure; and the like.

Examples of the aromatic ring structure having 6 or more ring atoms include a benzene structure, a naphthalene structure, a phenanthrene structure, an anthracene structure, and the like.

Examples of the aromatic heterocyclic structure having 6 or more ring atoms include:

oxygen atom-containing heterocyclic structures such as a furan structure, a pyran structure and a benzopyran structure;

nitrogen atom-containing heterocyclic structures such as a pyridine structure, a pyrimidine structure and an indole structure; and the like.

The lower limit of the number of ring atoms of the ring structure included in R^{p1} is preferably 7, more preferably 8, still more preferably 9, and particularly preferably 10. The upper limit of the number of ring atoms is preferably 15, more preferably 14, still more preferably 13, and particularly preferably 12. When the number of ring atoms falls within the above range, the aforementioned diffusion length of the acid may be further properly decreased, and consequently the LWR performances, etc. of the radiation-sensitive resin composition may be more improved.

A part or all of hydrogen atoms included in the ring structure of R′′ may be substituted with a substituent. Examples of the substituent include halogen atoms such as a fluorine atom, a chlorine atom, a bromine atom and an iodine atom, a hydroxy group, a carboxy group, a cyano group, a nitro group, an alkoxy group, an alkoxycarbonyl group, an alkoxycarbonyloxy group, an acyl group, an acyloxy group, and the like. Of these, the hydroxy group is preferred.

R^{p1} represents preferably a monovalent group that includes an alicyclic structure having 6 or more ring atoms or a monovalent group that includes an aliphatic heterocyclic structure having 6 or more ring atoms, more preferably a monovalent group that includes an alicyclic structure having 9 or more ring atoms or a monovalent group that includes an aliphatic heterocyclic structure having 9 or more ring atoms, still more preferably an adamantyl group, a hydroxyadamantyl group, a norbornanelactone-yl group, a norbornanesultone-yl group and a 5-oxo-4-oxatricyclo[4.3.1.1^{3,8}]undecan-yl group, and particularly preferably an adamantyl group.

Examples of the divalent linking group represented by R^{p2} include a carbonyl group, an ether group, a carbonyloxy group, a sulfide group, a thiocarbonyl group, a sulfonyl group, a divalent hydrocarbon group, and the like. Of these, the carbonyloxy group, the sulfonyl group, an alkanediyl group and a cycloalkanediyl group are preferred, the carbonyloxy group and the cycloalkanediyl group are more preferred, the carbonyloxy group and a norbornanediyl group are still more preferred, and the carbonyloxy group is particularly preferred.

The monovalent hydrocarbon group having 1 to 20 carbon atoms which may be represented by R^{p3} and R^{p4} is exemplified by an alkyl group having 1 to 20 carbon atoms, and the like. The monovalent fluorinated hydrocarbon group having 1 to 20 carbon atoms which may be represented by R^{p3} and R^{p4} is exemplified by a fluorinated alkyl group having 1 to 20 carbon atoms, and the like. R^{p3} and R^{p4} each independently represent preferably a hydrogen atom, a fluorine atom or a fluorinated alkyl group, more preferably a fluorine atom or a perfluoroalkyl group, and still more preferably a fluorine atom or a trifluoromethyl group.

The monovalent fluorinated hydrocarbon group having 1 to 20 carbon atoms which may be represented by R^{p5} and R^{p6} is exemplified by a fluorinated alkyl group having 1 to 20 carbon atoms, and the like. R^{p5} and R^{p6} each independently represent preferably a fluorine atom or a fluorinated alkyl group, more preferably a fluorine atom or a perfluoroalkyl group, still more preferably a fluorine atom or a trifluoromethyl group, and particularly preferably a fluorine atom.

In the above formula (4), n^{p1} is preferably an integer of 0 to 5, more preferably an integer of 0 to 3, still more preferably an integer of 0 to 2, and particularly preferably 0 or 1.

In the above formula (4), n^{p2} is preferably an integer of 0 to 5, more preferably an integer of 0 to 2, still more preferably 0 or 1, and particularly preferably 0.

The lower limit of n^{p3} is preferably 1, and more preferably 2. When n^{p3} is no less than 1, the strength of the acid generated from the compound (4) may be increased, and consequently the LWR performances, etc. of the radiation-sensitive resin composition may be more improved. The upper limit of n^{p3} is preferably 4, more preferably 3, and still more preferably 2.

The lower limit of the sum of n^{p1}, n^{p2} and n^{p3} is 1, preferably 2, and more preferably 4. The upper limit of the sum of n^{p1}, n^{p2} and n^{p3} is 30, preferably 20, and more preferably 10.

The acid generating agent (B1) in which A⁻ represents the imide acid anion is exemplified by a compound represented by the following formula (5) (hereinafter, may be also referred to as “compound (5)”), and the like.

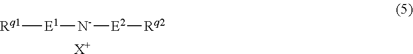

In the above formula (5), R^{q1} and R^{q2} each independently represent a monovalent organic group having 1 to 20 carbon atoms and a fluorine atom, or R^{q1} and R^{q2} taken together represent a ring structure having 4 to 20 ring atoms together with the atom chain to which R^{q1} and R^{q2} bond; E¹ and E² each independently represent —SO₂— or —CO—; and X⁺ is as defined in the above formula (3).

The acid generating agent (B1) in which A⁻ represents the amide acid anion is exemplified by a compound represented by the following formula (6) (hereinafter, may be also referred to as “compound (6)”), and the like.

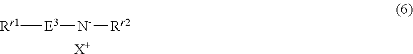

In the above formula (6), R^{r1} and R^{r2} each independently represent a monovalent organic group having 1 to 20 carbon atoms and a fluorine atom, or R^{r1} and R^{r2} taken together represent a ring structure having 4 to 20 ring atoms together with the atom chain to which R^{r1} and R^{r2} bond; E³ represents —SO₂— or —CO—; and X⁺ is as defined in the above formula (3).

The acid generating agent (B1) in which A⁻ represents the methide acid anion is exemplified by a compound represented by the following formula (7) (hereinafter, may be also referred to as “compound (7)”), and the like.

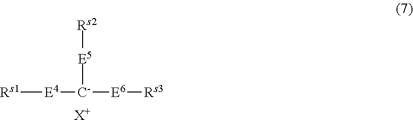

In the above formula (7), R^{s1}, R^{s2} and R^{s3} each independently represent a monovalent organic group having 1 to 20 carbon atoms and a fluorine atom, or at least two of R^{s1}, R^{s2} and R^{s3} taken together represent a ring structure having 4 to 20 ring atoms together with the atom chain to which the at least two of R^{s1}, R^{s2} and R^{s3} bond; E⁴, E⁵ and E⁶ each independently represents —SO₂— or —CO—; and X⁺ is as defined in the above formula (3).

Examples of the monovalent organic group having 1 to 20 carbon atoms and a fluorine atom which may be represented by R^{q1} or R^{q2}, R^{r1} or R^{r2}, or R^{s1}, R^{s2} or R^{s3} include monovalent fluorinated hydrocarbon groups having 1 to 20 carbon atoms, and the like. Of these, a fluorinated alkyl group having 1 to 20 carbon atoms is preferred, a fluorinated alkyl group having 1 to 4 carbon atoms is more preferred, a perfluoroalkyl group having 1 to 4 carbon atoms is still more preferred, and a trifluoromethyl group and a nonafluorobutyl group are particularly preferred.

Examples of the group taken together represented by R^{q1} and R^{q2}, R^{r1} and R^{r2}, or R^{s1} and R^{s2} include divalent fluorinated hydrocarbon groups having 2 to 20 carbon atoms, and the like. Of these, a fluorinated alkanediyl group having 2 to 20 carbon atoms is preferred, a fluorinated alkanediyl group having 2 to 4 carbon atoms is more preferred, a perfluoroalkanediyl group having 2 to 4 carbon atoms is still more preferred, and a hexafluoropropanediyl group is particularly preferred.

In light of the strength of the acid generated from the acid generating agent (B), E¹ to E⁶ each independently represent preferably —SO₂—.

The monovalent onium cation represented by X⁺ is typically a radiation-sensitive onium cation, more specifically, a cation that is degraded upon irradiation with a radioactive ray. In light-exposed regions, an acid such as a sulfonic acid is generated from an acid anion such as a sulfonate anion and a proton generated through the degradation of the radiation-sensitive onium cation. The radiation-sensitive onium cation is exemplified by a sulfonium cation, an iodonium cation, and the like. The sulfonium cation is exemplified by a cation represented by the following formula (b-1) (hereinafter, may be also referred to as “cation (b-1)”), and the like. The iodonium cation is exemplified by a cation represented by the following formula (b-2) (hereinafter, may be also referred to as “cation (b-2)”), and the like.

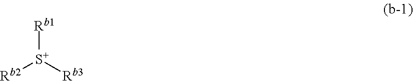

In the above formula (b-1), R^{b1}, R^{b2} and R^{b3} each independently represent a substituted or unsubstituted alkyl group having 1 to 10 carbon atoms, or a substituted or unsubstituted aryl group having 6 to 18 carbon atoms, or at least two of R^{b1}, R^{b2} and R^{b3} taken together represent a ring structure having 3 to 20 ring atoms together with the sulfur atom to which the at least two of R^{b1}, R^{b2} and R^{b3} bond.

R^{b4}—I⁺—R^{b5} (b-2)

In the above formula (b-2), R^{b4} and R^{b5} each independently represent a substituted or unsubstituted alkyl group having 1 to 10 carbon atoms, or a substituted or unsubstituted aryl group having 6 to 18 carbon atoms, or R^{b4} and R^{b5} taken together represent a ring structure having 3 to 20 ring atoms together with the iodine atom to which R^{b4} and R^{b5} bond.

The cation (b-1) is exemplified by a cation represented by the following formula (X-1) (hereinafter, may be also referred to as “cation (X-1)”), a cation represented by the following formula (X-2) (hereinafter, may be also referred to as “cation (X-2)”), and the like. The cation (b-2) is exemplified by a cation represented by the following formula (X-3) (hereinafter, may be also referred to as “cation (X-3)”), and the like.

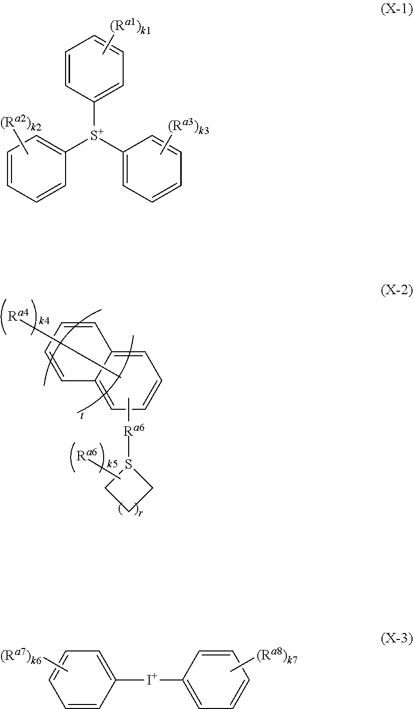

In the above formula (X-1), R^{a1}, R^{a2} and R^{a3} each independently represent a substituted or unsubstituted alkyl group having 1 to 12 carbon atoms, a substituted or unsubstituted aromatic hydrocarbon group having 6 to 12 carbon atoms, —OSO₂—R^{P} or —SO₂—R^{Q}, or at least two of R^{a1}, R^{a2} and R^{a3} taken together represent a ring structure; R^{P} and R^{Q} each independently represent a substituted or unsubstituted alkyl group having 1 to 12 carbon atoms, a substituted or unsubstituted alicyclic hydrocarbon group having 5 to 25 carbon atoms or a substituted or unsubstituted aromatic hydrocarbon group having 6 to 12 carbon atoms; and k1, k2 and k3 are each independently an integer of 0 to 5, wherein R^{a1} to R^{a3}, and R^{P} and R^{Q} are each present in a plurality of number, a plurality of R^{a1}s may be identical or different, a plurality of R^{a1}s may be identical or different, a plurality of R^{a3}s may be identical or different, a plurality of R^{P}s may be identical or different, and a plurality of R^{Q}s may be identical or different.

In the above formula (X-2), R^{a4} represents a substituted or unsubstituted alkyl group having 1 to 8 carbon atoms, or a substituted or unsubstituted aromatic hydrocarbon group having 6 to 8 carbon atoms; k4 is an integer of 0 to 7, wherein in a case where R^{a4} is present in a plurality of number, a plurality of R^{a4}s may be identical or different, or a plurality of R^{a4}s may taken together represent a ring structure; R^{a5} represents a substituted or unsubstituted alkyl group having 1 to 7 carbon atoms, or a substituted or unsubstituted aromatic hydrocarbon group having 6 or 7 carbon atoms; k5 is an integer of 0 to 6, wherein in a case where R^{a5} is present in a plurality of number, a plurality of R^{a5}s may be identical or different, or a plurality of R^{a5}s may taken together represent a ring structure; r is an integer of 0 to 3; R^{a6} represents a single bond or a divalent organic group having 1 to 20 carbon atoms; and t is an integer of 0 to 2.

In the above formula (X-3), R^{a7} and R^{a8} each independently represent a substituted or unsubstituted alkyl group having 1 to 12 carbon atoms, a substituted or unsubstituted aromatic hydrocarbon group having 6 to 12 carbon atoms, —OSO₂—R^{R} or —SO₂—R^{S}, or at least two of R^{a7}s taken together represent a ring structure and/or at least two of R^{a8}s taken together represent a ring structure; R^{R} and R^{S} each independently represent a substituted or unsubstituted alkyl group having 1 to 12 carbon atoms, a substituted or unsubstituted alicyclic hydrocarbon group having 5 to 25 carbon atoms or a substituted or unsubstituted aromatic hydrocarbon group having 6 to 12 carbon atoms; and k6 and k7 are each independently an integer of 0 to 5, wherein in a case where R^{a7}, R^{a8}, R^{R} and R^{S} are each present in a plurality of number, a plurality of R^{a7}s may be identical or different, a plurality of R^{a8}s may be identical or different, a plurality of R^{R}s may be identical or different, and a plurality of R^{S}s may be identical or different.

Examples of the alkyl group which may be represented by R^{a1}, R^{a2}, R^{a3}, R^{a4}, R^{a5}, R^{a7} or R^{a5} include:

linear alkyl groups such as a methyl group, an ethyl group, a n-propyl group and a n-butyl group;

branched alkyl groups such as an i-propyl group, an i-butyl group, a sec-butyl group and a t-butyl group; and the like.

Examples of the aromatic hydrocarbon group which may be represented by R^{a1}, R^{a2}, R^{a3}, R^{a4} or R^{a5} include:

aryl groups such as a phenyl group, a tolyl group, a xylyl group, a mesityl group and a naphthyl group;

aralkyl groups such as a benzyl group and a phenethyl group; and the like.

Examples of the aromatic hydrocarbon group which may be represented by R^{a4} and R^{a5} include a phenyl group, a tolyl group, a benzyl group, and the like.

Examples of the divalent organic group which may be represented by R^{a6} include groups derived by removing one hydrogen atom from the monovalent organic group represented by R⁴ in the above formula (a-3), and the like.

Examples of the substituent which may substitute for a hydrogen atom included in the alkyl group or the aromatic hydrocarbon group include halogen atoms such as a fluorine atom, a chlorine atom, a bromine atom and an iodine atom, a hydroxy group, a carboxy group, a cyano group, a nitro group, an alkoxy group, an alkoxycarbonyl group, an alkoxycarbonyloxy group, an acyl group, an acyloxy group, and the like. Of these, the halogen atoms are preferred, and the fluorine atom is more preferred.

R^{a1} to R^{a3}, R^{a4}, R^{a5}, R^{a7} and R^{a8} each independently represent preferably an unsubstituted alkyl group, a fluorinated alkyl group, an unsubstituted monovalent aromatic hydrocarbon group, —OSO₂—R″ or —SO₂—R″, more preferably a fluorinated alkyl group or an unsubstituted monovalent aromatic hydrocarbon group, and still more preferably the fluorinated alkyl group. R″ represents the unsubstituted monovalent alicyclic hydrocarbon group or the unsubstituted monovalent aromatic hydrocarbon group.

In the formula (X-1), k1, k2 and k3 each independently preferably an integer of 0 to 2, more preferably 0 or 1, and still more preferably 0. In the formula (X-2), k4 is preferably an integer of 0 to 2, more preferably 0 and 1, and still more preferably 1, k5 is preferably an integer of 0 to 2, more preferably 0 and 1, and still more preferably 0, r is preferably 2 and 3, and more preferably 2, and t is preferably 0 and 1, and more preferably 0. In the formula (X-3), k6 and k7 are each independently preferably an integer of 0 to 2, more preferably 0 and 1, and still more preferably 0.

Of these, X⁺ represents preferably the cation (X-1) or the cation (X-2), and more preferably a triphenylsulfonium cation or a 1-[2-(4-cyclohexylphenylcarbonyl)propan-2-yl]tetrahydrothiophenium cation.

The sulfonium cation is exemplified by cations represented by the following formulae (i-1) to (i-65) (hereinafter, may be also referred to as “cations (i-1) to (i-65)”), and the like.

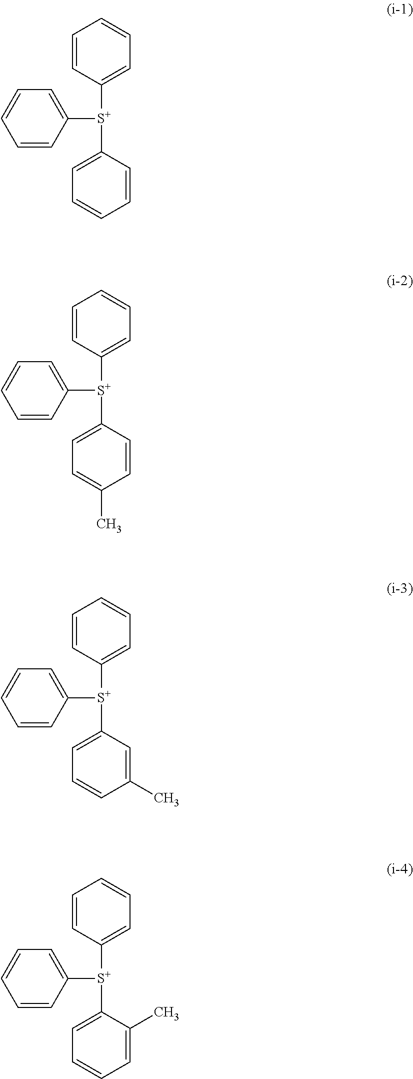 [SMILES: c1ccc([S+](c2ccccc2)c2ccccc2)cc1 ; Cc1ccc([S+](c2ccccc2)c2ccccc2)cc1 ; Cc1cccc([S+](c2ccccc2)c2ccccc2)c1 ; Cc1ccccc1[S+](c1ccccc1)c1ccccc1]

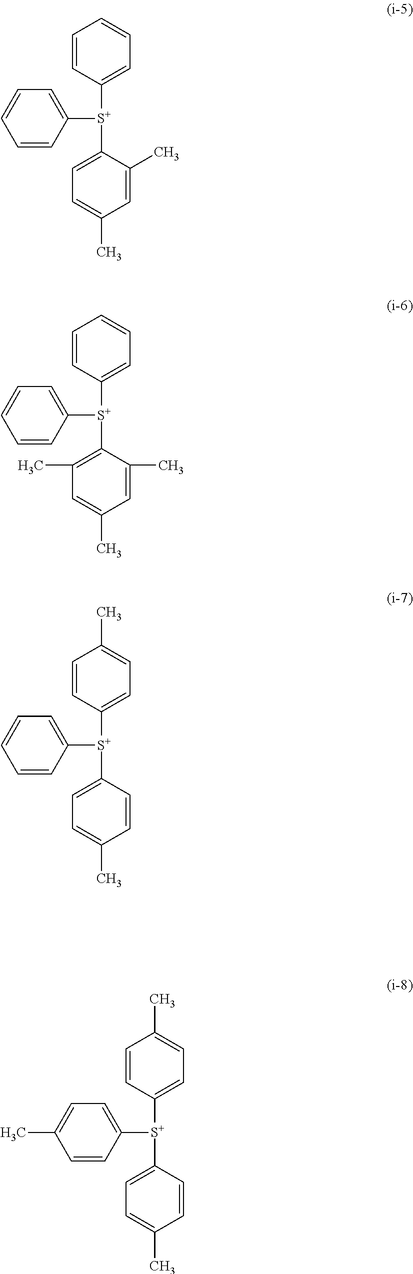

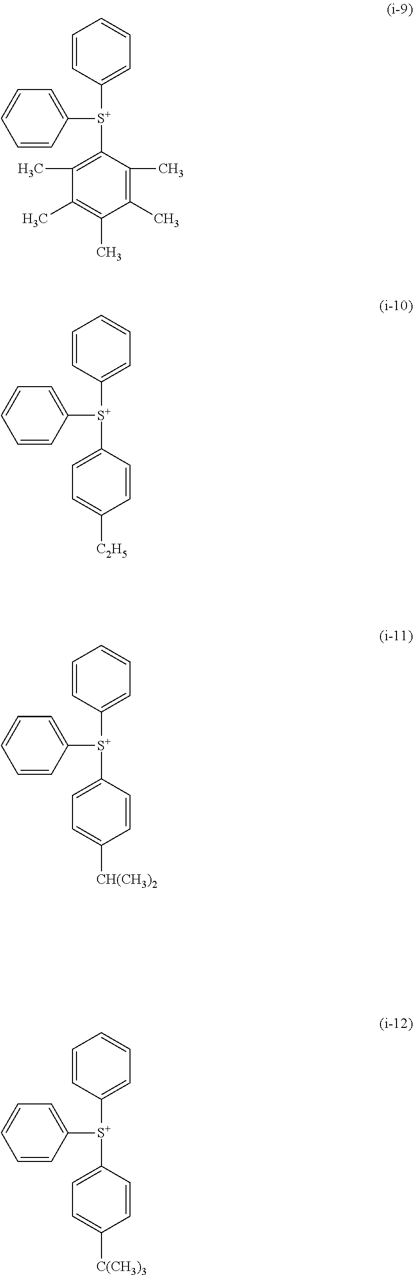 [SMILES: Cc1c(C)c(C)c([S+](c2ccccc2)c2ccccc2)c(C)c1C ; CCc1ccc([S+](c2ccccc2)c2ccccc2)cc1 ; CC(C)c1ccc([S+](c2ccccc2)c2ccccc2)cc1 ; CC(C)(C)c1ccc([S+](c2ccccc2)c2ccccc2)cc1]

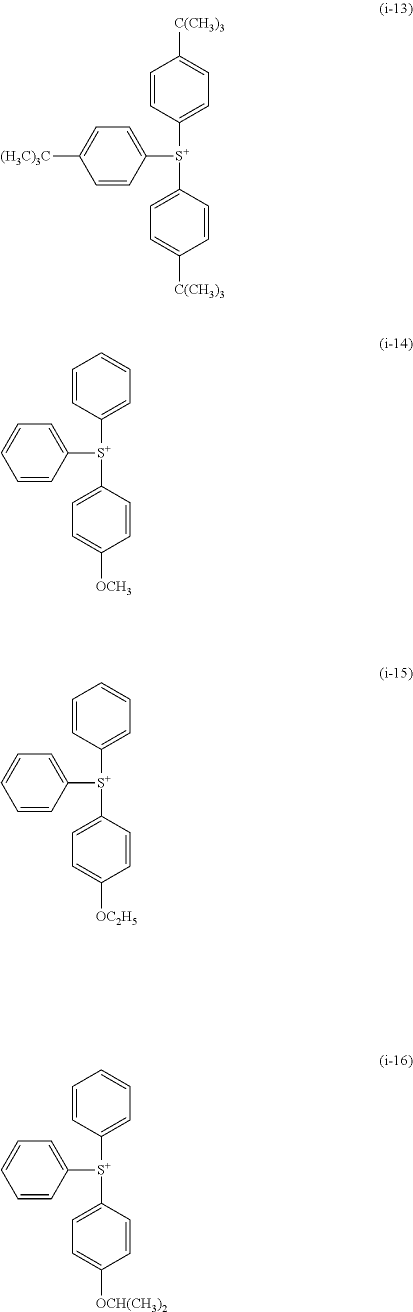

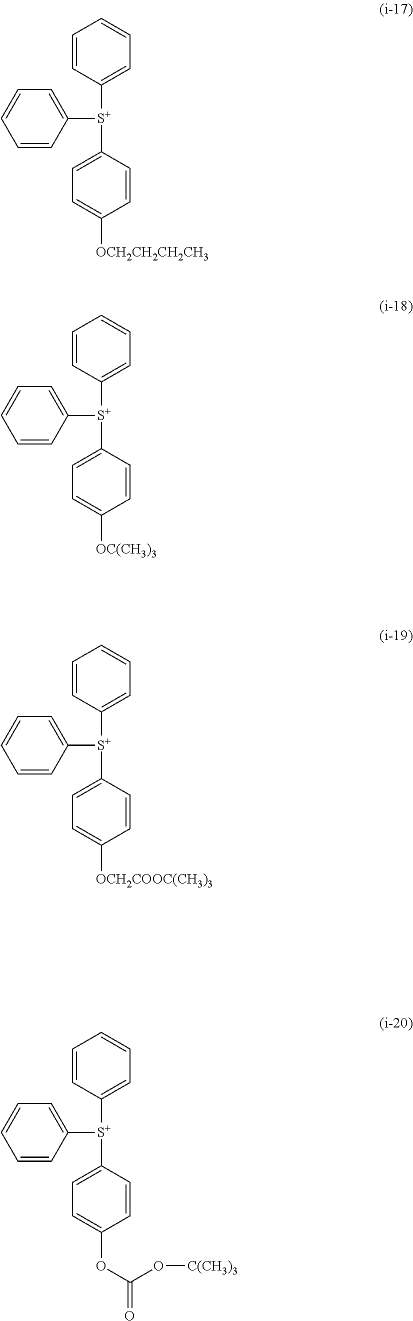

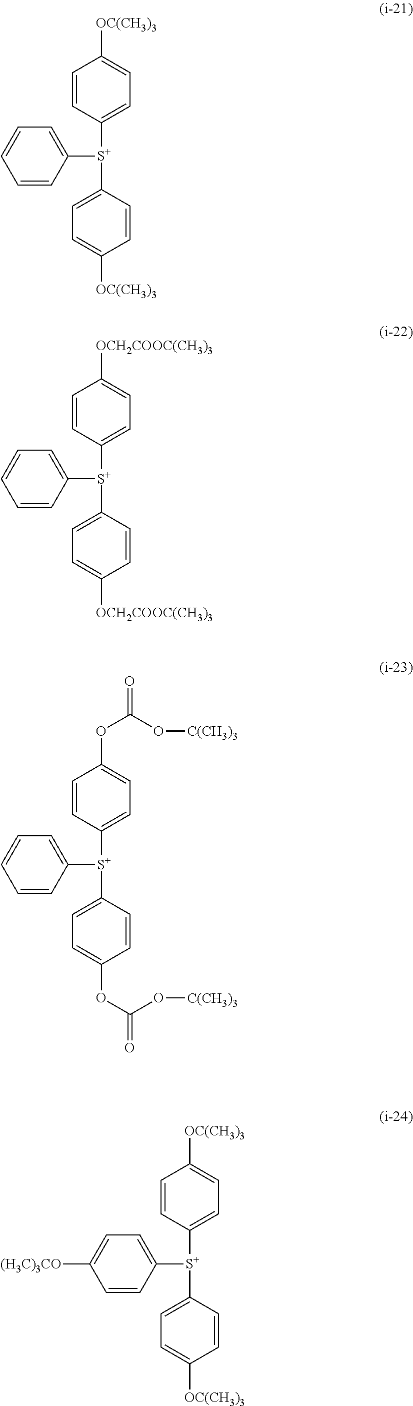

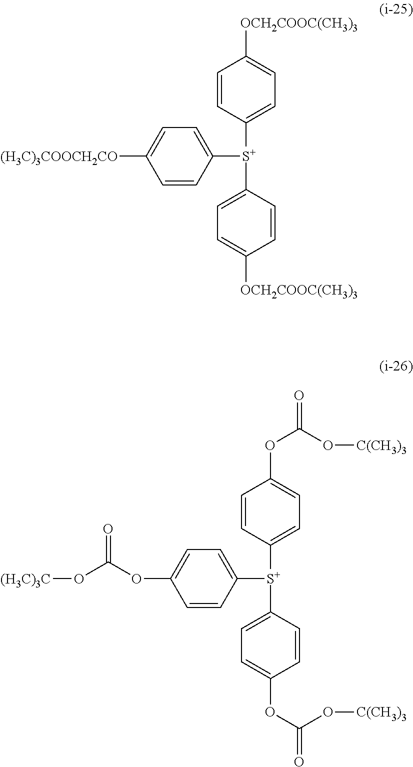

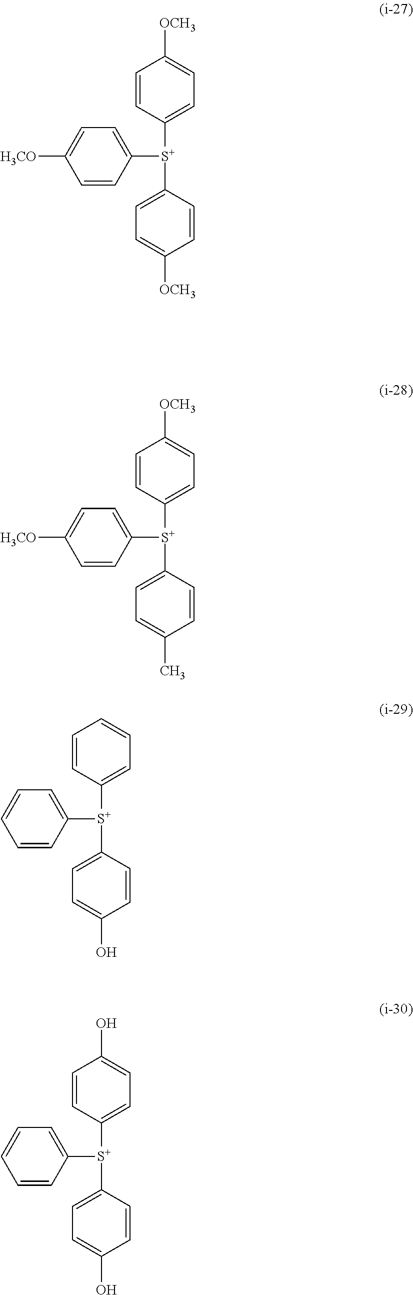 [SMILES: COc1ccc([S+](c2ccc(OC)cc2)c2ccc(OC)cc2)cc1 ; COc1ccc([S+](c2ccc(C)cc2)c2ccc(OC)cc2)cc1 ; Oc1ccc([S+](c2ccccc2)c2ccccc2)cc1 ; Oc1ccc([S+](c2ccccc2)c2ccc(O)cc2)cc1]

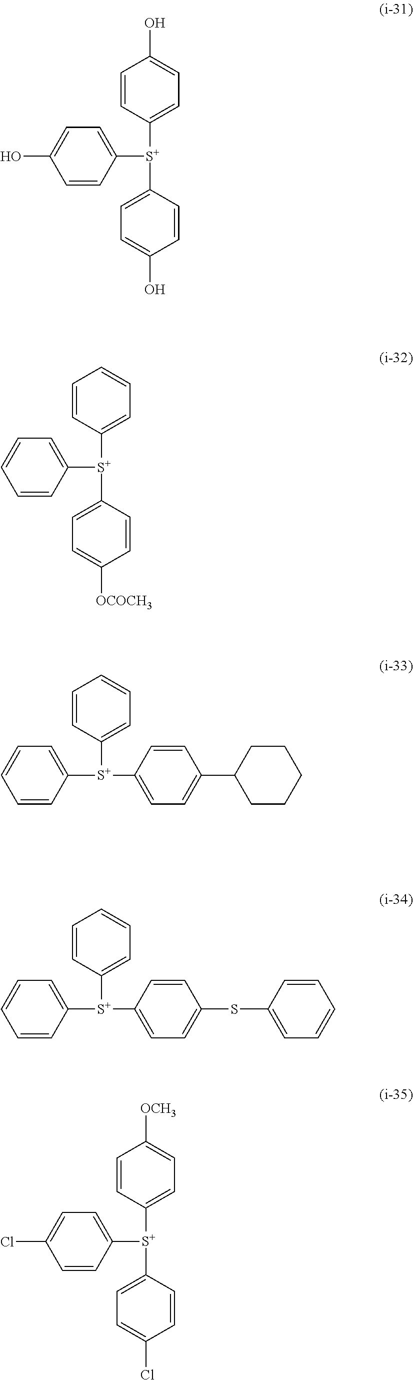

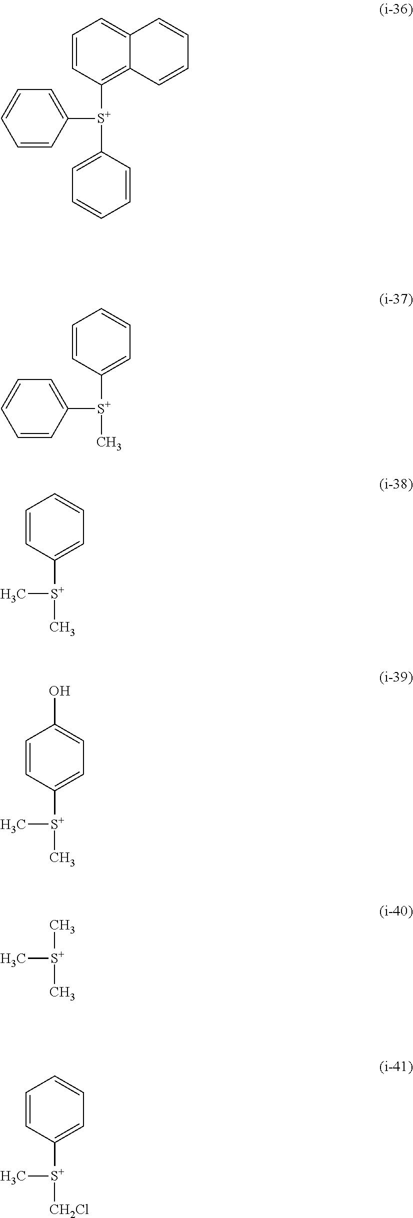

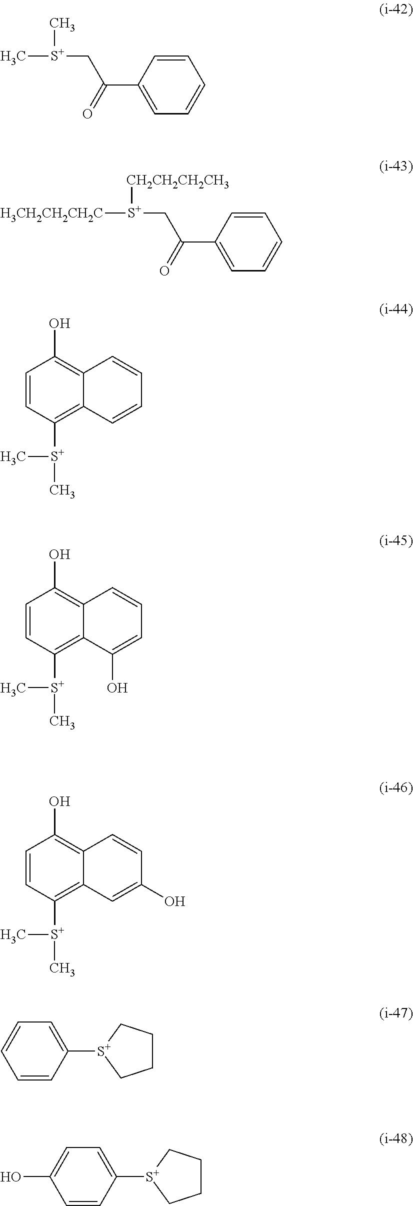

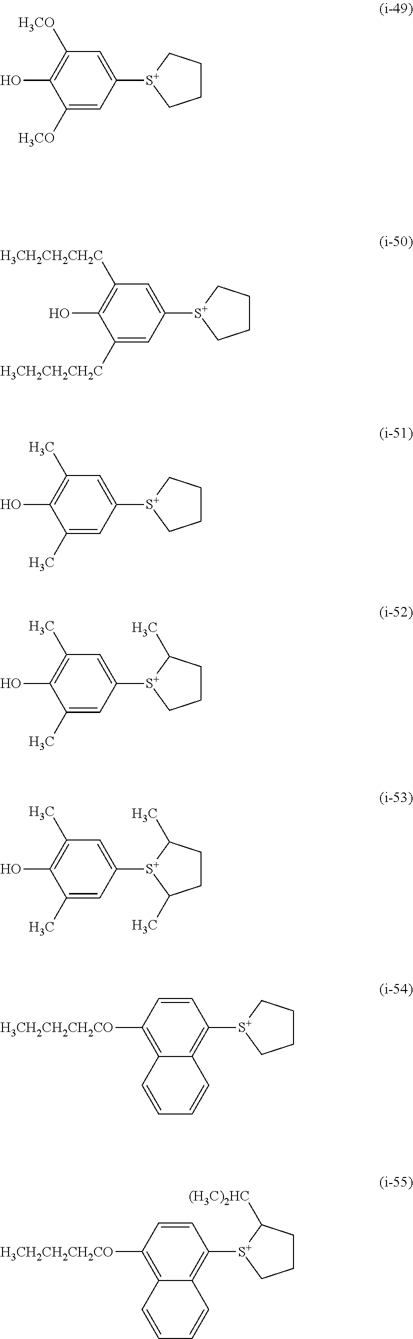

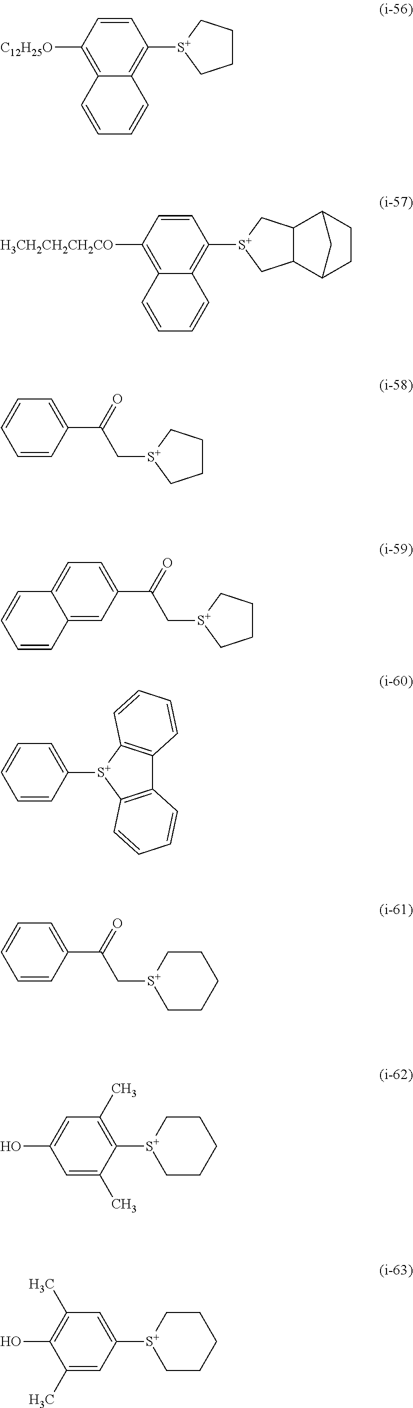

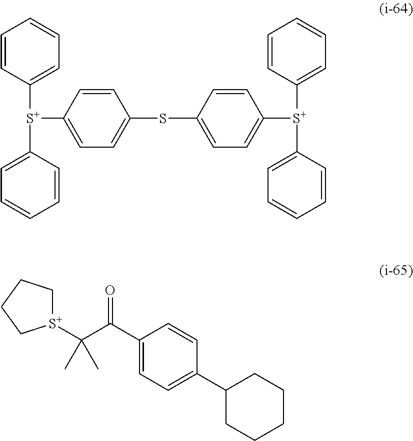 [SMILES: c1ccc([S+](c2ccccc2)c2ccc(Sc3ccc([S+](c4ccccc4)c4ccccc4)cc3)cc2)cc1 ; CC(C)(C(=O)c1ccc(C2CCCCC2)cc1)[S+]1CCCC1]

The iodonium cation is exemplified by cations represented by the following formulae (ii-1) to (ii-39), and the like.

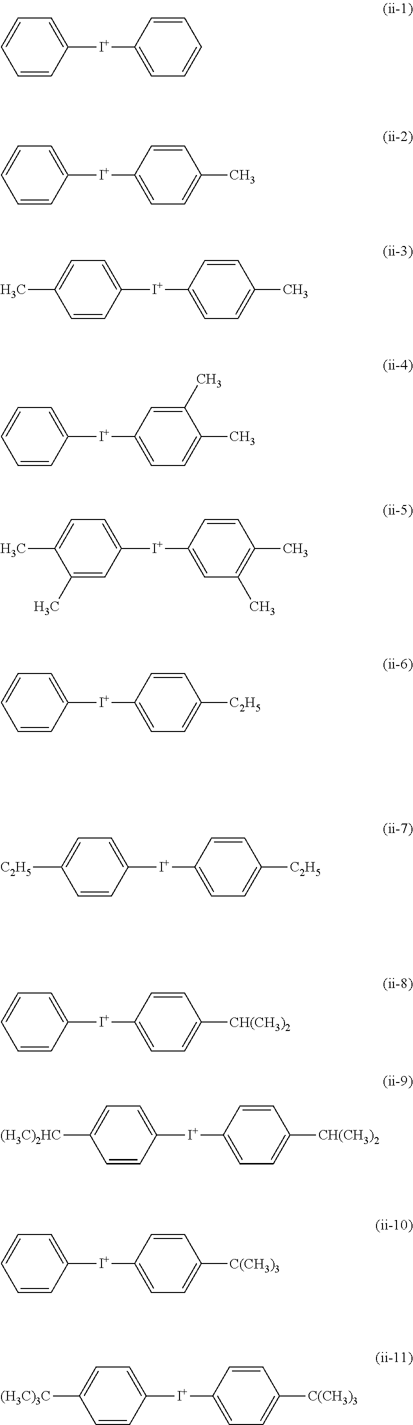

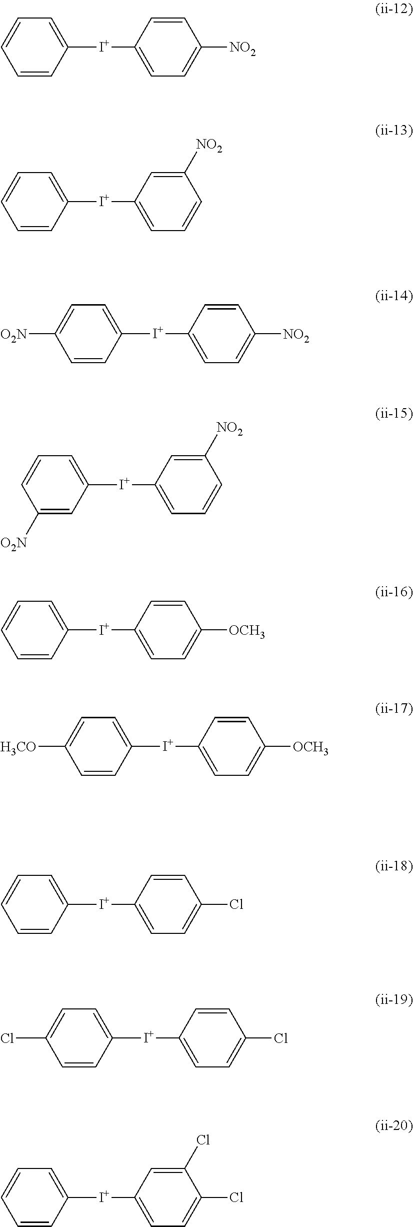

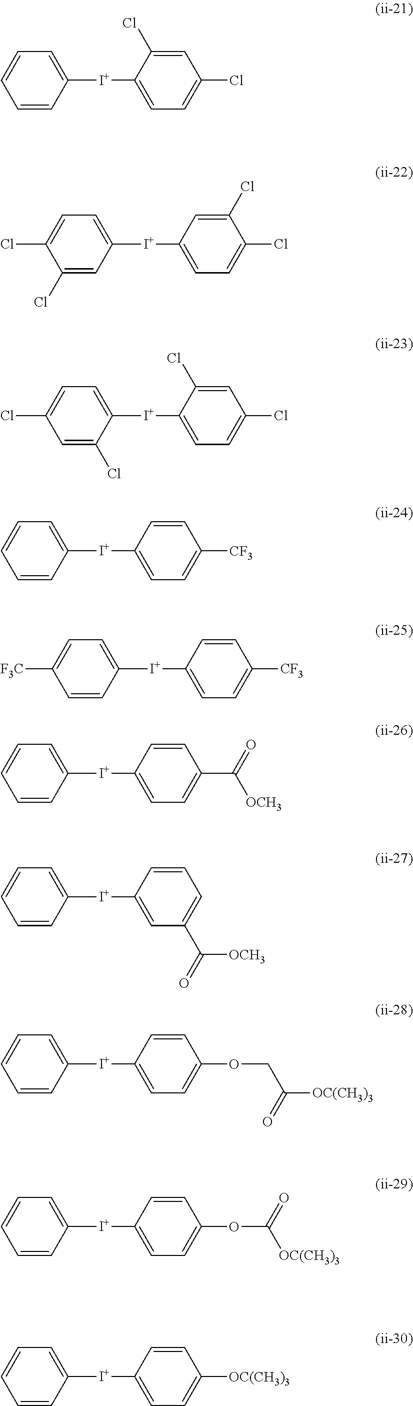

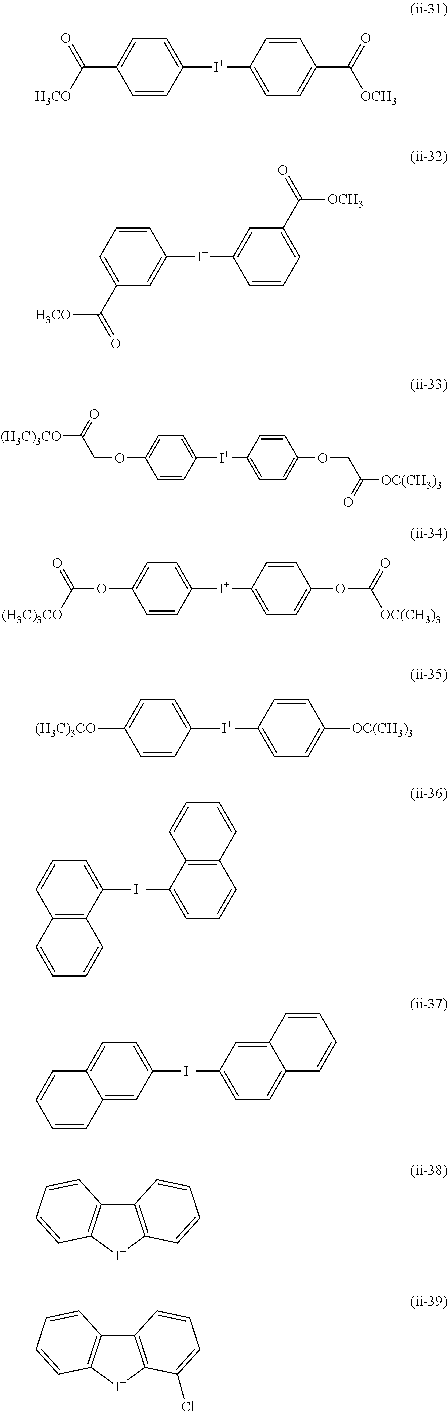

X⁺ represents preferably the cations (i-1), (i-12), (i-65) and (ii-1), and more preferably the cation (i-1).

The compound (4) is exemplified by compounds represented by the following formulae (4-1) to (4-15) (hereinafter, may be also referred to as “compounds (4-1) to (4-15)”), and the like, the compound (5) is exemplified by compounds represented by the following formulae (5-1) to (5-3) (hereinafter, may be also referred to as “compounds (5-1) to (5-3)”), and the like, the compound (6) is exemplified by compound represented by the following formulae (6-1) and (6-2) (hereinafter, may be also referred to as “compounds (6-1) and (6-2)”), and the like, and the compound (7) is exemplified by compounds represented by the following formulae (7-1) and (7-2) (hereinafter, may be also referred to as “compounds (7-1) and (7-2)”), and the like.

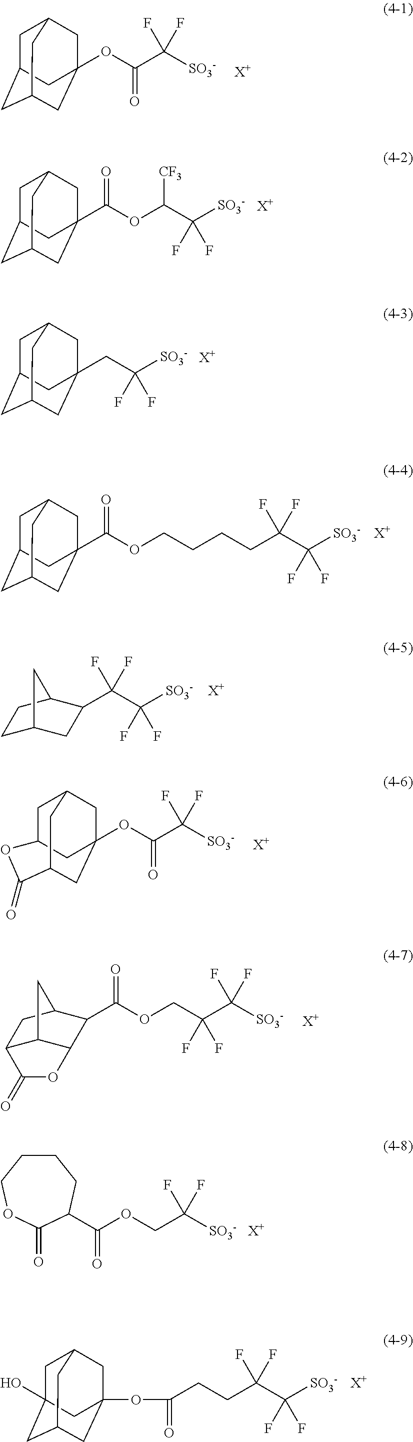

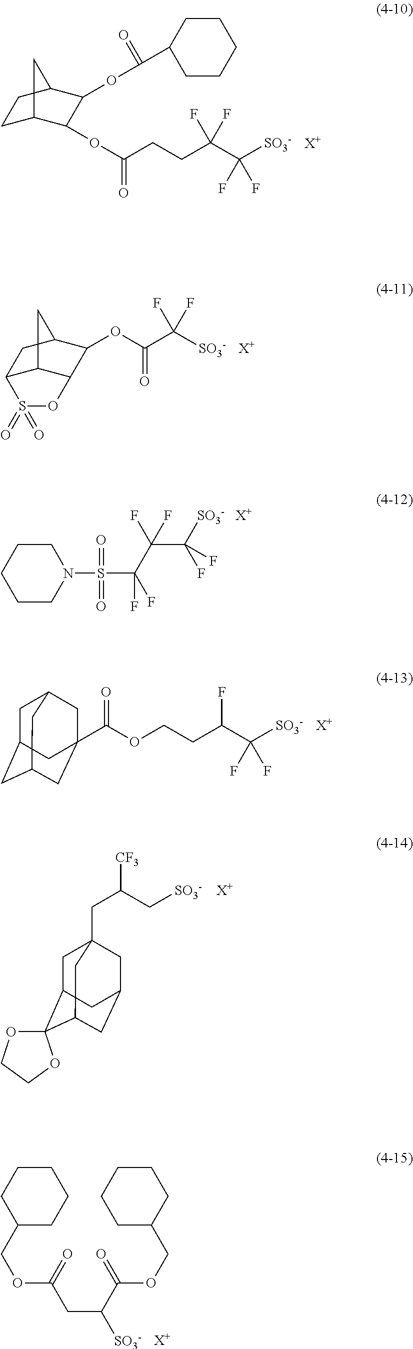

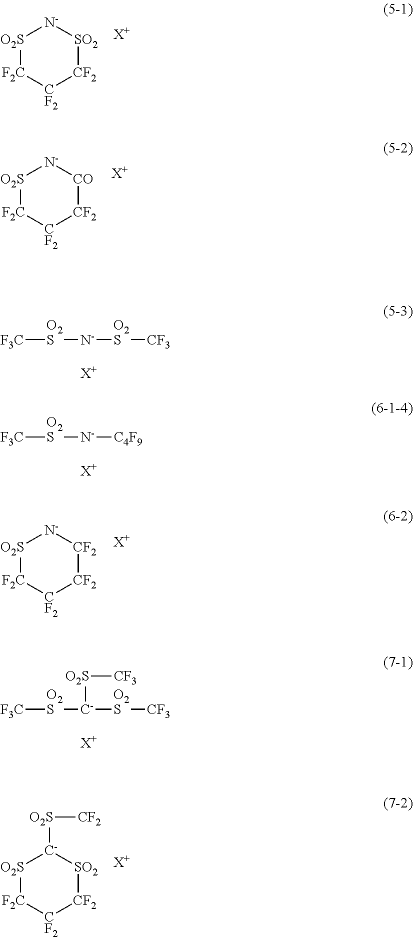

In the above formulae (4-1) to (4-15), (5-1) to (5-3), (6-1), (6-2), (7-1) and (7-2), X⁺ represents a monovalent onium cation.

As the acid generating agent (B1), the compound (4) and the compound (5) are preferred, the compound (4-1), the compound (4-2), the compound (4-11), the compound (4-12), the compound (4-14), the compound (4-15) and the compound (5-1) are more preferred.

As the acid generating agent (B1), the onium salt compound is preferred, the sulfonium salt compound is more preferred, and the triphenylsulfonium salt compound is still more preferred.

In addition, a polymer having the structure of the acid generator incorporated thereinto as a part of the polymer, e.g., a polymer that has a structural unit represented by the following formula (4′), is also preferred as the acid generator (B).

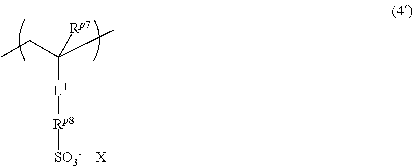

In the above formula (4′), R^{p7} represents a hydrogen atom or a methyl group; L¹ represents a single bond, —COO—, —Ar—, —COO—Ar— or —Ar—OSO₂—, wherein Ar represents a substituted or unsubstituted arenediyl group having 6 to 20 carbon atoms; R^{p8} represents a fluorinated alkanediyl group having 1 to 10 carbon atoms; and X⁺ represents a monovalent onium cation.

In light of the copolymerizability of a monomer that gives the structural unit represented by the above formula (4′), R^{p7} represents preferably a hydrogen atom or a methyl group, and more preferably a methyl group.

L¹ represents preferably —COO— or —Ar—OSO₂—, and more preferably —Ar—OSO₂—.

R^{p8} represents preferably a fluorinated alkanediyl group having 1 to 4 carbon atoms, more preferably a perfluoroalkanediyl group having 1 to 4 carbon atoms, and still more preferably a hexafluoropropanediyl group.

In a case where the acid generator (B) is the acid generating agent (B), the lower limit of the content of the acid generating agent (B) with respect to 100 parts by mass of the polymer (A) is preferably 0.1 parts by mass, more preferably 0.5 parts by mass, still more preferably 1 part by mass, particularly preferably 5 parts by mass, further particularly preferably 10 parts by mass, and most preferably 15 parts by mass. The upper limit of the aforementioned content is preferably 50 parts by mass, more preferably 40 parts by mass, still more preferably 30 parts by mass, and particularly preferably 25 parts by mass.

Moreover, the lower limit of the content of the acid generating agent (B) in terms of solid content equivalent, i.e., with respect to the total solid content of the radiation-sensitive resin composition, is preferably 0.1% by mass, more preferably 0.5% by mass, still more preferably 1% by mass, particularly preferably 5% by mass, further particularly preferably 10% by mass, and most preferably 15% by mass. The upper limit of the aforementioned content is preferably 50% by mass, more preferably 40% by mass, still more preferably 30% by mass, and particularly preferably 25% by mass.

When the content of the acid generating agent (B) falls within the above range, the sensitivity and the developability of the radiation-sensitive resin composition may be improved, and consequently LWR performances, etc. may be improved. In particular, in a case where the exposure light is an electron beam or EUV, in light of a more improvement of the sensitivity of the radiation-sensitive resin composition, the content of the acid generating agent (B) is preferably no less than 10 parts by mass with respect to 100 parts by mass of the polymer (A), and preferably no less than 10% by mass with respect to the total solid content of the radiation-sensitive resin composition. The acid generator (B) may be used either alone of one type, or two or more types of thereof.

### (C) Salt

The salt (C) contains an onium cation (hereinafter, may be also referred to as “onium cation (C)”), and HCO₃⁻, CO₃²⁻ or a combination thereof. Since the salt (C) can exhibit an acid-trapping function due to HCO₃⁻ and/or CO₃²⁻, the salt (C) functions as an acid diffusion control agent.

Due to containing the salt (C) in addition to the polymer (A) and the acid generator (B), the radiation-sensitive resin composition is superior in the LWR performances. Although not necessarily clarified, the reason for achieving the effects described above due to the radiation-sensitive resin composition having the aforementioned constitution is inferred as in the following, for example.

More specifically, due to containing an anion derived from carbonic acid, i.e., HCO₃⁻ and/or CO₃²⁻, the salt (C) has adequately greater basicity as compared with salts containing a sulfonic acid anion and a carboxylic acid anion. Therefore, the salt (C) is inferred to have an adequately superior acid-trapping function as compared with a conventional acid diffusion control agent containing a sulfonic acid anion or a carboxylic acid anion. In addition, HCO₃⁻ and/or CO₃²⁻ of the salt (C) are/is converted into carbon dioxide and water upon trapping of an acid. Thus, unlike the case with the conventional acid diffusion control agent containing the sulfonic acid anion or the carboxylic acid anion, an increase of the diffusion length of the acid generated from the acid generator (B) in the resist film, which would be caused by a substance generated from the anion upon the trapping of the acid and remaining in the resist film, and the like can be inhibited. Consequently, the LWR performances, etc. of the radiation-sensitive resin composition would be improved.

The onium cation (C) is exemplified by a sulfonium cation, a ammonium cation, an iodonium cation, a phosphonium cation, a diazonium cation, and the like. Of these, the sulfonium cation, the ammonium cation and the iodonium cation are preferred.

The onium cation (C) may be radiation-sensitive or radiation-insensitive, but radiation-sensitive onium cations are preferred. When the onium cation (C) is radiation-sensitive, HCO₃⁻ and/or CO₃²⁻ would be converted to carbon dioxide and water in light-exposed regions through binding with a proton generated from the radiation-sensitive onium cation upon the exposure, leading to a decrease of the acid-trapping function thereof. Therefore, the salt (C) would function as a radiation-sensitive acid diffusion control agent, leading to a further increase of a quenching contrast between the light-exposed regions and the light-unexposed regions. Consequently, the LWR performances, etc. of the radiation-sensitive resin composition may be more improved. However, in this case, the salt (C) shall not fall under the acid generator (B).

In a case where the salt (C) contains a plurality of types of onium cations (C), it is preferred that a part or all of the onium cations (C) are radiation-sensitive, and it is more preferred that all of the onium cations (C) are radiation-sensitive.

The valency of the onium cation (C) is not particularly limited, and the onium cation (C) may have a valency of one, two, or three or more; in light of the dispersibility of the salt (C) in the resist film, the onium cation (C) has a valency of preferably one or two, and more preferably one.

The sulfonium cation is exemplified by the cation (b-1) which has been exemplified in connection with X⁺ of the acid generator (B), and the like. The iodonium cation is exemplified by the cation (b-2) which has been exemplified in connection with X⁺ of the acid generator (B), and the like.

The sulfonium cation is preferably a tri(4-trifluoromethylphenyl)sulfonium cation, a 4-cyclohexylsulfonylphenyldiphenylsulfonium cation, and the cation (i-1), (i-13), (i-14), (i-54) or (i-59) exemplified in connection with X⁺ of the acid generator (B) described above.

The ammonium cation is exemplified by a cation represented by the following formula (b-3), and the like.

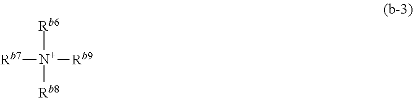

In the above formula (b-3), R^{b6} to R^{b9} each independently represent a hydrogen atom, a substituted or unsubstituted monovalent hydrocarbon group having 1 to 20 carbon atoms, or at least two of R^{b6} to R^{b9} taken together represent a ring structure together with the nitrogen atom to which the at least two of R^{b6} to R^{b9} bond.

The phosphonium cation is exemplified by a cation represented by the following formula (b-4), and the like.

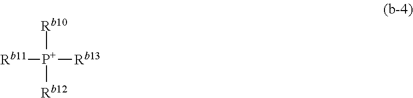

In the above formula (b-4), R^{b10} to R^{b13} each independently represent a hydrogen atom, a substituted or unsubstituted monovalent hydrocarbon group having 1 to 20 carbon atoms, or at least two of R^{b10} to R^{b13} taken together represent a ring structure together with the phosphorus atom to which the at least two of R^{b10} to R^{b13} bond.

As R^{b6} to R^{b13}, an alkyl group and a cycloalkyl group are preferred, an alkyl group having 1 to 6 carbon atoms and a cycloalkyl group having 5 to 8 carbon atoms are more preferred, and a n-butyl group and a cyclohexyl group are still more preferred.

The diazonium cation is exemplified by a cation represented by the following formula (b-5), and the like.

R^{b14}—N₂⁺ (b-5)

In the above formula (b-5), R^{b14} represents a substituted or unsubstituted monovalent hydrocarbon group having 1 to 20 carbon atoms.

As R^{b14}, an aralkyl group is preferred, an aralkyl group having 7 to 12 carbon atoms is more preferred, and a benzyl group is still more preferred.

The salt (C) is preferably a compound represented by the following formula (1) (hereinafter, may be also referred to as “compound (1)”), a compound represented by the following formula (2) (hereinafter, may be also referred to as “compound (2)”) or a combination thereof.

HCO₃⁻Zₐ⁺ (1)

CO₃²⁻Z_{b}⁺Z_{c}⁺ (2)

In the above formula (1), Zₐ⁺ represents a monovalent onium cation.

In the above formula (2), Z_{b}⁺ and Z_{c}⁺ each independently represent a monovalent onium cation.

The salt (C) is exemplified by compounds represented by the following formulae (1-1) to (1-10) (hereinafter, may be also referred to as “compounds (1-1) to (1-10)”) and the like as the compound (1), and compounds represented by the following formulae (2-1) to (2-8) (hereinafter, may be also referred to as “compounds (2-1) to (2-8)”) and the like as the compound (2).

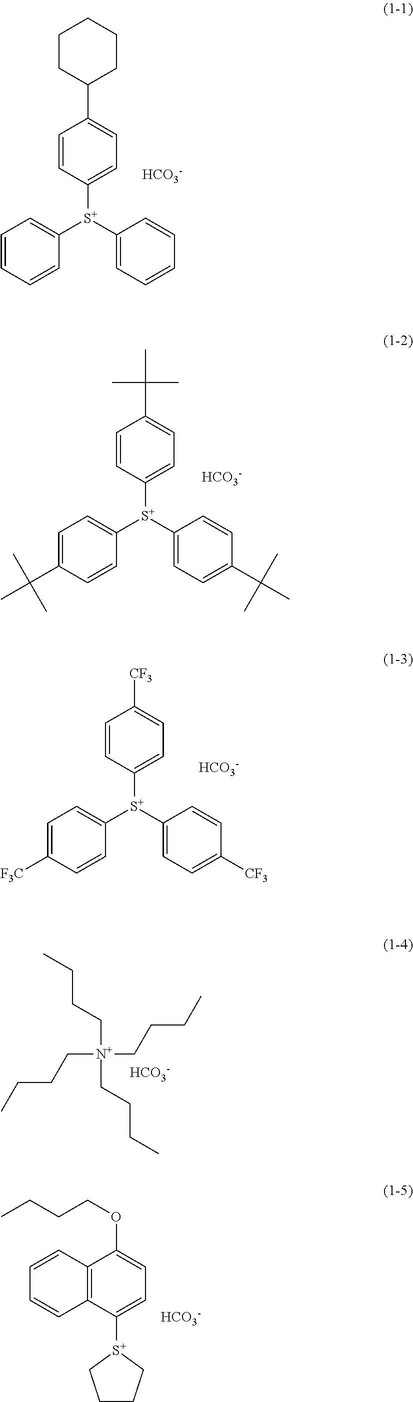

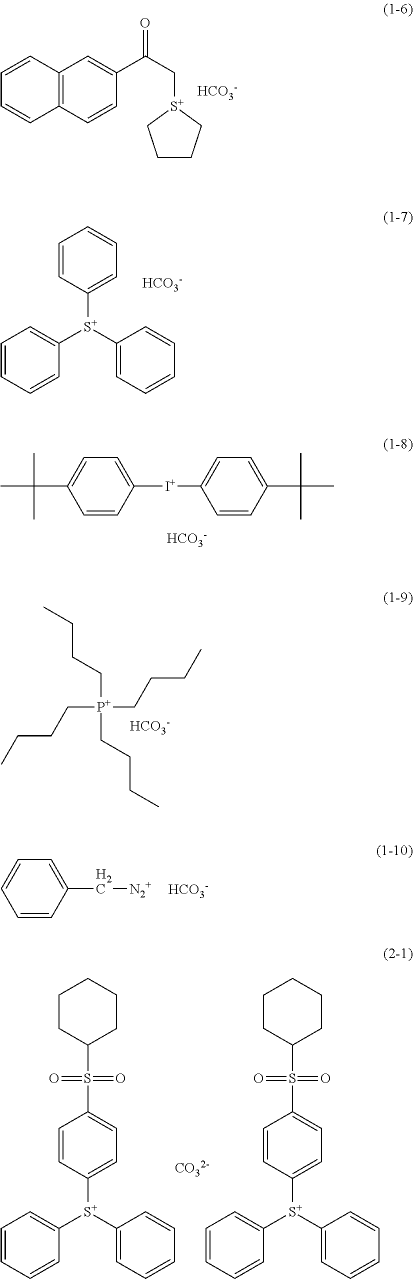

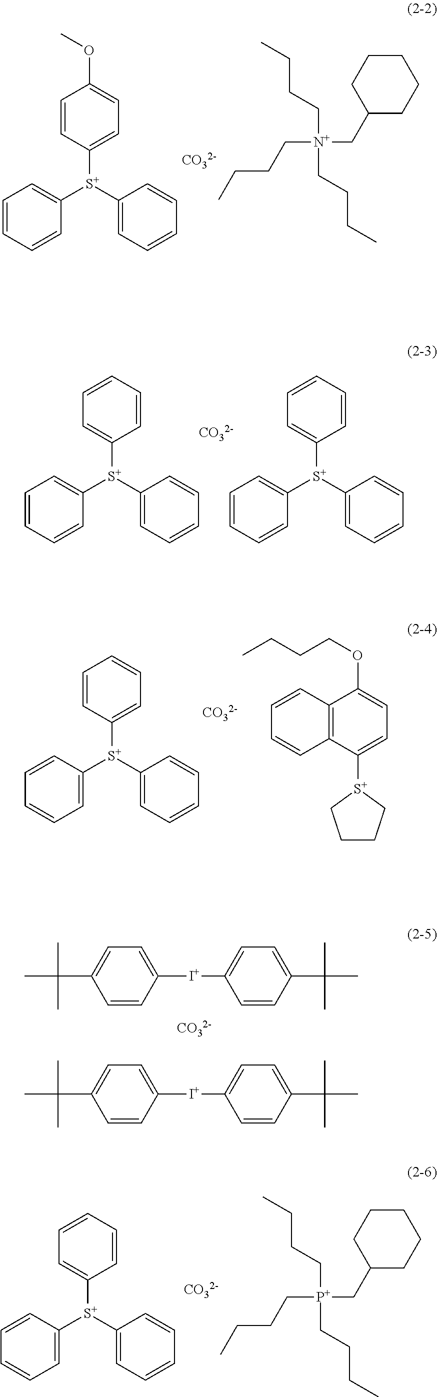

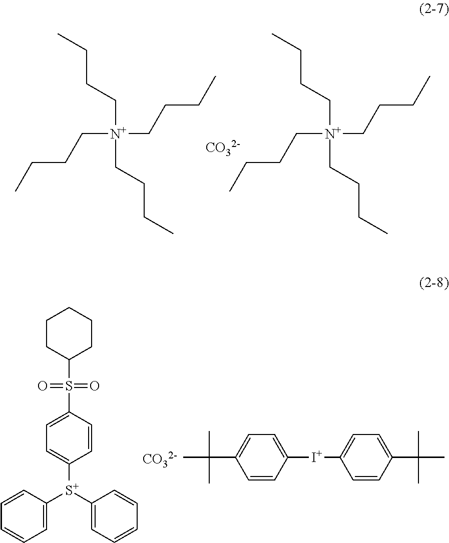

As the salt (C), the compounds (1-1) to (1-6), and the compounds (2-1) and (2-2) are preferred.

The salt (C) may be synthesized, for example, by a salt exchange between a salt that contains the monovalent onium cation and a halide anion and an alkali metal carbonate salt or an alkali metal hydrogencarbonate salt.

The lower limit of the content of the salt (C) with respect to 100 parts by mass of the polymer (A) is preferably 0.1 parts by mass, more preferably 0.5 parts by mass, still more preferably 1 part by mass, and particularly preferably 2 parts by mass. The upper limit of the aforementioned content is preferably 30 parts by mass, more preferably 20 parts by mass, still more preferably 10 parts by mass, and particularly preferably 5 parts by mass.

The lower limit of the content of the salt (C) in terms of solid content equivalent, i.e., with respect to the total solid content of the radiation-sensitive resin composition, is preferably 0.1% by mass, more preferably 0.5% by mass, still more preferably 1% by mass, and particularly preferably 2% by mass. The upper limit of the aforementioned content is preferably 30% by mass, more preferably 20% by mass, still more preferably 10% by mass, and particularly preferably 5% by mass.

When the content of the salt (C) falls within the above range, the LWR performances, etc. of the radiation-sensitive resin composition may be further improved. The radiation-sensitive resin composition may contain one type, or two or more types of the salt (C).

### (D) Polymer

The polymer (D) has a greater mass percentage content of fluorine atoms than that of the polymer (A). Since the polymer (D) has a greater mass percentage content of fluorine atoms than that of the polymer (A), when a resist film is formed, oil repellent characteristics of the polymer (D) tend to allow the polymer (D) to be localized in the surface region of the resist film. Consequently, according to the radiation-sensitive resin composition, elution of an acid generator, an acid diffusion controller and the like into a liquid immersion medium may be inhibited in liquid immersion lithography. In addition, according to the radiation-sensitive resin composition, due to water repellent characteristics of the polymer (D), an advancing contact angle of a liquid immersion medium on the resist film can be controlled to fall within a desired range, whereby generation of bubble defects can be inhibited. Further, according to the radiation-sensitive resin composition, a greater receding contact angle of the liquid immersion medium on the resist film is attained, whereby an exposure by high speed scanning without being accompanied by residual water beads is enabled. Due to thus containing the polymer (D), the radiation-sensitive resin composition can form a resist film suitable for liquid immersion lithography processes.

The lower limit of the mass percentage content of fluorine atoms of the polymer (D) is preferably 1% by mass, more preferably 2% by mass, still more preferably 4% by mass, and particularly preferably 7% by mass. The upper limit of the aforementioned mass percentage content is preferably 60% by mass, more preferably 50% by mass, still more preferably 40% by mass, and particularly preferably 30% by mass. When the mass percentage content of fluorine atoms falls within the above range, the localization of the polymer (D) in the resist film can be regulated more appropriately. It is to be noted that the mass percentage content of fluorine atoms of the polymer can be calculated based on the structure of the polymer determined by ¹³C-NMR spectroscopy.

The mode of the incorporation of the fluorine atom in the polymer (D) is not particularly limited, and the fluorine atom may bond to any of the main chain, a side chain or the end of the polymer (D). The polymer (D) preferably has a structural unit that includes a fluorine atom (hereinafter, may be also referred to as “structural unit (F)”). In light of an improvement of the development defects-inhibiting effect of the radiation-sensitive resin composition, the polymer (D) preferably has, in addition to the structural unit (F), a structural unit that includes an acid-labile group. The structural unit that includes an acid-labile group is exemplified by the structural unit (I) in the polymer (A), and the like.

Moreover, the polymer (D) preferably has an alkali-labile group. When the polymer (D) has the alkali-labile group, the surface of the resist film can be altered effectively from hydrophobic to hydrophilic in a development with an alkali, whereby the development defects-inhibiting effect of the radiation-sensitive resin composition may be more improved. The “alkali-labile group” as referred to means a group that substitutes for the hydrogen atom of a carboxy group, a hydroxy group or the like and may be dissociated in an alkaline aqueous solution (for example, a 2.38% by mass aqueous tetramethylammonium hydroxide solution at 23° C.).

The structural unit (F) is preferably a structural unit represented by the following formula (f-1) (hereinafter, may be also referred to as “structural unit (F-1)”) or a structural unit represented by the following formula (f-2) (hereinafter, may be also referred to as “structural unit (F-2)”). The structural unit (F) may contain one type, or two or more types of each of the structural unit (F-1) and the structural unit (F-2).

### Structural Unit (F-1)

The structural unit (F-1) is represented by the following formula (f-1). When the polymer (D) has the structural unit (F-1), the mass percentage content of fluorine atoms can be adjusted.

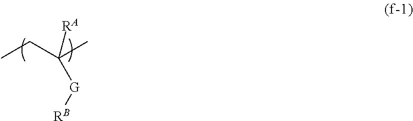

In the above formula (f-1), R^{A} represents a hydrogen atom, a fluorine atom, a methyl group or a trifluoromethyl group; G represents a single bond, an oxygen atom, a sulfur atom, —COO—, —SO₂ONH—, —CONH— or —OCONH—; and R^{B} represents a monovalent fluorinated chain hydrocarbon group having 1 to 6 carbon atoms or a monovalent fluorinated alicyclic hydrocarbon group having 4 to 20 carbon atoms.

In light of the copolymerizability of a monomer that gives the structural unit (F-1), R^{A} represents preferably a hydrogen atom or a methyl group, and more preferably a methyl group.

G represents preferably COO—, —SO₂ONH—, —CONH— or —OCONH—, and more preferably —COO—.

Examples of the monovalent fluorinated chain hydrocarbon group having 1 to 6 carbon atoms which may be represented by R^{B} include a trifluoromethyl group, a 2,2,2-trifluoroethyl group, a perfluoroethyl group, a 2,2,3,3,3-pentafluoropropyl group, a 1,1,1,3,3,3-hexafluoropropyl group, a perfluoro-n-propyl group, a perfluoro-i-propyl group, a perfluoro-n-butyl group, a perfluoro-i-butyl group, a perfluoro-t-butyl group, a 2,2,3,3,4,4,5,5-octafluoropentyl group, a perfluorohexyl group, and the like.

Examples of the monovalent fluorinated alicyclic hydrocarbon group having 4 to 20 carbon atoms which may be represented by R^{B} include a monofluorocyclopentyl group, a difluorocyclopentyl group, a perfluorocyclopentyl group, a monofluorocyclohexyl group, a difluorocyclopentyl group, a perfluorocyclohexylmethyl group, a fluoronorbornyl group, a fluoroadamantyl group, a fluorobornyl group, a fluoroisobornyl group, a fluorotricyclodecyl group, a fluorotetracyclodecyl group, and the like.

R^{B} represents preferably a fluorinated chain hydrocarbon group, more preferably a 2,2,2-trifluoroethyl group or a 1,1,1,3,3,3-hexafluoro-2-propyl group, and still more preferably a 1,1,1,3,3,3-hexafluoro-2-propyl group.

In a case where the polymer (D) has the structural unit (F-1), the lower limit of the proportion of the structural unit (F-1) with respect to the total structural units constituting the polymer (D) is preferably 3 mol %, and more preferably 5 mol %. The upper limit of the aforementioned proportion is preferably 90 mol %, more preferably 70 mol %, and still more preferably 50 mol %. When the proportion of the structural unit (F-1) falls within the above range, the mass percentage content of fluorine atoms of the polymer (D) can be adjusted further appropriately.

### Structural Unit (F-2)

The structural unit (F-2) is represented by the following formula (f-2). When the polymer (D) has the structural unit (F-2), the mass percentage content of fluorine atoms can be adjusted, and additionally the surface of the resist film can be altered from water-repellent to hydrophilic through the development with an alkali.

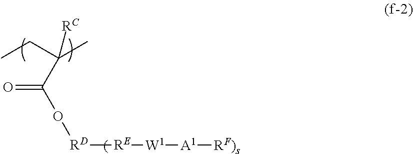

In the above formula (f-2), R^{C} represents a hydrogen atom, a fluorine atom, a methyl group or a trifluoromethyl group; R^{D} represents a hydrocarbon group having 1 to 20 carbon atoms and having a valency of (s+1), or a structure in which an oxygen atom, a sulfur atom, —NR′—, a carbonyl group, —COO— or —CONH— is bound to the end on the R^{E} side of the hydrocarbon group, wherein R′ represents a hydrogen atom or a monovalent hydrocarbon group having 1 to 10 carbon atoms; R^{E} represents a single bond or a divalent organic group having 1 to 20 carbon atoms; W′ represents a single bond or a divalent fluorinated chain hydrocarbon group having 1 to 20 carbon atoms; A¹ represents an oxygen atom, —NR″—, —COO—* or —SO₂O—*, wherein R″ represents a hydrogen atom or a monovalent hydrocarbon group having 1 to 10 carbon atoms, and * denotes a binding site to R^{F}; R^{F} represents a hydrogen atom or a monovalent organic group having 1 to 30 carbon atoms; and s is an integer of 1 to 3, wherein in a case where s is 1, R^{D} may represent a single bond, in a case where s is 2 or 3, a plurality of R^{E}s may be identical or different, a plurality of W¹s may be each identical or different, a plurality of A¹s may be each identical or different and a plurality of R^{F}s may be each identical or different, and in a case where W¹ represents the single bond, R^{F} represents a group that includes a fluorine atom.

In light of the copolymerizability of a monomer that gives the structural unit (F-2), and the like, R^{C} represents preferably a hydrogen atom or a methyl group, and more preferably a methyl group.

Examples of the hydrocarbon group having 1 to 20 carbon atoms and having a valency of (s+1) which may be represented by R^{D} include groups derived from the monovalent hydrocarbon group exemplified in connection with R^{e1} in the above formula (Y-1) by removing s hydrogen atom(s) therefrom, and the like.

In the above formula (f-2), s is preferably 1 or 2, and more preferably 1.

In the case where s is 1, R^{D} represents preferably a single bond or a divalent hydrocarbon group, more preferably a single bond or an alkanediyl group, still more preferably a single bond or an alkanediyl group having 1 to 4 carbon atoms, and particularly preferably a single bond, a methanediyl group or a propanediyl group.

Examples of the divalent organic group having 1 to 20 carbon atoms which may be represented by R^{E} include groups derived from the monovalent organic group having 1 to 20 carbon atoms which has been exemplified in connection with R⁴ in the above formula (a-3) by removing one hydrogen atom therefrom, and the like.

R^{E} represents preferably a single bond or a group that has a lactone structure, more preferably a single bond or a group that has a polycyclic lactone structure, and more preferably a single bond or a group that has a norbornanelactone structure.

Examples of the divalent fluorinated chain hydrocarbon group having 1 to 20 carbon atoms, which may be represented by W¹, include:

fluorinated alkanediyl groups such as a fluoromethanediyl group, a difluoromethanediyl group, a fluoroethanediyl group, a difluoroethanediyl group, a tetrafluoroethanediyl group, a hexafluoropropanediyl group and an octafluorobutanediyl group;

fluorinated alkenediyl groups such as a fluoroethenediyl group and a difluoroethenediyl group; and the like. Of these, the fluorinated alkanediyl group is preferred, and the difluoromethanediyl group is more preferred.

A¹ represents preferably the oxygen atom, —COO—* or —SO₂O—*, and more preferably —COO—*.

The monovalent organic group having 1 to 30 carbon atoms, which may be represented by R^{F}, is exemplified by an alkali-labile group, an acid-labile group, a hydrocarbon group having 1 to 30 carbon atoms, and the like. Of these, R^{F} represents preferably the alkali-labile group. When R^{F} represents the alkali-labile group, the surface of the resist film can be altered from hydrophobic to hydrophilic more effectively in the development with an alkali, the development defects-inhibiting effect of the radiation-sensitive resin composition may be further improved.

When R^{F} represents the alkali-labile group, R^{F} preferably represents groups represented by the following formulae (iii) to (v) (hereinafter, may be also referred to as “groups (iii) to (v)”).

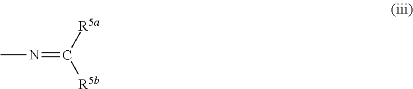

In the above formula (iii), R^{5a} and R^{5b} each independently represent a monovalent organic group having 1 to 20 carbon atoms, or R^{5a} and R^{5b} taken together represent an alicyclic structure having 3 to 20 ring atoms together with the carbon atom to which R^{5a} and R^{5b} bond.

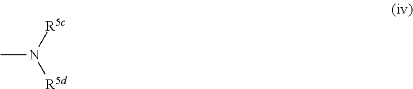

In the above formula (iv), R^{5c} and R^{5d} each independently represent a monovalent organic group having 1 to 20 carbon atoms, or R^{5c} and R^{5d} taken together represent heterocyclic structure having 3 to 20 ring atoms together with the nitrogen atom to which R^{5c} and R^{5d} bond.

—R^{5e} (v)

In the above formula (v), R^{5e} represents a monovalent hydrocarbon group having 1 to 20 carbon atoms or a monovalent fluorinated hydrocarbon group having 1 to 20 carbon atoms.

Examples of the monovalent organic group having 1 to 20 carbon atoms and the monovalent hydrocarbon group having 1 to 20 carbon atoms include groups similar to those exemplified in connection with R^{e1} in the above formula (Y-1), and the like.

The monovalent fluorinated hydrocarbon group having 1 to 20 carbon atoms is exemplified by groups derived from the groups exemplified as the monovalent hydrocarbon group having 1 to 20 carbon atoms by substituting a part or all of hydrogen atoms included therein with a fluorine atom, and the like.

As the group (iii), groups represented by the following formulae (iii-1) to (iii-4) (hereinafter, may be also referred to as “groups (iii-1) to (iii-4)”) are preferred. As the group (iv), a group represented by the following formula (iv-1) (hereinafter, may be also referred to as “group (iv-1)”) is preferred. As the group (v), groups represented by the following formulae (v-1) to (v-5) (hereinafter, may be also referred to as “groups (v-1) to (v-5)”) are preferred.

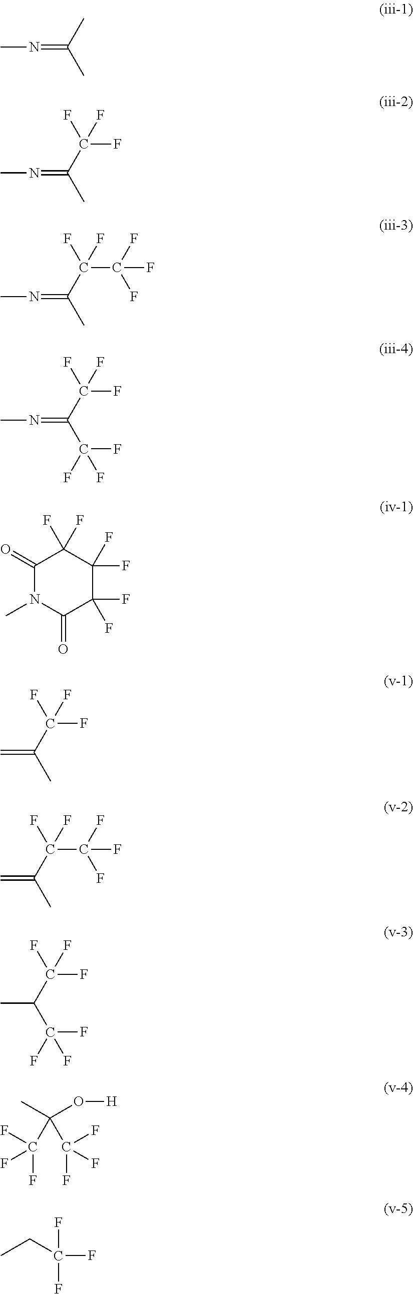

Of these, the groups (v-3) and (v-5) are preferred.

In addition, it is preferred that R^{F} represents the hydrogen atom, since the affinity of the polymer (D) for an alkaline developer solution may be improved. In this case, when A¹ represents an oxygen atom and W¹ represents a 1,1,1,3,3,3-hexafluoro-2,2-methanediyl group, the aforementioned affinity may be further improved.

When the polymer (D) has the structural unit (F-2), the lower limit of the proportion of the structural unit (F-2) with respect to the total structural units constituting the polymer (D) is preferably 10 mol %, more preferably 20 mol %, and still more preferably 40 mol %. The upper limit of the aforementioned proportion is preferably 90 mol %, more preferably 85 mol %, and still more preferably 80 mol %. When the proportion of the structural unit (F-2) falls within the above range, the surface of a resist film formed from the radiation-sensitive resin composition can be altered from water repellent to hydrophilic more appropriately through the development with an alkali.

The lower limit of the proportion of the structural unit (F) with respect to the total structural units constituting the polymer (D) is preferably 20 mol %, more preferably 30 mol %, and still more preferably 40 mol %. The upper limit of the aforementioned proportion is preferably 90 mol %, more preferably 85 mol %, and still more preferably 80 mol %.

The lower limit of the proportion of the structural unit that includes an acid-labile group in the polymer (D) with respect to the total structural units constituting the polymer (D) is preferably 10 mol %, more preferably 15 mol %, and still more preferably 20 mol %. The upper limit of the aforementioned proportion is preferably 60 mol %, more preferably 50 mol %, and still more preferably 40 mol %. When the proportion of the structural unit that includes an acid-labile group falls within the above range, the development defects-inhibiting effect of the radiation-sensitive resin composition may be further improved.

When the radiation-sensitive resin composition contains the polymer (D), the lower limit of the content of the polymer (D) with respect to 100 parts by mass of the polymer (A) is preferably 0.1 parts by mass, more preferably 0.2 parts by mass, still more preferably 0.5 parts by mass, and particularly preferably 1 part by mass. The upper limit of the aforementioned content is preferably 30 parts by mass, more preferably 20 parts by mass, still more preferably 15 parts by mass, and particularly preferably 10 parts by mass.

The polymer (D) may be synthesized according to a method similar to the aforementioned method for the polymer (A).

The lower limit of the Mw as determined by GPC of the polymer (D) is preferably 1,000, more preferably 2,000, still more preferably 2,500, and particularly preferably 3,000. The upper limit of the Mw is preferably 50,000, more preferably 30,000, still more preferably 20,000, and particularly preferably 15,000. When the Mw of the polymer (D) falls within the above range, the application property and the development defects-inhibiting effect of the radiation-sensitive resin composition may be improved.

The lower limit of the ratio (Mw/Mn) of the Mw to the Mn as determined by GPC of the polymer (D) is typically 1, and preferably 1.2. The upper limit of the aforementioned ratio is preferably 5, more preferably 3, and still more preferably 2.

### (E) Solvent

The radiation-sensitive resin composition typically contains the solvent (E). The solvent (E) is not particularly limited as long as the solvent (E) can dissolve or disperse at least the polymer (A), the acid generator (B) and the salt (C), as well as the polymer (D) and the like which are contained as needed.

The solvent (E) is exemplified by alcohol solvents, ether solvents, ketone solvents, amide solvents, ester solvents, hydrocarbon solvents, and the like.

Examples of the alcohol solvents include:

aliphatic monohydric alcohol solvents having 1 to 18 carbon atoms such as 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as propylene glycol monomethyl ether; and the like.

Examples of the ether solvents include:

dialkyl ether solvents such as diethyl ether, dipropyl ether, dibutyl ether, dipentyl ether, diisoamyl ether, dihexyl ether and diheptyl ether;

cyclic ether solvents such as tetrahydrofuran and tetrahydropyran;

aromatic ring-containing ether solvents such as diphenyl ether and anisole; and the like.

Examples of the ketone solvents include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone and trimethylnonanone:

cyclic ketone solvents such as cyclopentanone, cyclohexanone, cycloheptanone, cyclooctanone and methylcyclohexanone:

2,4-pentanedione, acetonylacetone and acetophenone; and the like.

Examples of the amide solvents include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methyl acetamide, N,N-dimethylacetamide and N-methylpropionamide; and the like.

Examples of the ester solvents include:

monocarboxylic acid ester solvents such as n-butyl acetate and ethyl lactate;

polyhydric alcohol carboxylate solvents such as propylene glycol acetate;

polyhydric alcohol partial ether carboxylate solvents such as propylene glycol monomethyl ether acetate;

polyhydric carboxylic acid diester solvents such as diethyl oxalate;

carbonate solvents such as dimethyl carbonate and diethyl carbonate; and the like.

Examples of the hydrocarbon solvents include:

aliphatic hydrocarbon solvents having 5 to 12 carbon atoms such as n-pentane and n-hexane;

aromatic hydrocarbon solvents having 6 to 16 carbon atoms such as toluene and xylene; and the like.

As the solvent (E), the ester solvents and the ketone solvents are preferred, the polyhydric alcohol partial ether carboxylate solvents and the cyclic ketone solvents are more preferred, polyhydric alcohol partial alkyl ether acetates and cycloalkanones are still more preferred, and propylene glycol monomethyl ether acetate and cyclohexanone are particularly preferred. The radiation-sensitive resin composition may contain one type, or two or more types of the solvent (E).

### (F) Localization Accelerator

The localization accelerator (F) facilitates more efficient localization of the polymer (D) in the surface region of the resist film, for example, in the case of the radiation-sensitive resin composition containing the polymer (D). When the radiation-sensitive resin composition contains the localization accelerator (F), the polymer (D) can be more effectively localized in the surface region of the resist film, and consequently the amount of the polymer (D) used can be decreased. Examples of the localization accelerator (F) include lactone compounds, carbonate compounds, nitrile compounds, polyhydric alcohols, and the like. The localization accelerator (F) may be used either alone of one type, or in combination of two or more types thereof.

Examples of the lactone compounds include γ-butyrolactone, valerolactone, mevalonic lactone, norbornanelactone, and the like.

Examples of the carbonate compounds include propylene carbonate, ethylene carbonate, butylene carbonate, vinylene carbonate, and the like.

Examples of the nitrile compounds include succinonitrile, and the like.

Examples of the polyhydric alcohols include glycerin, and the like.

Of these, the lactone compounds are preferred, and γ-butyrolactone is more preferred.

When the radiation-sensitive resin composition contains the localization accelerator (F), the lower limit of the content of the localization accelerator (F) with respect to 100 parts by mass of the polymer (A) is preferably 5 parts by mass, more preferably 10 parts by mass, and still more preferably 20 parts by mass. The upper limit of the aforementioned content is preferably 300 parts by mass, more preferably 100 parts by mass, and still more preferably 70 parts by mass.

### (G) Other Acid Diffusion Controller

The other acid diffusion controller (G) is an acid diffusion controller other than the salt (C). The other acid diffusion controller (G) controls a diffusion phenomenon of the acid generated from the acid generator (B) upon an exposure in the resist film. Consequently, an effect of inhibiting unfavorable chemical reaction(s) in light-unexposed regions is achieved. In addition, the storage stability of the radiation-sensitive resin composition may be further improved. Furthermore, a resolution of the radiation-sensitive resin composition may be further improved, and additionally variation of the line width of the resist pattern caused by variation of post exposure time delay from the exposure until a development treatment can be inhibited, thereby enabling a radiation-sensitive resin composition with superior process stability to be obtained. The other acid diffusion controller (G) may be contained in the radiation-sensitive resin composition in the form of a low-molecular-weight compound (hereinafter, may be also referred to as “(G) other acid diffusion control agent” or “other acid diffusion control agent (G)”, as appropriate), or in the form incorporated as a part of the polymer, or may be in both of these forms. The other acid diffusion controller (G) may be used either alone of one type, or in combination of two or more types thereof.

The other acid diffusion control agent (G) is exemplified by a compound represented by the following formula (8) (hereinafter, may be also referred to as “nitrogen-containing compound (I)”), a compound having two nitrogen atoms in a single molecule (hereinafter, may be also referred to as “nitrogen-containing compound (II)”), a compound having three nitrogen atoms (hereinafter, may be also referred to as “nitrogen-containing compound (III)”), an amide group-containing compound, a urea compound, a nitrogen-containing heterocyclic compound, and the like.

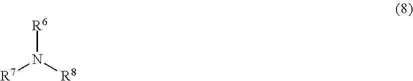

In the above formula (8), R⁶, R⁷ and R⁸ each independently represent a hydrogen atom, a substituted or unsubstituted alkyl group, a substituted or unsubstituted cycloalkyl group, a substituted or unsubstituted aryl group or a substituted or unsubstituted aralkyl group.

Examples of the nitrogen-containing compound (I) include monoalkylamines such as n-hexylamine; dialkylamines such as di-n-butylamine; trialkylamines such as triethylamine and tri-n-pentylamine; aromatic amines such as aniline; and the like.

Examples of the nitrogen-containing compound (II) include ethylene diamine, N,N,N′,N′-tetramethylethylenediamine, and the like.

Examples of the nitrogen-containing compound (III) include: polyamine compounds such as polyethyleneimine and polyallylamine; polymers of dimethylaminoethylacrylamide, etc.; and the like.

Examples of the amide group-containing compound include formamide, N-methylformamide, N,N-dimethylformamide, acetamide, N-methylacetamide, N,N-dimethyl acetamide, propionamide, benzamide, pyrrolidone, N-methylpyrrolidone, and the like.

Examples of the urea compound include urea, methylurea, 1,1-dimethylurea, 1,3-dimethylurea, 1,1,3,3-tetramethylurea, 1,3-diphenylurea, tributylthiourea, and the like.

Examples of the nitrogen-containing heterocyclic compound include: pyridines such as pyridine and 2-methylpyridine; morpholines such as N-propylmorpholine and N-(undecan-1-ylcarbonyloxyethyl)morpholine; pyrazine and pyrazole; and the like.

A nitrogen-containing compound having an acid-labile group may also be used as the nitrogen-containing compound. Examples of the nitrogen-containing compound having an acid-labile group include N-t-butoxycarbonylpiperidine, N-t-butoxycarbonylimidazole, N-t-butoxycarbonylbenzimidazole, N-t-butoxycarbonyl-2-phenylbenzimidazole, N-(t-butoxycarbonyl)di-n-octylamine, N-(t-butoxycarbonyl)diethanolamine, N-(t-butoxycarbonyl)dicyclohexylamine, N-(t-butoxycarbonyl)diphenylamine, N-t-butoxycarbonyl-4-hydroxypiperidine, N-t-amyloxycarbonyl-4-hydroxypiperidine, and the like.

Of these, the nitrogen-containing heterocyclic compound is preferred, the morpholines are more preferred, and N-(undecan-1-ylcarbonyloxyethyl)morpholine is still more preferred.

Alternatively, a photolabile base which is sensitized upon an exposure to generate a weak acid may also be used as the other acid diffusion controller (G). The photolabile base is exemplified by an onium salt compound that loses acid diffusion controllability through degradation upon an exposure, and the like (except for those corresponding to the salt (C)).

Examples of the onium salt compound include triphenylsulfonium salicylate, 4-cyclohexylphenyldiphenylsulfonium salicylate, triphenylsulfonium acetylacetate, triphenylsulfonium 2,4,6-tri-i-propylbenzenesulfonate, triphenylsulfonium 10-camphorsulfonate, triphenylsulfonium 1-cyclohexylbutane-1,3-dion-2-ate, and the like. Of these, 4-cyclohexylphenyldiphenylsulfonium salicylate, triphenylsulfonium acetylacetate, triphenylsulfonium 2,4,6-tri-i-propylbenzenesulfonate, triphenylsulfonium 10-camphorsulfonate and triphenylsulfonium 1-cyclohexylbutane-1,3-dion-2-ate are preferred, and 4-cyclohexylphenyldiphenylsulfonium salicylate and triphenylsulfonium 1-cyclohexylbutane-1,3-dion-2-ate are more preferred.

When the radiation-sensitive resin composition contains the other acid diffusion control agent (G), the lower limit of the content of the other acid diffusion control agent (G) with respect to 100 parts by mass of the polymer (A) is preferably 0.1 parts by mass, more preferably 0.3 parts by mass, still more preferably 0.5 parts by mass, and particularly preferably 1 part by mass. The upper limit of the aforementioned content is preferably 20 parts by mass, more preferably 15 parts by mass, still more preferably 10 parts by mass, and particularly preferably 5 parts by mass.

Moreover, the lower limit of the content of the other acid diffusion control agent (G) with respect to 100 parts by mass of the salt (C) is preferably 10 parts by mass, more preferably 20 parts by mass, and still more preferably 25 parts by mass. The upper limit of the aforementioned content is preferably 95 parts by mass, more preferably 90 parts by mass, and still more preferably 85 parts by mass.

### Other Optional Component

The radiation-sensitive resin composition may contain other optional component than the components (A) to (G). The other optional component is exemplified by a surfactant, an alicyclic skeleton-containing compound, a sensitizing agent, and the like. These other optional components each may be used either alone of one type, or in combination of two or more types thereof.

### Surfactant

The surfactant achieves the effect of improving the application property, striation, developability, and the like. Examples of the surfactant include: nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate; commercially available products such as “KP341” available from Shin-Etsu Chemical Co., Ltd., “Polyflow No. 75” and “Polyflow No. 95” available from Kyoeisha Chemical Co., Ltd., “EFTOP EF301”, “EFTOP EF303” and “EFTOP EF352” available from Tochem Products Co. Ltd., “Megaface F171” and “Megaface F173” available from DIC, “Fluorad FC430” and “Fluorad FC431” available from Sumitomo 3M Limited, “ASAHI GUARD AG710”, “Surflon S-382”, “Surflon SC-101”, “Surflon SC-102”, “Surflon SC-103”, “Surflon SC-104”, “Surflon SC-105” and “Surflon SC-106” available from Asahi Glass Co., Ltd.; and the like. The upper limit of the content of the surfactant with respect to 100 parts by mass of the polymer (A) is preferably 2 parts by mass, and more preferably 1 part by mass.

### Alicyclic Skeleton-Containing Compound

The alicyclic skeleton-containing compound achieves the effect of improving dry-etching resistance, a pattern configuration, adhesiveness to a substrate, and the like.

### Sensitizing Agent

The sensitizing agent exhibit the action of increasing the amount of the acid generated from the acid generator (B) or the like, and achieves the effect of improving “apparent sensitivity” of the radiation-sensitive resin composition.

Examples of the sensitizing agent include carbazoles, acetophenones, benzophenones, naphthalenes, phenols, biacetyl, eosin, rose bengal, pyrenes, anthracenes, phenothiazines, and the like. These sensitizing agents may be used either alone, or two or more types thereof may be used in combination. The upper limit of the content of the sensitizing agent with respect to 100 parts by mass of the polymer (A) is preferably 2 parts by mass, and more preferably 1 part by mass.

### Preparation Method of Radiation-Sensitive Resin Composition

The radiation-sensitive resin composition may be prepared, for example, by mixing the polymer (A), the acid generator (B) and the salt (C), as well as the polymer (D), the solvent (E) and other optional component(s) which are contained as needed, at a predetermined ratio, and preferably filtering the resulting mixture through a filter having a pore size of about 0.2 μm, for example. The lower limit of the solid content concentration of the radiation-sensitive resin composition is preferably 0.1% by mass, more preferably 0.5 parts by mass, and still more preferably 1% by mass. The upper limit of the aforementioned solid content concentration is preferably 50% by mass, more preferably 30% by mass, and still more preferably 20% by mass.

The radiation-sensitive resin composition may be used for formation of positive type patterns by using an alkaline developer solution, and formation of negative type patterns by using a developer solution containing an organic solvent. Of these, when used for the formation of negative type patterns by using the developer solution containing the organic solvent, the radiation-sensitive resin composition may exhibit more superior resolution.

### Resist Pattern-Forming Method

The resist pattern-forming method according to another embodiment of the present invention includes: the step of forming a resist film (hereinafter, may be also referred to as “resist film-forming step”); the step of exposing the resist film (hereinafter, may be also referred to as “exposure step”); and the step of developing the resist film exposed (hereinafter, may be also referred to as “development step”). According to the resist pattern-forming method, the resist film is formed from the radiation-sensitive resin composition according to the embodiment of the present invention.

According to the resist pattern-forming method, since the radiation-sensitive resin composition described above is used, a resist pattern that is superior in LWR performances, CDU performances, resolution and rectangularity of cross-sectional shape can be formed while superior depth of focus and MEEF performances are exhibited. Hereinafter, each step will be described.

### Resist Film-Forming Step

In this step, a resist film is formed from the radiation-sensitive resin composition. The substrate on which the resist film is formed is exemplified by a silicon wafer, a wafer coated with aluminum, and the like. The radiation-sensitive resin composition is applied on the substrate to form the resist film. The application procedure of the radiation-sensitive resin composition is not particularly limited, and is exemplified by a well-known procedure such as spin coating. When the radiation-sensitive resin composition is applied, the amount of the radiation-sensitive resin composition applied is adjusted such that the resist film formed has a desired thickness. It is to be noted that after the radiation-sensitive resin composition is applied on the substrate, soft baking (hereinafter, may be also referred to as “SB”) may be carried out to evaporate the solvent. The lower limit of the temperature of SB is preferably 30° C., and more preferably 50° C. The upper limit of the aforementioned temperature is preferably 200° C., and more preferably 150° C. The lower limit of the time period of SB is preferably 10 sec, and more preferably 30 sec. The upper limit of the time period is preferably 600 sec, and more preferably 300 sec. The lower limit of the average thickness of the resist film is preferably 10 nm, and more preferably 20 nm. The upper limit of the aforementioned average thickness is preferably 1,000 nm, and more preferably 200 nm.

### Exposure Step

In this step, the resist film formed in the resist film-forming step is exposed. The exposure may be carried out by irradiation with a radioactive ray through a mask having a predetermined pattern, and through a liquid for liquid immersion lithography such as water, as needed.

A liquid having a refractive index greater than that of air is typically used as the liquid for liquid immersion lithography. Specific examples of such a liquid include pure water, long chain or cyclic aliphatic compounds, and the like. The resist film is irradiated with the radioactive ray emitted from a lithography device through the liquid for liquid immersion lithography, i.e., with a space between a lens and the resist film being filled with the liquid for liquid immersion lithography, whereby the resist film is exposed through a mask having a predetermined pattern.

The radioactive ray used may be appropriately selected from a visible light ray, an ultraviolet ray, a far ultraviolet ray, an X-ray, a charged particle ray and the like in accordance with the type of the radiation-sensitive acid generator used, and of these, far ultraviolet rays such as an ArF excimer laser beam (wavelength: 193 nm) and a KrF excimer laser beam (wavelength: 248 nm) are preferred, and the ArF excimer laser beam (wavelength: 193 nm) is more preferred. It is to be noted that exposure conditions such as an exposure dose may be appropriately selected in accordance with the blend composition of the resist composition for liquid immersion lithography, the type of an additive, and the like.

The exposed resist film is preferably subjected to a baking treatment (hereinafter, may be also referred to as “post exposure baking (PEB)”). The PEB enables the dissociation reaction of the acid-labile group included in the polymer (A) or the like to smoothly proceed. The baking conditions for the PEB may be appropriately adjusted in accordance with the blend composition of the radiation-sensitive resin composition, and the lower limit of the temperature of PEB is preferably 30° C., more preferably 50° C., and still more preferably 60° C. The upper limit of the aforementioned temperature is preferably 200° C., more preferably 150° C., and still more preferably 120° C. The lower limit of the time period of PEB is preferably 10 sec, and more preferably 30 sec. The upper limit of the time period is preferably 600 sec, and more preferably 300 sec.

In addition, in order to maximally utilize the potential of the radiation-sensitive resin composition, an organic or inorganic antireflective film may also be formed on the substrate employed, as disclosed in, for example, Japanese Examined Patent Application, Publication No. H6-12452, Japanese Unexamined Patent Application, Publication No. S59-93448, and the like. Moreover, in order to avoid the influence of basic impurities and the like contained in an environment atmosphere, a protective film may be provided on the resist film, as disclosed in, for example, Japanese Unexamined Patent Application, Publication No. H5-188598, and the like.

### Development Step

In this step, the resist film exposed in the exposure step is developed. The developer solution for use in this development is exemplified by an alkaline aqueous solution (alkaline developer solution), a liquid containing an organic solvent (organic solvent developer solution), and the like. Thus, a predetermined resist pattern is formed.

The alkaline developer solution is exemplified by alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, etc., and the like. Of these, an aqueous TMAH solution is preferred, and a 2.38% by mass aqueous TMAH solution is more preferred.

The organic solvent developer solution is exemplified by organic solvents such as hydrocarbon solvents, ether solvents, ester solvents, ketone solvents and alcohol solvents, or liquids containing an organic solvent. Examples of the organic solvent include one type, or two or more types of the solvents exemplified in connection with the solvent (E) of the aforementioned radiation-sensitive resin composition, and the like. Of these, the ester solvents and the ketone solvents are preferred. As the ester solvent, acetic acid ester solvents are preferred, and n-butyl acetate is more preferred. As the ketone solvent, chain ketones are preferred, and 2-heptanone is more preferred. The lower limit of the content of the organic solvent in the organic solvent developer solution is preferably 80% by mass, more preferably 90% by mass, still more preferably 95% by mass, and particularly preferably 99% by mass. Components other than the organic solvent in the organic solvent developer solution are exemplified by water, silicone oil, and the like.

These developer solutions may be used either alone, or in combination of two or more types thereof. It is to be noted that washing with water or the like, followed by drying, is generally carried out after the development.

### EXAMPLES

Hereinafter, the present invention is explained in detail by way of Examples, but the present invention is not in any way limited to these Examples. Measuring methods for various types of physical properties are shown below.

### Weight Average Molecular Weight (Mw) and Number Average Molecular Weight (Mn)

The Mw and the Mn were determined by GPC using GPC columns (“G2000 HXL”×2, “G3000 HXL”×1 and “G4000 HXL”×1 available from Tosoh Corporation), a differential refractometer as a detector, and mono-dispersed polystyrene as a standard under analytical conditions involving a flow rate of 1.0 mL/min, an elution solvent of tetrahydrofuran (available from Wako Pure Chemical Industries, Ltd.), sample concentration of 1.0% by mass, an amount of injected sample of 100 μL, a column temperature of 40° C. Moreover, the value of the Mw/Mn (dispersity index) was calculated from the result of the determination of the Mw and the Mn.

¹³C-NMR Analysis

Analysis for determining the proportion (mol %) of each structural unit contained in the polymer was carried out using a nuclear magnetic resonance apparatus (“JNM-ECX400” available from JEOL, Ltd.) and deuterochloroform as a solvent for measurement.

### Synthesis of Polymer (A) and Polymer (D)

Monomers used in the synthesis of each polymer are shown below.

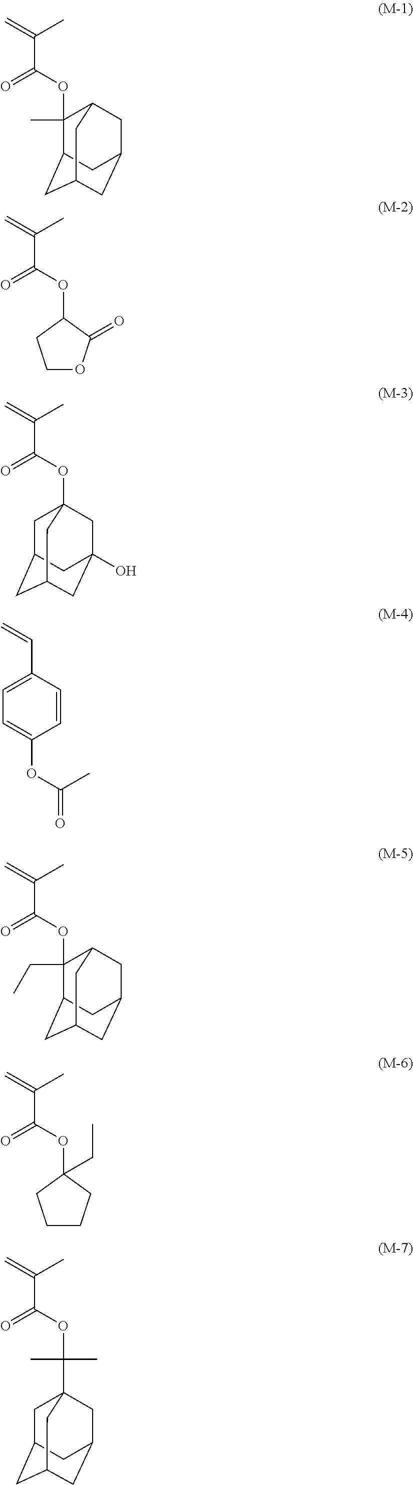

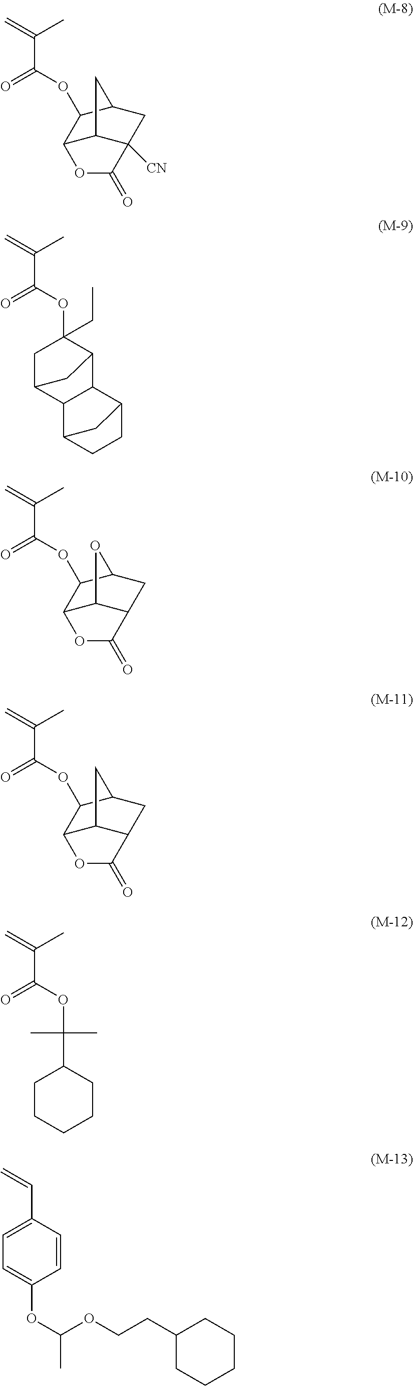

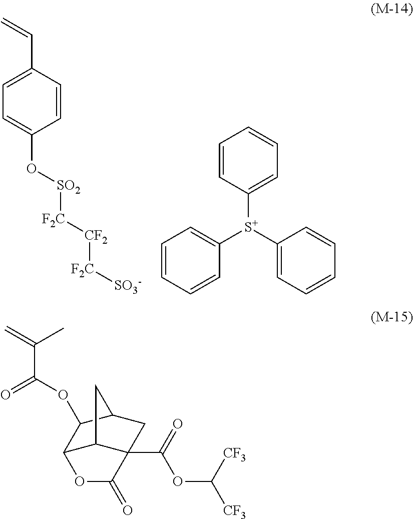

### Synthesis of Polymer (A)

### Synthesis Example 1

### Synthesis of Polymer (A-1)

A monomer solution was prepared by dissolving 7.97 g (35 mol %) of the compound (M-1), 7.44 g (45 mol %) of the compound (M-2) and 4.49 g (20 mol %) of the compound (M-3) in 40 g of 2-butanone, and further adding thereto 0.80 g (5 mol % with respect to the total number of moles of the compounds) of AIBN as a radical polymerization initiator. Next, a 100 mL three-neck flask containing 20 g of 2-butanone was purged with a nitrogen gas for 30 min, followed by heating to 80° C. with stirring, and the monomer solution prepared as described above was added dropwise over 3 hrs using a dropping funnel. The time of the start of the dropwise addition was regarded as the time of the start of the polymerization reaction, and the polymerization reaction was allowed to proceed for 6 hrs. After the completion of the polymerization reaction, the polymerization reaction mixture was water-cooled to 30° C. or below. The polymerization reaction mixture was poured into 400 g of methanol, and a precipitated white powder was filtered off. The collected white powder was washed twice with 80 g of methanol, followed by filtration, and dried at 50° C. for 17 hrs to synthesize a polymer (A-1) as a white powder (amount: 15.2 g; yield: 76%). The polymer (A-1) had an Mw of 7,300 and an Mw/Mn of 1.53. The result of ¹³C-NMR analysis indicated that the proportions of the structural units derived from (M-1), (M-2) and (M-3) was 34.3 mol %, 45.1 mol % and 20.6 mol %, respectively.

### Synthesis Examples 2 to 4, 6 and 7

### Synthesis of Polymers (A-2) to (A-4), (A-6) and (A-7)

Polymers (A-2) to (A-4), (A-6) and (A-7) were synthesized in a similar manner to Synthesis Example 1 except that the type and the amount of the monomer used were as shown in Table 1. The total mass of the monomers used was 20 g. Values of the yield (%), the Mw, the Mw/Mn, and the proportion (mol %) of each structural unit of the obtained polymer are shown together in Table 1 below.

### Synthesis Example 5

### Synthesis of Polymer (A-5)

After 55.0 g (65 mol %) of the compound (M-4) and 45.0 g (35 mol %) of the compound (M-5), 4 g of AIBN as a radical polymerization initiator, and 1 g of t-dodecyl mercaptan were dissolved in 100 g of propylene glycol monomethyl ether, the mixture was subjected to copolymerization for 16 hrs under a nitrogen atmosphere, while the reaction temperature was maintained at 70° C. After the completion of the polymerization reaction, the polymerization reaction mixture was added dropwise to 1,000 g of n-hexane to permit solidification purification of a polymer. Next, to the resulting polymer was added 150 g of propylene glycol monomethyl ether, and then 150 g of methanol, 34 g of triethylamine and 6 g of water were further added. The mixture was subjected to a hydrolysis reaction for 8 hrs while refluxing at a boiling point was allowed. After the completion of the reaction, the solvent and triethylamine were distilled off in vacuo, the resulting polymer was dissolved in 150 g of acetone, which was then added dropwise to 2,000 g of water to permit solidification, and the formed white powder was filtered off and was dried at 50° C. for 17 hrs to obtain a polymer (A-5) as a white powder (amount: 65.7 g; yield: 77%). The polymer (A-5) had an Mw of 7,500 and an Mw/Mn of 1.90. The result of ¹³C-NMR analysis indicated that the proportions of the structural units derived from p-hydroxystyrene and (M-5) were 65.4 mol % and 34.6 mol %, respectively.

TABLE 1

| | | | | | Monomer that gives | | | | | |
|---|---|---|---|---|---|---|---|---|---|---|
| | | Monomer that gives | | | structural unit other than | | | | | |
| | | structural unit (I) | | | structural unit (I) | | | | | |
| | | | | proportion | | | proportion | | | |
| | (A) | | amount | of structural | | amount | of structural | Yield | | |
| | polymer | type | (mol %) | unit (mol %) | type | (mol %) | unit (mol %) | (%) | Mw | Mw/Mn |
| Synthesis | A-1 | M-1 | 35 | 34.3 | M-2 | 45 | 45.1 | 76 | 7,300 | 1.53 |
| Example 1 | | | | | M-3 | 20 | 20.6 | | | |
| Synthesis | A-2 | M-6 | 40 | 40.1 | M-8 | 50 | 49.8 | 75 | 7,500 | 1.55 |
| Example 2 | | M-7 | 10 | 10.1 | | | | | | |
| Synthesis | A-3 | M-6 | 20 | 19.5 | M-10 | 40 | 40.1 | 77 | 7,200 | 1.53 |
| Example 3 | | M-9 | 15 | 15.5 | M-3 | 25 | 24.9 | | | |
| Synthesis | A-4 | M-12 | 50 | 50.1 | M-11 | 50 | 49.9 | 76 | 7,300 | 1.53 |
| Example 4 | | | | | | | | | | |
| Synthesis | A-5 | M-5 | 35 | 34.6 | M-4 | 65 | 65.4 | 77 | 7,500 | 1.90 |
| Example 5 | | | | | | | | | | |
| Synthesis | A-6 | M-13 | 40 | 39.9 | M-8 | 60 | 60.1 | 75 | 7,500 | 1.62 |
| Example 6 | | | | | | | | | | |
| Synthesis | A-7 | M-6 | 40 | 39.9 | M-10 | 55 | 55.1 | 76 | 7,400 | 1.65 |
| Example 7 | | | | | M-14 | 5 | 5.0 | | | |

### Synthesis of Polymer (D)

### Synthesis Example 8

### Synthesis of Polymer (D-1)

A monomer solution was prepared by dissolving 82.2 g (70 mol %) of the compound (M-15) and 17.8 g (30 mol %) of the compound (M-12) in 200 g of 2-butanone, and adding thereto 0.46 g (1 mol % with respect to the total number of moles of the compounds) of AIBN as a radical polymerization initiator. Next, a 500 mL three-neck flask containing 100 g of 2-butanone was purged with a nitrogen gas for 30 min, followed by heating to 80° C. with stirring, and the monomer solution prepared as described above was added dropwise over 3 hrs using a dropping funnel. The time of the start of the dropwise addition was regarded as the time of the start of the polymerization reaction, and the polymerization reaction was allowed to proceed for 6 hrs. After the completion of the polymerization reaction, the polymerization reaction mixture was water-cooled to 30° C. or below. After the solvent was replaced with 400 g of acetonitrile, an operation of adding 100 g of hexane, followed by stirring, and collecting the acetonitrile layer was repeated three times. The solvent was replaced with propylene glycol monomethyl ether acetate, whereby a solution containing 60.1 g of a polymer (D-1) was obtained (yield: 60%). The polymer (D-1) had an Mw of 15,000 and an Mw/Mn of 1.90. The result of ¹³C-NMR analysis indicated that the proportions of the structural units derived from (M-15) and (M-12) were 70.3 mol % and 29.7 mol %, respectively.

### Preparation of Radiation-Sensitive Resin Composition

The acid generating agent (B), the salt (C), the solvent (E), the localization accelerator (F) and the other acid diffusion control agent (G) which were used in the preparation of the radiation-sensitive resin composition are shown below.

### (B) Acid Generating Agent

Each structural formula is shown below.
B-1: triphenylsulfonium 2-(adamantan-1-ylcarbonyloxy)-1,1,3,3,3-pentafluoropropane-1-sulfonate
B-2: triphenylsulfonium norbornanesultone-2-yloxycarbonyldifluoromethanesulfonate
B-3: triphenylsulfonium 3-(piperidin-1-ylsulfonyl)-1,1,2,2,3,3-hexafluoropropane-1-sulfonate
B-4: triphenylsulfonium adamantan-1-yloxycarbonyldifluoromethanesulfonate
B-5: triphenylsulfonium hexafluoropropanedisulfonylimide
B-6: triphenylsulfonium 3-(4,4-ethanediyldioxyadamantan-1-yl)-2-trifluoromethylpropane-1-sulfonate
B-7: triphenylsulfonium 1,2-di(cyclohexylmethoxycarbonyl)ethane-1-sulfonate

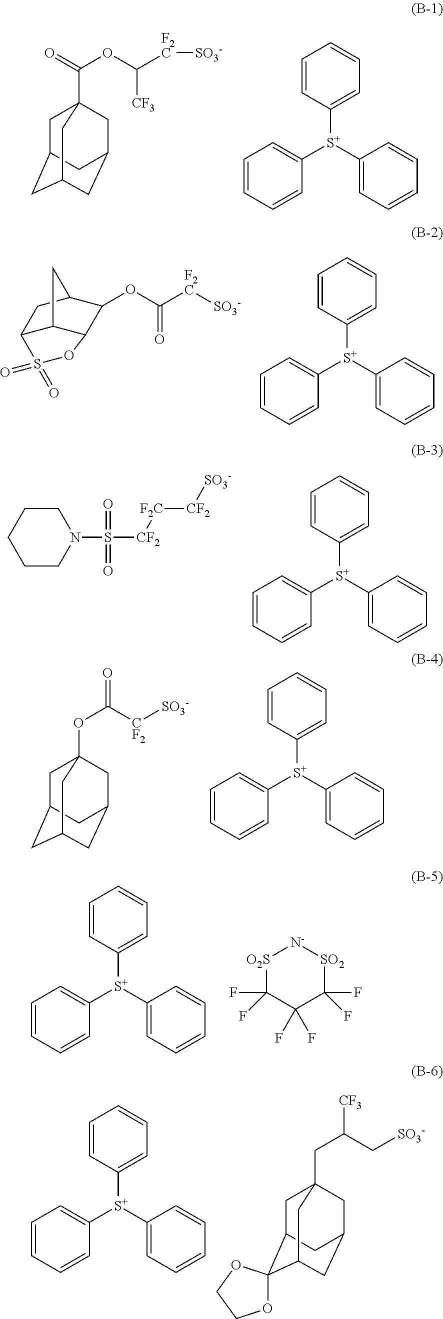

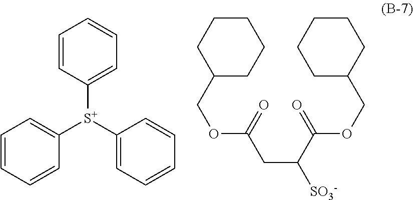

### (C) Salt

Each structural formula is shown below.
Z-1: 4-cyclohexylphenyldiphenylsulfonium hydrogencarbonate
Z-2: tri(4-t-butylphenyl)sulfonium hydrogencarbonate
Z-3: tri(4-trifluoromethylphenyl)sulfonium hydrogencarbonate
Z-4: tetra-n-butylammonium hydrogencarbonate
Z-5: 4-n-butoxynaphthalen-1-yltetrahydrothiophenium hydrogencarbonate
Z-6: naphthalen-2-ylcarbonylmethyltetrahydrothiophenium hydrogencarbonate
Z-7: bis(4-cyclohexylsulfonylphenyldiphenylsulfonium) carbonate
Z-8: 4-methoxyphenyldiphenylsulfonium cyclohexylmethyltri-n-butylammonium carbonate

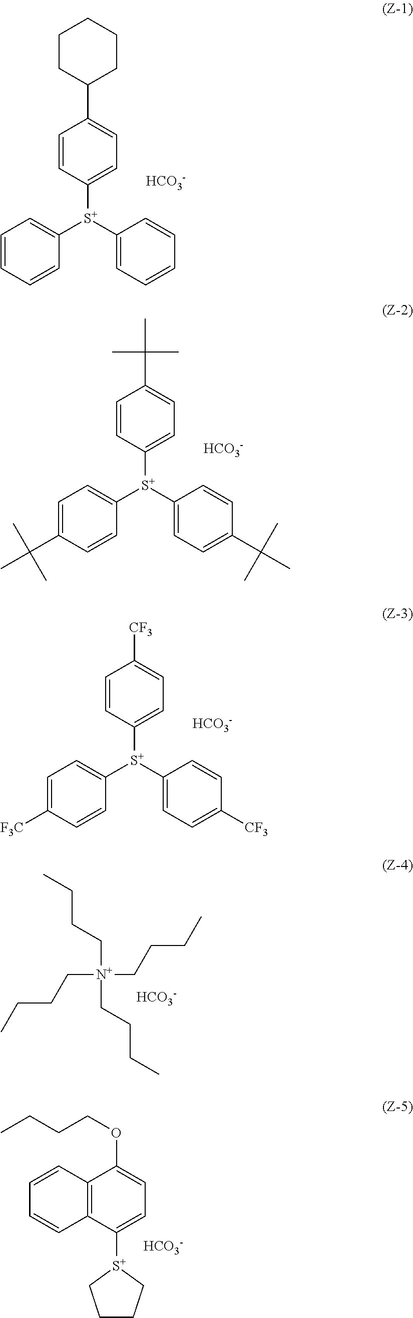

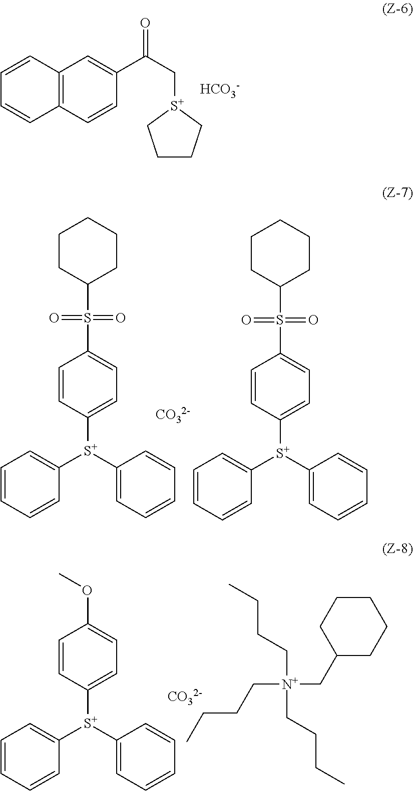

### (E) Solvent

E-1: propylene glycol monomethyl ether acetate
E-2: cyclohexanone

### (F) Localization Accelerator

F-1: γ-butyrolactone

### (G) Other Acid Diffusion Control Agent

Each structural formula is shown below.
G-1: 4-cyclohexylphenyldiphenylsulfonium benzoate
G-2: triphenylsulfonium 1-cyclohexyl-1,3-dioxo-2-butanide
G-3: N-n-undecylcarbonyloxyethylmorpholine
G-4: triethanolamine
G-5: N-t-butoxycarbonyl-4-hydroxypiperidine

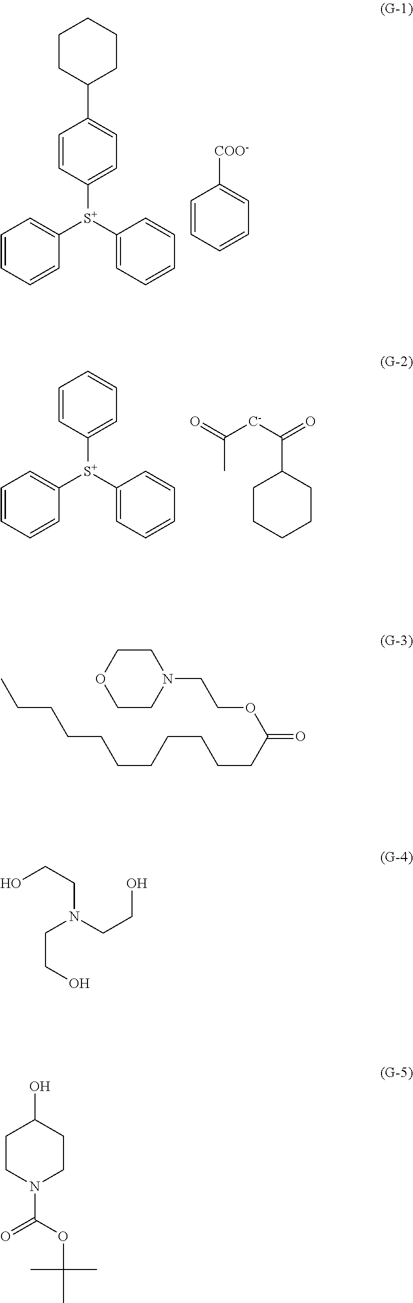

### Preparation of Radiation-Sensitive Resin Composition for ArF Exposure Example 1

A radiation-sensitive resin composition (J1-1) was prepared by mixing 100 parts by mass of (A-1) as the polymer (A), 8.5 parts by mass of (B-1) as the acid generating agent (B), 2.3 parts by mass of (Z-1) as the salt (C), 3 parts by mass of (D-1) as the polymer (D), 2,240 parts by mass of (E-1) and 960 parts by mass of (E-2) as the solvent (E), and 30 parts by mass of (F-1) as the localization accelerator (F), and thereafter filtering the resulting mixture through a membrane filter having a pore size of 0.2 μm.

### Examples 2 to 14 and Comparative Examples 1 to 10

Each radiation-sensitive resin composition was prepared by a similar operation to that of Example 1 except that the type and the content of each component used were as shown in Table 2. In Table 2, “−” indicates that the corresponding component was not used.

TABLE 2

| | | | | (B) Acid | | | | | | | | (F) | | (G) Other acid | |
|---|---|---|---|---|---|---|---|---|---|---|---|---|---|---|---|
| | | | | generating | | | | | | | | Localization | | diffusion | |
| | | (A) Polymer | | agent | | (C) Salt | | (D) Polymer | | (E) Solvent | | accelerator | | control agent | |
| | Radiation- | | content | | content | | content | | content | | content | | content | | content |
| | sensitive | | (parts | | (parts | | (parts | | (parts | | (parts | | (parts | | (parts |
| | resin | | by | | by | | by | | by | | by | | by | | by |
| | composition | type | mass) | type | mass) | type | mass) | type | mass) | type | mass) | type | mass) | type | mass) |
| Example 1 | J1-1 | A-1 | 100 | B-1 | 8.5 | Z-1 | 2.3 | D-1 | 3 | E-1/E-2 | 2,240/960 | F-1 | 30 | — | — |
| Example 2 | J1-2 | A-1 | 100 | B-1 | 8.5 | Z-2 | 2.3 | D-1 | 3 | E-1/E-2 | 2,240/960 | F-1 | 30 | — | — |
| Example 3 | J1-3 | A-1 | 100 | B-1 | 8.5 | Z-3 | 2.3 | D-1 | 3 | E-1/E-2 | 2,240/960 | F-1 | 30 | — | — |
| Example 4 | J1-4 | A-1 | 100 | B-1 | 8.5 | Z-4 | 2.3 | D-1 | 3 | E-1/E-2 | 2,240/960 | F-1 | 30 | — | — |
| Example 5 | J1-5 | A-1 | 100 | B-1 | 8.5 | Z-5 | 2.3 | D-1 | 3 | E-1/E-2 | 2,240/960 | F-1 | 30 | — | — |
| Example 6 | J1-6 | A-1 | 100 | B-1 | 8.5 | Z-6 | 2.3 | D-1 | 3 | E-1/E-2 | 2,240/960 | F-1 | 30 | — | — |
| Example 7 | J1-7 | A-1 | 100 | B-1 | 8.5 | Z-7 | 2.3 | D-1 | 3 | E-1/E-2 | 2,240/960 | F-1 | 30 | — | — |
| Example 8 | J1-8 | A-1 | 100 | B-1 | 8.5 | Z-8 | 2.3 | D-1 | 3 | E-1/E-2 | 2,240/960 | F-1 | 30 | — | — |
| Example 9 | J1-9 | A-1 | 100 | B-1 | 8.5 | Z-1 | 1.3 | D-1 | 3 | E-1/E-2 | 2,240/960 | F-1 | 30 | G-5 | 1.0 |
| Example 10 | J1-10 | A-2 | 100 | B-2 | 8.5 | Z-1 | 2.3 | D-1 | 3 | E-1/E-2 | 2,240/960 | F-1 | 30 | — | — |
| Example 11 | J1-11 | A-3 | 100 | B-3 | 8.5 | Z-1 | 2.3 | D-1 | 3 | E-1/E-2 | 2,240/960 | F-1 | 30 | — | — |
| Example 12 | J1-12 | A-4 | 100 | B-4 | 8.5 | Z-1 | 2.3 | D-1 | 3 | E-1/E-2 | 2,240/960 | F-1 | 30 | — | — |
| Example 13 | J1-13 | A-2 | 100 | B-5 | 8.5 | Z-1 | 2.3 | D-1 | 3 | E-1/E-2 | 2,240/960 | F-1 | 30 | — | — |
| Example 14 | J1-14 | A-3 | 100 | B-6 | 8.5 | Z-1 | 2.3 | D-1 | 3 | E-1/E-2 | 2,240/960 | F-1 | 30 | — | — |
| Comparative | CJ1-1 | A-1 | 100 | B-1 | 8.5 | — | — | D-1 | 3 | E-1/E-2 | 2,240/960 | F-1 | 30 | G-1 | 2.3 |
| Example 1 | | | | | | | | | | | | | | | |
| Comparative | CJ1-2 | A-1 | 100 | B-1 | 8.5 | — | — | D-1 | 3 | E-1/E-2 | 2,240/960 | F-1 | 30 | G-2 | 2.3 |
| Example 2 | | | | | | | | | | | | | | | |
| Comparative | CJ1-3 | A-1 | 100 | B-1 | 8.5 | — | — | D-1 | 3 | E-1/E-2 | 2,240/960 | F-1 | 30 | G-3 | 2.3 |
| Example 3 | | | | | | | | | | | | | | | |
| Comparative | CJ1-4 | A-1 | 100 | B-1 | 8.5 | — | — | D-1 | 3 | E-1/E-2 | 2,240/960 | F-1 | 30 | G-4 | 2.3 |
| Example 4 | | | | | | | | | | | | | | | |
| Comparative | CJ1-5 | A-1 | 100 | B-1 | 8.5 | — | — | D-1 | 3 | E-1/E-2 | 2,240/960 | F-1 | 30 | G-5 | 2.3 |
| Example 5 | | | | | | | | | | | | | | | |
| Comparative | CJ1-6 | A-2 | 100 | B-2 | 8.5 | — | — | D-1 | 3 | E-1/E-2 | 2,240/960 | F-1 | 30 | G-1 | 2.3 |
| Example 6 | | | | | | | | | | | | | | | |
| Comparative | CJ1-7 | A-3 | 100 | B-3 | 8.5 | — | — | D-1 | 3 | E-1/E-2 | 2,240/960 | F-1 | 30 | G-1 | 2.3 |
| Example 7 | | | | | | | | | | | | | | | |
| Comparative | CJ1-8 | A-4 | 100 | B-4 | 8.5 | — | — | D-1 | 3 | E-1/E-2 | 2,240/960 | F-1 | 30 | G-1 | 2.3 |
| Example 8 | | | | | | | | | | | | | | | |
| Comparative | CJ1-9 | A-2 | 100 | B-5 | 8.5 | — | — | D-1 | 3 | E-1/E-2 | 2,240/960 | F-1 | 30 | G-1 | 2.3 |
| Example 9 | | | | | | | | | | | | | | | |
| Comparative | CJ1-10 | A-3 | 100 | B-6 | 8.5 | — | — | D-1 | 3 | E-1/E-2 | 2,240/960 | F-1 | 30 | G-1 | 2.3 |
| Example 10 | | | | | | | | | | | | | | | |

### Preparation of Radiation-Sensitive Resin Composition for Electron Beam Exposure

### Example 15

A radiation-sensitive resin composition (J2-1) was prepared by mixing 100 parts by mass of (A-5) as the polymer (A), 20 parts by mass of (B-1) as the acid generating agent (B), 3.6 parts by mass of (Z-1) as the salt (C), and 4,280 parts by mass (E-1) and 1,830 parts by mass of (E-2) as the solvent (E), and thereafter filtering the resulting mixture through a membrane filter having a pore size of 0.2 μm.

### Examples 16 to 30 and Comparative Examples 11 to 22

Each radiation-sensitive resin composition was prepared by a similar operation to that of Example 15 except that the type and the content of each component used were as shown in Table 3. In Table 3, “−” indicates that the corresponding monomer was not used.

TABLE 3

| | | | | (B) Acid | | | | | | (G) Other acid | |
|---|---|---|---|---|---|---|---|---|---|---|---|
| | | | | generating | | | | | | diffusion | |
| | | (A) Polymer | | agent | | (C) Salt | | (E) Solvent | | control agent | |
| | Radiation- | | content | | content | | content | | content | | content |
| | sensitive | | (parts | | (parts | | (parts | | (parts | | (parts |
| | resin | | by | | by | | by | | by | | by |
| | composition | type | mass) | type | mass) | type | mass) | type | mass) | type | mass) |
| Example 15 | J2-1 | A-5 | 100 | B-1 | 20 | Z-l | 3.6 | E-1/E-2 | 4,280/1,830 | — | — |
| Example 16 | J2-2 | A-5 | 100 | B-1 | 20 | Z-2 | 3.6 | E-1/E-2 | 4,280/1,830 | — | — |
| Example 17 | J2-3 | A-5 | 100 | B-1 | 20 | Z-3 | 3.6 | E-1/E-2 | 4,280/1,830 | — | — |
| Example 18 | J2-4 | A-5 | 100 | B-1 | 20 | Z-4 | 3.6 | E-1/E-2 | 4,280/1,830 | — | — |
| Example 19 | J2-5 | A-5 | 100 | B-1 | 20 | Z-5 | 3.6 | E-1/E-2 | 4,280/1,830 | — | — |
| Example 20 | J2-6 | A-5 | 100 | B-1 | 20 | Z-6 | 3.6 | E-1/E-2 | 4,280/1,830 | — | — |
| Example 21 | J2-7 | A-5 | 100 | B-1 | 20 | Z-7 | 3.6 | E-1/E-2 | 4,280/1,830 | — | — |
| Example 22 | J2-8 | A-5 | 100 | B-1 | 20 | Z-8 | 3.6 | E-1/E-2 | 4,280/1,830 | — | — |
| Example 23 | J2-9 | A-5 | 100 | B-1 | 20 | Z-1 | 2.0 | E-1/E-2 | 4,280/1,830 | G-5 | 1.6 |
| Example 24 | J2-10 | A-1 | 100 | B-2 | 20 | Z-1 | 3.6 | E-1/E-2 | 4,280/1,830 | — | — |
| Example 25 | J2-11 | A-2 | 100 | B-3 | 20 | Z-1 | 3.6 | E-1/E-2 | 4,280/1,830 | — | — |
| Example 26 | J2-12 | A-3 | 100 | B-4 | 20 | Z-1 | 3.6 | E-1/E-2 | 4,280/1,830 | — | — |
| Example 27 | J2-13 | A-4 | 100 | B-5 | 20 | Z-1 | 3.6 | E-1/E-2 | 4,280/1,830 | — | — |
| Example 28 | J2-14 | A-6 | 100 | B-6 | 20 | Z-1 | 3.6 | E-1/E-2 | 4,280/1,830 | — | — |
| Example 29 | J2-15 | A-6 | 100 | B-7 | 20 | Z-1 | 3.6 | E-1/E-2 | 4,280/1,830 | — | — |
| Example 30 | J2-16 | A-7 | 100 | — | — | Z-1 | 3.6 | E-1/E-2 | 4,280/1,830 | — | — |
| Comparative | CJ2-1 | A-5 | 100 | B-1 | 20 | — | — | E-1/E-2 | 4,280/1,830 | G-1 | 3.6 |
| Example 11 | | | | | | | | | | | |
| Comparative | CJ2-2 | A-5 | 100 | B-1 | 20 | — | — | E-1/E-2 | 4,280/1,830 | G-2 | 3.6 |
| Example 12 | | | | | | | | | | | |
| Comparative | CJ2-3 | A-5 | 100 | B-1 | 20 | — | — | E-1/E-2 | 4,280/1,830 | G-3 | 3.6 |
| Example 13 | | | | | | | | | | | |
| Comparative | CJ2-4 | A-5 | 100 | B-1 | 20 | — | — | E-1/E-2 | 4,280/1,830 | G-4 | 3.6 |
| Example 14 | | | | | | | | | | | |
| Comparative | CJ2-5 | A-5 | 100 | B-1 | 20 | — | — | E-1/E-2 | 4,280/1,830 | G-5 | 3.6 |
| Example 15 | | | | | | | | | | | |
| Comparative | CJ2-6 | A-1 | 100 | B-2 | 20 | — | — | E-1/E-2 | 4,280/1,830 | G-1 | 3.6 |
| Example 16 | | | | | | | | | | | |
| Comparative | CJ2-7 | A-2 | 100 | B-3 | 20 | — | — | E-1/E-2 | 4,280/1,830 | G-1 | 3.6 |
| Example 17 | | | | | | | | | | | |
| Comparative | CJ2-8 | A-3 | 100 | B-4 | 20 | — | — | E-1/E-2 | 4,280/1,830 | G-1 | 3.6 |
| Example 18 | | | | | | | | | | | |
| Comparative | CJ2-9 | A-4 | 100 | B-5 | 20 | — | — | E-1/E-2 | 4,280/1,830 | G-1 | 3,6 |
| Example 19 | | | | | | | | | | | |
| Comparative | CJ2-10 | A-6 | 100 | B-6 | 20 | — | — | E-1/E-2 | 4,280/1,830 | G-1 | 3.6 |
| Example 20 | | | | | | | | | | | |
| Comparative | CJ2-11 | A-6 | 100 | B-7 | 20 | — | — | E-1/E-2 | 4,280/1,830 | G-1 | 3.6 |
| Example 21 | | | | | | | | | | | |
| Comparative | CJ2-12 | A-7 | 100 | — | — | — | — | E-1/E-2 | 4,280/1,830 | G-1 | 3.6 |
| Example 22 | | | | | | | | | | | |

### Resist Pattern Formation

ArF Exposure

### Resist Pattern Formation (1)

An underlayer antireflective film having an average thickness of 105 nm was formed on the surface of a 12-inch silicon wafer by applying a composition for underlayer antireflective film formation (“ARC66” available from Brewer Science) on the surface of the 12-inch silicon wafer using a spin-coater (“CLEAN TRACK ACT12” available from Tokyo Electron Limited), and thereafter baking the composition at 205° C. for 60 sec. The radiation-sensitive resin composition prepared as described above was applied on the underlayer antireflective film using the spin-coater, and subjected to SB at 90° C. for 60 sec. Thereafter, cooling was carried out at 23° C. for 30 sec to form a resist film having an average thickness of 90 nm. Next, the resist film was exposed using an ArF excimer laser Immersion Scanner (“NSR-S610C” available from NIKON) through a 40 nm line-and-space (1L1S) mask pattern, under optical conditions involving NA of 1.3 and dipole (Sigma: 0.977/0.782). After the exposure, PEB was carried out at 90° C. for 60 sec. Thereafter, a development was carried out with a 2.38% by mass aqueous TMAH solution as an alkaline developer solution, followed by washing with water and drying to form a positive resist pattern. In this resist pattern formation, an exposure dose at which a 1:1 line-and-space with a line width of 40 nm was formed through a mask for a 1:1 line-and-space with a target dimension of 40 nm was defined as “optimum exposure dose (Eop)”.

### Resist Pattern Formation (2)

A negative resist pattern was formed by a similar operation to that of the Formation of Resist Pattern (1) described above except that: n-butyl acetate was used in place of the aqueous TMAH solution used in the Formation of Resist Pattern (1) described above to execute a development with an organic solvent; and the washing with water was not carried out.

### Electron Beam Exposure

### Resist Pattern Formation (3)

The radiation-sensitive resin composition prepared as described above was applied on the surface of an 8-inch silicon wafer using a spin-coater (“CLEAN TRACK ACT8” available from Tokyo Electron Limited), and subjected to SB at 90° C. for 60 sec. Thereafter, cooling was carried out at 23° C. for 30 sec to form a resist film having an average thickness of 50 nm. Next, this resist film was irradiated with an electron beam using a simplified electron beam writer (“HL800D” available from Hitachi, Ltd.; output: 50 KeV, electric current density: 5.0 A/cm²). After the irradiation, PEB was carried out at 120° C. for 60 sec. Thereafter, a development was carried out using a 2.38% by mass aqueous TMAH solution as an alkaline developer solution at 23° C. for 30 sec, followed by washing with water and drying to form a positive resist pattern.

### Resist Pattern Formation (4)

A negative resist pattern was formed by a similar operation to that of the Formation of Resist Pattern (3) described above except that: n-butyl acetate was used in place of the aqueous TMAH solution used in the Formation of Resist Pattern (3) described above to execute a development with an organic solvent; and the washing with water was not carried out.

### Evaluations

The LWR performance, the CDU performance, the resolution, the rectangularity of cross-sectional shape, the depth of focus and the MEEF performance of the resist pattern formed using each radiation-sensitive resin composition were evaluated according to the following methods. The results of the evaluations are shown in Tables 4 and 5. For a line-width measurement of the resist patterns, a scanning electron microscope (“CG-4100” available from Hitachi High-Technologies Corporation) was used.

### LWR Performance

The resist pattern formed through an irradiation at the exposure dose of the Eop was observed from above the pattern using the scanning electron microscope. The line width was measured at arbitrary points of 50 in total, then a 3 Sigma value was determined from the distribution of the measurements, and the value was defined as “LWR performance” (nm). The smaller value is more favorable since a better LWR performance is indicated, revealing a less irregularity. In the ArF exposure, the LWR performance was evaluated to be: “favorable” in a case where the value of the LWR performance was no greater than 3.4 nm; and “unfavorable” in a case where the value of the LWR performance was greater than 3.4 nm. Alternatively, in the electron beam exposure, the LWR performance was evaluated to be: “favorable” in a case where the value of the LWR performance was no greater than 5.5 nm; and “unfavorable” in a case where the value of the LWR performance was greater than 5.5 nm.

### CDU Performance

The resist pattern formed through an irradiation at the exposure dose of the Eop was observed from above the pattern using the scanning electron microscope. The line width was measured at 20 points within the range of 400 nm, and an averaged value of the width was determined. The averaged value was determined at arbitrary points of 500 in total, and a 3 Sigma value was determined from the distribution of the averaged values. The 3 Sigma value was defined as “CDU performance” (nm). The smaller value is more favorable since a better CDU performance is indicated, revealing a less variance of the line widths in greater ranges. In the ArF exposure, the CDU performance was evaluated to be: “favorable” in a case where the value of the CDU performance was no greater than 4.2 nm; and “unfavorable” in a case where the value of the CDU performance was greater than 4.2 nm. Alternatively, in the electron beam exposure, the CDU performance was evaluated to be: “favorable” in a case where the value of the CDU performance was no greater than 5.0 nm; and “unfavorable” in a case where the value of the CDU performance was greater than 5.0 nm.

### Resolution

A dimension of the minimum resist pattern which was resolved through an irradiation at the exposure dose of the Eop was measured, and the measurement value was defined as “resolution” (nm). The smaller value is more favorable since a better resolution is indicated, revealing that a finer pattern can be formed. The resolution was evaluated to be: “favorable” in a case where the value of the resolution was no greater than 35 nm; and “unfavorable” in a case where the value of the resolution was greater than 35 nm.

### Rectangularity of Cross-Sectional Shape

The cross-sectional shape of the resist pattern which was resolved through an irradiation at the exposure dose of the Eop was observed, and a line width Lb in the middle portion of the resist pattern along the height direction, and a line width La on the top of the resist pattern were measured. Then, a value La/Lb was calculated and defined as an indicator of the “rectangularity of cross-sectional shape”. The value of La/Lb more approximate to 1 is more favorable since better “rectangularity of cross-sectional shape” is indicated, revealing a more rectangular resist pattern. The rectangularity of cross-sectional shape was evaluated to be: “favorable” in a case where 0.9≦(La/Lb)≦1.05; and “unfavorable” in a case where (La/Lb)<0.9 or 1.05<(La/Lb).

### Depth of Focus

On the resist pattern which was resolved through an irradiation at the exposure dose of the Eop, the dimension of a pattern formed when the focus was shifted along the depth direction was observed, a latitude in the depth direction in which the pattern dimension falls within the range of 90% to 110% of the basis without being accompanied by a bridge and/or residue was determined, and the measurement value was defined as “depth of focus” (nm). The greater depth of focus is more favorable since a less variation of the dimension of the resulting pattern with the shift of the position of the focal point is indicated, leading to a higher process yield in the production of devices. The depth of focus was evaluated to be: “favorable” in a case where the value of the depth of focus was no less than 50 nm; and “unfavorable” in a case where the value of the depth of focus was less than 50 nm.

### MEEF Performance

With respect to the resist pattern which was resolved through an irradiation at the exposure dose of the Eop, line widths of resist patterns formed using mask patterns each giving a line width of 41 nm, 43 nm, 45 nm, 47 nm or 49 nm were plotted along the ordinate with respect to the size of the mask pattern along the abscissa. The slope of the straight line was calculated, and the value of the slope was defined as “MEEF performance”. The value of the MEEF performance more approximate to 1 is more favorable since better MEEF performance is indicated, revealing more superior mask reproducibility. The MEEF performance was evaluated to be: “favorable” in a case where the value of the MEEF performance was no greater than 3.7; and “unfavorable” in a case where the value of the MEEF performance was greater than 3.7.

TABLE 4

| | | Development with alkali | | | | | | Development with organic solvent | | | | | |
|---|---|---|---|---|---|---|---|---|---|---|---|---|---|
| | | | | | rectangu- | | | | | | rectangu- | | |
| | Radiation- | LWR | CDU | | larity | depth | | LWR | CDU | | larity | depth | |
| | sensitive | perfor- | perfor- | resolu- | of cross- | of | MEEF | perfor- | perfor- | resolu- | of cross- | of | MEEF |
| | resin | mance | mance | tion | sectional | focus | perfor- | mance | mance | tion | sectional | focus | perfor- |
| | composition | (nm) | (nm) | (nm) | shape | (nm) | mance | (nm) | (nm) | (nm) | shape | (nm) | mance |
| Example 1 | J1-1 | 2.98 | 3.88 | 30 | 1.01 | 80 | 3.22 | 2.97 | 3.90 | 31 | 0.98 | 70 | 3.09 |
| Example 2 | J1-2 | 3.02 | 3.86 | 30 | 0.93 | 70 | 3.31 | 2.88 | 3.88 | 32 | 1.03 | 70 | 3.08 |
| Example 3 | J1-3 | 2.99 | 3.76 | 31 | 0.93 | 70 | 3.32 | 3.12 | 3.78 | 32 | 1.01 | 80 | 3.12 |
| Example 4 | J1-4 | 3.14 | 3.97 | 30 | 0.94 | 80 | 3.03 | 3.11 | 3.99 | 32 | 0.99 | 90 | 3.14 |
| Example 5 | J1-5 | 2.98 | 3.76 | 30 | 0.95 | 80 | 3.04 | 3.09 | 3.78 | 31 | 0.98 | 80 | 3.15 |
| Example 6 | J1-6 | 2.99 | 3.77 | 32 | 1.02 | 70 | 3.11 | 3.07 | 3.79 | 31 | 0.96 | 90 | 3.16 |
| Example 7 | J1-7 | 2.99 | 3.75 | 31 | 0.95 | 80 | 3.18 | 3.11 | 3.77 | 31 | 1.01 | 90 | 3.03 |
| Example 8 | J1-8 | 3.03 | 3.65 | 31 | 1.03 | 70 | 3.34 | 3.09 | 3.67 | 32 | 0.99 | 60 | 3.04 |
| Example 9 | J1-9 | 3.04 | 3.89 | 31 | 0.99 | 60 | 3.32 | 3.11 | 3.91 | 30 | 1.02 | 70 | 3.11 |
| Example 10 | J1-10 | 2.98 | 3.76 | 32 | 0.99 | 70 | 3.33 | 3.08 | 3.78 | 31 | 0.96 | 60 | 3.18 |
| Example 11 | J1-11 | 3.14 | 3.77 | 31 | 1.03 | 70 | 3.12 | 3.07 | 3.79 | 30 | 1.02 | 70 | 3.34 |
| Example 12 | J1-12 | 2.97 | 3.88 | 32 | 1.02 | 80 | 3.09 | 3.21 | 3.90 | 30 | 0.96 | 60 | 3.32 |
| Example 13 | J1-13 | 3.02 | 3.91 | 32 | 1.02 | 80 | 3.08 | 3.25 | 3.93 | 30 | 1.02 | 80 | 3.35 |
| Example 14 | J1-14 | 2.87 | 3.79 | 32 | 0.99 | 60 | 3.12 | 3.08 | 3.81 | 31 | 1.02 | 60 | 3.22 |
| Comparative | CJ1-1 | 3.56 | 4.57 | 36 | 1.11 | 40 | 4.33 | 3.78 | 4.59 | 32 | 1.08 | 30 | 4.67 |
| Example 1 | | | | | | | | | | | | | |
| Comparative | CJ1-2 | 3.48 | 4.88 | 37 | 1.11 | 40 | 4.01 | 3.86 | 4.90 | 38 | 1.09 | 40 | 4.98 |
| Example 2 | | | | | | | | | | | | | |
| Comparative | CJ1-3 | 3.67 | 4.86 | 36 | 1.09 | 30 | 4.43 | 3.67 | 4.88 | 38 | 1.11 | 40 | 5.01 |
| Example 3 | | | | | | | | | | | | | |
| Comparative | CJ1-4 | 3.76 | 4.88 | 36 | 1.08 | 40 | 4.56 | 3.86 | 4.90 | 39 | 1.12 | 30 | 4.99 |
| Example 4 | | | | | | | | | | | | | |
| Comparative | CJ1-5 | 3.55 | 4.91 | 35 | 1.09 | 50 | 4.37 | 3.66 | 4.93 | 37 | 1.11 | 40 | 4.87 |
| Example 5 | | | | | | | | | | | | | |
| Comparative | CJ1-6 | 3.59 | 4.93 | 37 | 1.07 | 40 | 4.33 | 3.76 | 4.95 | 39 | 1.13 | 40 | 4.94 |
| Example 6 | | | | | | | | | | | | | |
| Comparative | CJ1-7 | 3.78 | 4.79 | 37 | 1.09 | 30 | 4.48 | 3.87 | 4.81 | 38 | 1.11 | 40 | 4.93 |
| Example 7 | | | | | | | | | | | | | |
| Comparative | CJ1-8 | 3.86 | 4.77 | 36 | 1.11 | 30 | 4.49 | 3.86 | 4.79 | 38 | 1.12 | 30 | 4.79 |
| Example 8 | | | | | | | | | | | | | |
| Comparative | CJ1-9 | 3.47 | 4.75 | 38 | 1.12 | 40 | 4.57 | 3.88 | 4.77 | 37 | 1.09 | 30 | 5.11 |
| Example 9 | | | | | | | | | | | | | |
| Comparative | CJ1-10 | 3.99 | 4.88 | 37 | 1.08 | 40 | 4.44 | 3.91 | 4.90 | 39 | 1.09 | 40 | 5.17 |
| Example 10 | | | | | | | | | | | | | |

TABLE 5

| | | Development with alkali | | | | Development with organic solvent | | | |
|---|---|---|---|---|---|---|---|---|---|
| | | | | | rectangu- | | | | rectangu- |
| | Radiation- | LWR | CDU | | larity | LWR | CDU | | larity |
| | sensitive | perfor- | perfor- | resolu- | of cross- | perfor- | perfor- | resolu- | of cross- |
| | resin | mance | mance | tion | sectional | mance | mance | tion | sectional |
| | composition | (nm) | (nm) | (nm) | shape | (nm) | (nm) | (nm) | shape |
| Example 15 | J2-1 | 4.78 | 4.46 | 32 | 0.99 | 4.91 | 4.57 | 32 | 0.98 |
| Example 16 | J2-2 | 4.88 | 4.57 | 31 | 0.98 | 5.01 | 4.68 | 31 | 0.99 |
| Example 17 | J2-3 | 4.97 | 4.67 | 33 | 0.98 | 5.10 | 4.78 | 31 | 0.97 |
| Example 18 | J2-4 | 4.86 | 4.77 | 32 | 0.97 | 4.99 | 4.88 | 32 | 0.96 |
| Example 19 | J2-5 | 4.55 | 4.83 | 32 | 0.99 | 4.68 | 4.94 | 33 | 0.98 |
| Example 20 | J2-6 | 4.68 | 4.39 | 32 | 0.98 | 4.81 | 4.50 | 32 | 0.97 |
| Example 21 | J2-7 | 4.49 | 4.48 | 33 | 0.97 | 4.62 | 4.59 | 32 | 0.98 |
| Example 22 | J2-8 | 4.97 | 4.42 | 31 | 1.01 | 5.10 | 4.53 | 32 | 1.01 |
| Example 23 | J2-9 | 4.87 | 4.45 | 32 | 1.02 | 5.00 | 4.56 | 31 | 1.02 |
| Example 24 | J2-10 | 4.88 | 4.49 | 31 | 0.97 | 5.01 | 4.60 | 32 | 0.99 |
| Example 25 | J2-11 | 4.86 | 4.47 | 32 | 0.99 | 4.99 | 4.58 | 32 | 0.99 |
| Example 26 | J2-12 | 4.79 | 4.46 | 33 | 1.01 | 4.92 | 4.57 | 31 | 1.01 |
| Example 27 | J2-13 | 4.89 | 4.46 | 32 | 1.02 | 5.02 | 4.57 | 33 | 0.98 |
| Example 28 | J2-14 | 4.92 | 4.48 | 32 | 0.98 | 5.05 | 4.59 | 31 | 0.97 |
| Example 29 | J2-15 | 4.83 | 4.47 | 33 | 0.97 | 4.96 | 4.58 | 32 | 1.01 |
| Example 30 | J2-16 | 4.81 | 4.44 | 31 | 0.98 | 4.94 | 4.55 | 32 | 1.01 |
| Comparative | CJ2-1 | 5.99 | 5.34 | 38 | 1.07 | 6.12 | 5.45 | 39 | 1.09 |
| Example 11 | | | | | | | | | |
| Comparative | CJ2-2 | 6.01 | 5.37 | 38 | 1.08 | 6.14 | 5.48 | 39 | 1.08 |
| Example 12 | | | | | | | | | |
| Comparative | CJ2-3 | 6.04 | 5.29 | 39 | 1.08 | 6.17 | 5.40 | 38 | 1.11 |
| Example 13 | | | | | | | | | |
| Comparative | CJ2-4 | 6.33 | 5.54 | 38 | 1.09 | 6.46 | 5.65 | 37 | 1.12 |
| Example 14 | | | | | | | | | |
| Comparative | CJ2-5 | 5.96 | 5.55 | 37 | 1.11 | 6.09 | 5.66 | 39 | 1.12 |
| Example 15 | | | | | | | | | |
| Comparative | CJ2-6 | 5.99 | 5.46 | 38 | 1.09 | 6.12 | 5.57 | 38 | 1.09 |
| Example 16 | | | | | | | | | |
| Comparative | CJ2-7 | 5.67 | 5.49 | 38 | 1.09 | 5.80 | 5.60 | 38 | 1.08 |
| Example 17 | | | | | | | | | |
| Comparative | CJ2-8 | 5.79 | 5.48 | 39 | 1.11 | 5.92 | 5.59 | 37 | 1.12 |
| Example 18 | | | | | | | | | |
| Comparative | CJ2-9 | 5.93 | 5.46 | 38 | 1.12 | 6.06 | 5.57 | 38 | 1.11 |
| Example 19 | | | | | | | | | |
| Comparative | CJ2-10 | 5.94 | 5.43 | 37 | 1.09 | 6.07 | 5.54 | 39 | 1.08 |
| Example 20 | | | | | | | | | |
| Comparative | CJ2-11 | 5.93 | 5.51 | 37 | 1.08 | 6.06 | 5.62 | 39 | 1.08 |
| Example 21 | | | | | | | | | |
| Comparative | CJ2-12 | 5.92 | 5.38 | 38 | 1.08 | 6.05 | 5.49 | 38 | 1.11 |
| Example 22 | | | | | | | | | |

As is clear from the results shown in Tables 4 and 5, the radiation-sensitive resin compositions of Examples were superior in LWR performance, CDU performance, resolution, rectangularity of cross-sectional shape, depth of focus and MEEF performance in the case of the ArF exposure and the electron beam exposure, and in both cases of the development with an alkali or an organic solvent. The radiation-sensitive resin compositions of Comparative Examples were inferior in each of these characteristics as compared with the radiation-sensitive resin compositions of Examples. An electron beam exposure is generally known to give a tendency similar to that in the case of the EUV exposure. Therefore, the radiation-sensitive resin compositions of Examples are expected to be superior in LWR performances, etc. also in the case of the EUV exposure.

The radiation-sensitive resin composition and the resist pattern-forming method according to the embodiments of the present invention enable a resist pattern that is superior in LWR performances, CDU performances, resolution and rectangularity of cross-sectional shape to be formed while superior depth of focus and MEEF performances are exhibited. Therefore, these can be suitably used for pattern formation in production of semiconductor devices, and the like, in which further progress of miniaturization is expected.

Obviously, numerous modifications and variations of the present invention are possible in light of the above teachings. It is therefore to be understood that within the scope of the appended claims, the invention may be practiced otherwise than as specifically described herein.

1. A radiation-sensitive resin composition comprising:
a polymer comprising a structural unit that comprises an acid-labile group;
a radiation-sensitive acid generator; and
a salt that comprises an onium cation, and HCO₃⁻, CO₃²⁻ or a combination thereof.

2. The radiation-sensitive resin composition according to claim 1, wherein the onium cation is a sulfonium cation, an ammonium cation, an iodonium cation, a phosphonium cation, a diazonium cation or a combination thereof.

3. The radiation-sensitive resin composition according to claim 2, wherein the onium cation is the sulfonium cation, the ammonium cation, the iodonium cation or a combination thereof.

4. The radiation-sensitive resin composition according to claim 1, wherein the onium cation is represented by formula (b-1) or (b-2): 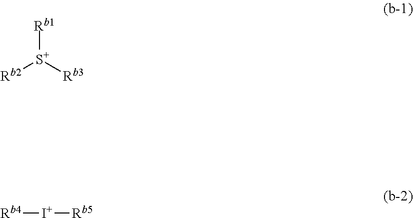
wherein, in the formula (b-1),
R^{b1}, R^{b2} and R^{b3} each independently represent a substituted or unsubstituted alkyl group having 1 to 10 carbon atoms, or a substituted or unsubstituted aryl group having 6 to 18 carbon atoms, or at least two of R^{b1}, R^{b2} and R^{b3} taken together represent a ring structure having 3 to 20 ring atoms together with the sulfur atom to which the at least two of R^{b1}, R^{b2} and R^{b3} bond, and
wherein, in the formula (b-2),
R^{b4} and R^{b5} each independently represent a substituted or unsubstituted alkyl group having 1 to 10 carbon atoms, or a substituted or unsubstituted aryl group having 6 to 18 carbon atoms, or R^{b4} and R^{b5} taken together represent a ring structure having 3 to 20 ring atoms together with the iodine atom to which R^{b4} and R^{b5} bond.

5. The radiation-sensitive resin composition according to claim 1, wherein an acid generated from the radiation-sensitive acid generator is a sulfonic acid, an imide acid, an amide acid, a methide acid or a combination thereof.

6. The radiation-sensitive resin composition according to claim 1, wherein the radiation-sensitive acid generator is represented by formula (3):
A⁻X⁺ (3)
wherein, in the formula (3),
A⁻ represents a monovalent sulfonic acid anion, a monovalent imide acid anion, a monovalent amide acid anion or a monovalent methide acid anion; and
X⁺ represents a monovalent onium cation.

7. The radiation-sensitive resin composition according to claim 6, wherein A⁻ represents the monovalent sulfonic acid anion, and the radiation-sensitive acid generator represented by the formula (3) is represented by formula (4): 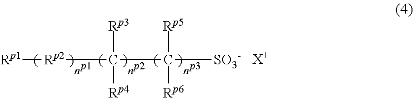
wherein, in the formula (4),
R^{p1} represents a monovalent group that comprises a ring structure having 6 or more ring atoms;
R^{p2} represents a divalent linking group;
R^{p3} and R^{p4} each independently represent a hydrogen atom, a fluorine atom, a monovalent hydrocarbon group having 1 to 20 carbon atoms or a monovalent fluorinated hydrocarbon group having 1 to 20 carbon atoms;
R^{p5} and R^{p6} each independently represent a fluorine atom or a monovalent fluorinated hydrocarbon group having 1 to 20 carbon atoms;
n^{p1} is an integer of 0 to 10;
n^{p2} is an integer of 0 to 10;
n^{p3} is an integer of 0 to 10,
wherein a sum of n^{p1}, n^{p2} and n^{p3} is no less than 1 and no greater than 30, wherein in a case where n^{p1} is no less than 2, a plurality of R^{p2}s are identical or different, wherein in a case where n^{p2} is no less than 2, a plurality of R^{p3}s are identical or different and a plurality of R^{p4}s are identical or different, and wherein in a case where n^{p3} is no less than 2, a plurality of R^{p5}s are identical or different and a plurality of R^{p6}s are identical or different; and
X⁺ is as defined in the formula (3).

8. The radiation-sensitive resin composition according to claim 7, wherein n^{p3} is no less than 1.

9. The radiation-sensitive resin composition according to claim 6, wherein X⁺ represents a sulfonium cation or an iodonium cation.

10. The radiation-sensitive resin composition according to claim 6, wherein X⁺ is represented by formula (b-1) or (b-2): 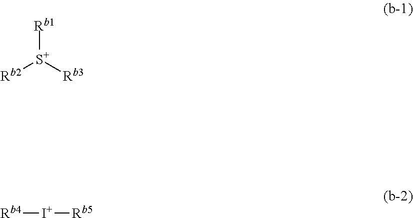
wherein, in the formula (b-1),
R^{b1}, R^{b2} and R^{b3} each independently represent a substituted or unsubstituted alkyl group having 1 to 10 carbon atoms, or a substituted or unsubstituted aryl group having 6 to 18 carbon atoms, or at least two of R^{b1}, R^{b2} and R^{b3} taken together represent a ring structure having 3 to 20 ring atoms together with the sulfur atom to which the at least two of R^{b1}, R^{b2} and R^{b3} bond, and
wherein, in the formula (b-2),
R^{b4} and R^{b5} each independently represent a substituted or unsubstituted alkyl group having 1 to 10 carbon atoms, or a substituted or unsubstituted aryl group having 6 to 18 carbon atoms, or R^{b4} and R^{b5} taken together represent a ring structure having 3 to 20 ring atoms together with the iodine atom to which the R^{b4} and R^{b5} bond.

11. The radiation-sensitive resin composition according to claim 1, wherein the radiation-sensitive acid generator is a radiation-sensitive acid generating agent, and a content of the radiation-sensitive acid generating agent in terms of solid content equivalent is no less than 5% by mass and no greater than 30% by mass.

12. The radiation-sensitive resin composition according to claim 11, wherein the content of the radiation-sensitive acid generating agent in terms of solid content equivalent is no less than 10% by mass.

13. The radiation-sensitive resin composition according to claim 1, wherein the structural unit that comprises the acid-labile group is represented by formula (a-1) or (a-2): 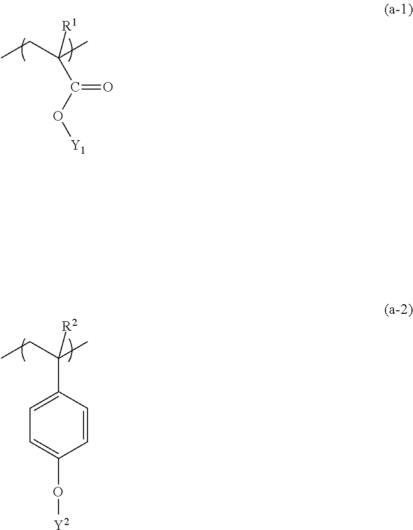
wherein, in the formula (a-1),
R¹ represents a hydrogen atom, a fluorine atom, a methyl group or a trifluoromethyl group; and
Y¹ represents a monovalent acid-labile group represented by formula (Y-1): 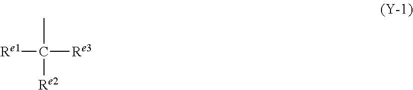
wherein, in the formula (Y-1),
R^{e1} represents a monovalent hydrocarbon group having 1 to 20 carbon atoms; and
R^{e2} and R^{e3} each independently represent a monovalent hydrocarbon group having 1 to 20 carbon atoms, or R^{e2} and R^{e3} taken together represent an alicyclic structure having 3 to 20 ring atoms together with the carbon atom to which R^{e2} and R^{e3} bond, and wherein, in the formula (a-2),
R² represents a hydrogen atom or a methyl group; and
Y² represents a monovalent acid-labile group represented by formula (Y-2): 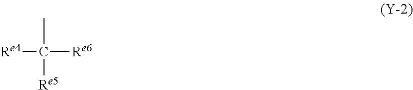
wherein, in the formula (Y-2),
R^{e4}, R^{e5} and R^{e6} each independently represent a hydrogen atom, a monovalent chain hydrocarbon group having 1 to 20 carbon atoms, a monovalent alicyclic hydrocarbon group having 3 to 20 carbon atoms, an oxychain hydrocarbon group having 1 to 20 carbon atoms or an oxyalicyclic hydrocarbon group having 3 to 20 carbon atoms, wherein at least one of R^{e4}, R^{e5} and R^{e6} does not represent a hydrogen atom.

14. A resist pattern-forming method comprising:
applying the radiation-sensitive resin composition according to claim 1 on a substrate to form a resist film on the substrate;
exposing the resist film; and
developing the resist film exposed.

15. The resist pattern-forming method according to claim 14, wherein a developer solution used in the developing is an alkaline aqueous solution.

16. The resist pattern-forming method according to claim 14, wherein a developer solution used in the developing comprises an organic solvent.
